(19) United States
(12) Patent Application Publication
(10) Pub. No.: US 2011/0207328 A1
(43) Pub. Date: Aug. 25, 2011

(54) METHODS AND APPARATUS FOR THE MANUFACTURE OF MICROSTRUCTURES

(76) Inventor: Stuart Philip Speakman, Essex (GB)

(21) Appl. No.: 12/446,452

(22) PCT Filed: Oct. 19, 2007
(86) PCT No.: PCT/GB2007/004012

§ 371 Date: Dec. 6, 2010

(30) Foreign Application Priority Data
Oct. 20, 2006 (GB) 0620955.5

(51) Int. Cl. H01L 21/02

(52) U.S. Cl. 438/694; 257/E21.002

(57) ABSTRACT

A method of manufacturing microstructures is disclosed, the method comprising a applying a mask to substrate; forming a pattern in the mask; processing the substrate according to the pattern; and mechanically removing the mask from the substrate. A polymer mask is disclosed for manufacturing micro scale structure, the polymer mask comprising a thin, preferably ultra thin flexible film. A method of manufacturing an integrated circuit is disclosed, the method comprising forming a plurality of isolated semiconductor devices on a common substrate; and connecting some of the devices. Apparatus for manufacturing microstructures is disclosed comprising: a mechanism for coating a mass substrate to create a structure; a mechanism for removing a mask from the substrate; and processing apparatus. A thin film transistor is disclosed comprising drain source and gate electrodes, the drain and source electrode being separated by a semiconductor, and the gate electrode being separated from the semiconductor by an insulator, comprising a bandgap alignment layer disposed between a semiconductor and the insulator.

This invention relates to methods and apparatus for the manufacture of microstructures. In particular, but not exclusively, this invention relates to the methods and apparatus for the manufacturer of semiconductor devices, and other microstructures, such methods involving the use of masking techniques. This invention also relates to novel microstructures, in particular, but not exclusively, novel semiconductor devices particularly those which may be manufactured by the use of masking techniques. This invention is of particular, although not exclusive, relevance to the field of thin film transistors, particularly transparent thin film transistors.

The manufacture of microstructures, particularly semiconductor devices, has transformed modern society. The highly flexible and useful products which may be made from these devices are now an integral part of modern life, and there is a continuing need to manufacture such devices more cost effectively, both to lower the cost of current products and to open up new markets.

Typically, at present, semiconductor based microstructures are manufactured by an etching process. A mask is applied to a multi-layered silicon structure, various chemical etching techniques are used to remove layers of the structure, preferentially layers which are not protected by the mask. Multiple masks may be used in the manufacture of more complex devices, with each mask being chemically removed from the silicon multilayer structure.

However, there are disadvantages with many current fabrication processes. In particular, it is difficult to manufacture low cost, relatively simple, microstructures cost effectively. This is because typical fabrication processes rely on economies of scale, with the result that it is more cost effective to manufacture devices with a degree of redundancy but that are suitable for many applications, than application-specific devices, which have, inherently, smaller markets. The need for economies of scale also means that it is difficult to mix and match manufacturing processes cost-effectively.

There is a need to introduce flexibility into the manufacturing process of such microstructure.

Present methods are particularly disadvantageous when it comes to the manufacture of flexible micro-structures, or the manufacture of micro-structures on a flexible substrate, such as in the manufacture of flexible displays. The films which make up the multi-layer structure may break or become degraded (with respect to operational lifetime and performance and storage life) if over-flexed.

Described hereinafter are methods of manufacture which comprise applying a mask to a substrate; forming a pattern in the mask; processing the substrate according to the pattern; and removing the mask from the substrate and a number of aspects and variants of invention relating thereto.

According to a first aspect of the invention, the mask (as will be described hereinafter in more detail) may be removed using a film coating. The film coating may also be used to remove debris resulting from the formation of the pattern and processing of the substrate, although other means may be used for this purpose either alone or in conjunction with the film coating as will appear hereinafter. The film coating may also be further referred to herein as a “Seal-n-Peel” layer or film, or as a “Peel-n-Seal” layer or film, or as a “sealing-removal film”.

The mask is preferably in intimate contact with the substrate.

The film coating therefore serves to remove what may be referred to as a patterning sandwich, which might include the film coating, and the processed mask, and optionally debris. The materials which form the mask and the film coating should be so chosen that the bond between the film coating and the mask is stronger than the bond between the mask and the substrate in order to ensure that the mask strips off the substrate when the film coating is removed. The materials should also be chosen such that the film coating is stronger than the mask. Advantageously the film coating may be more rigid than the mask and heavier than the mask per unit area. With these criteria in mind, the film coating may be made thicker than the mask. Although reference is made herein to a film coating, the same may take the form of a film or of a coating which may be applied in any convenient manner as will be described hereinafter in more detail. The expression film coating is therefore to be understood in a broad and general sense.

The invention also provides an apparatus for performing the first aspect of the invention comprising means for applying a mask to a substrate, means for forming a pattern in the mask, means for processing the substrate according to the pattern, means for applying a film coating, and means for removing from the substrate the film coating and the mask

The method may include applying a further mask or masks to the substrate or to another mask. Hereinafter, reference to “a multiple mask arrangement” comprehends such an arrangement in which more that one mask is applied to the substrate, or one mask is applied to a further mask, whereby the substrate is associated with more than one mask. Consequently a stack of masks may be carried by the substrate. A method of manufacturing a microstructure may therefore comprise any or all of the following steps: namely forming a pattern in the further mask or masks; processing the substrate according to the pattern; and removing the further mask or masks. Any one mask may be removed from another mask or from a substrate surface. Alternatively or additionally a mask in the form of a multiple mask stack may be removed directly from the substrate surface as a complete stack. Alternatively or additionally, the method may comprise removing portions of at least one of the masks successively from the substrate.

The mask or at least one mask of a multiple mask arrangement may be in the form of a film, which may be a flexible film, or may be a relatively rigid film. Alternatively the mask may be in the form of a coating. The mask may be referred to hereinafter as masking film or a mask coating). One or more masks of a multiple mask arrangement may be in the form of a masking film and the other or others in the form of mask coatings.

The mask or at least one mask of a multiple mask arrangement may be applied to the substrate and/or to another mask by lamination. Thus the method may comprise applying a mask or at least one mask of a multiple mask arrangement, each in the form of masking film, to the substrate by lamination. Alternatively, masks in the form of masking film may be laminated together.

Herein, “lamination” is defined to mean cover or overlay with a thin layer of material irrespective of how the layer of material is applied.

At least one of the masks may be in solid form before being applied to the substrate, such as by lamination. Alternatively or additionally, at least one of the masks may be in liquid or vapour form before being applied to the substrate, such as by lamination or otherwise

The mask or at least one mask of a multiple mask arrangement may be made of a polymer. The polymer mask may be made of a material such as a polyethylene terephalate, a polypropylene, a polyethylene napthalate, polyethersulphone, or a polyimide. Alternatively or additionally one of the masks may be a polymer treated paper or an inorganic coating treated polymer film.

Masks in accordance with aspects of this invention, including polymer masks, may take the form of a coating, which may consist of pure adhesive or other substance applied by a liquid coating method. Alternatively, the mask may take the form of a film which may be applied using a separate adhesive, The mask is desirably ultra-thin, being of molecular thickness. Such a mask may have a thickness of between 0.1 to 200 μm, preferably 0.5 to 50 μm, more preferably 0.5 to 25 μm, and still more preferably less than 5.0 μm.

Masks in accordance with aspects of the invention may be relatively flexible and not as rigid as masks known for photolithography purposes, and are not used in connection with photolithography.

The mask or at least one mask of a multiple mask arrangement may comprise or incorporate photoabsorbers. Such photoabsorbers may be liquid or particulates. Such photoabsorbers may be organic or inorganic. Such photoabsorbers may be pigments or dyes. Conveniently, particulate photoabsorbers will be less than 25 nm in size. preferably <10 nm. Such absorbers may be selected from carbon black nanoparticles, nanorods, nanotubes and nanoplatlets. Alternatively, the absorbers may be inorganic pigments or dyes. A preferred photoabsorber is zinc oxide. Organic dyes may be also be used. It will be appreciated that an alternative approach to photoabsorption is to alter the chemical nature of the polymer mask material (e.g. the polymer side chains). The use of photoabsorbers serves to prevent a laser used to etch the mask from etching the substrate, especially when an infrared laser is employed. The mask is therefore adapted to the laser which is employed. When made of plastics, the substrate and mask may be made from the same material.

Methods in accordance with the invention may comprise applying at least one of the masks as a mask coating by a method such as dip coating, spray coating (gas pressure assisted, electrostatic or piezoelectric), flow coating, spin coating, capillary (laminar) flow coating, roll coating, printing (thermal, screen, digital ink jet, gravure), chemical, sol-gel, electrophoretic, draw bar, vapour coating, plasma (including plasma polymerized), electron beam, thermally evaporated, and/or sputtered.

At least one of the masks may comprise a plurality of layers. At least one of the masks may comprise a plurality of masks. The layers and or masks may be bonded by adhesive to each other with differential bond energy. One such layer may be reflective, preferably a layer between an adhesive layer and the masking film. This means that the adhesive layer is etched by the reflected laser light making peel-off easier. Preferably the method comprises applying a reflective layer to the substrate. Such a mask may be applied to the substrate such that the reflective layer is the closest layer of the mask to the substrate and/or on the opposite side of the substrate to the mask. The method may comprise controlling a profile of the mask using the reflective layer, preferably through controlling the angle of reflection. The mask may have a predetermined layer thickness. Preferably the layers are bonded by adhesive. This aspect of the invention provides for the etching of the rear surface of the masking film from a reflective surface that is on the other surface of the transparent (to a substantial portion of the laser wavelength) substrate material. In this instance the masking film or film stack may be applied to the upper (top) surface of the substrate material and a second masking film may be applied to the lower (bottom) surface of the substrate material forming a sandwich structure.

The lower surface mask may be so manufactured as to provide on, or in, the surface of the masking film closest to the bottom surface of the substrate a surface feature that causes an incoming parallel beam of laser light to be reflected at a controlled angle substantially in the direction of the incoming laser light (focussed beam). This reflected light may be of sufficient energy density so as to travel back along through the substrate material at the angle defined by the reflecting surface structure where it interacts with the surface preferably the lower surface of the surface in contact with the substrate of the upper masking structure so as to cause a volume of the masking film to be disrupted preferably by bond scission and preferably to be expelled under a pressure gradient into the space created by the initial laser etching of a feature into the upper masking structure. This may create a controlled geometry undercut that would ease peelable removal of the masking film structure preferably even with substantially conformal coating deposits.

One or more of the layers may comprise an adhesive. The adhesive may be a low tack pressure-sensitive or a low weight high tack permanent adhesive. Alternatively, a full weight permanent adhesive may be used if the mask is to remain in place after functional coating deposition. The adhesive may be temporary semi-permanent without restriction on time. One such layer may be reflective.

The mask may have a high chemical stability (chemical resistance). The mask may include an FEP (Fluorinated Ethene Propene) or PTFE (Polytetrafluorethene) based system.

The film coating may comprise an adhesive layer and be laminated onto the substrate, or onto at least one mask of a multiple mask arrangement, and/or onto a top surface which has been formed on the substrate. The adhesive may be a strong and/or permanent adhesive. In the event that the mask is laminated to the substrate using an adhesive, the adhesive forming the adhesive layer which constitutes or forms part of the film coating creates a stronger bond than the adhesive used to laminate the mask to the substrate. This serves to ensure that the mask is stripped off the substrate during the removal process.

In accordance with another aspect of the invention, the mask, or at least one mask of a multiple mask arrangement, may be mechanically removed from the substrate or from another mask that has been applied to the substrate. Preferably such removal is by peeling. Preferably the mask or at least one mask of a multiple mask arrangement is mechanically removed from the substrate or another mask that has been applied to the substrate by peeling. Alternatively, or additionally, the mask or at least one mask of a multiple mask arrangement may be removed by applying a force along a plane at a controlled angle that may be substantially parallel to the surface of the substrate. Alternatively or additionally, the method may comprise removing portions of at least one of the masks successively from the substrate. The method may comprises starting removal at one side of the substrate, proceeding in a direction generally parallel to a surface of the substrate, and finishing at a far side of the substrate.

In accordance with an alternative and further aspect of the invention, the mask or at least one mask of a multiple mask arrangement may be removed by a non-mechanical removal method such as liquid penetration along the mask-substrate interface. Alternatively or additionally use may be made of a de-bonding method that assists with the peel-off and/or clean removal of a processed mask from the substrate or further mask. Such methods may be of a thermal, electrostatic (e.g. anti-static), air pressure (e.g. air-blade “knife”) or chemical nature.

When employing a film coating in accordance with the first aspect of the invention, the film coating may form with the mask and optionally debris a sandwich in which all residual materials and debris are sealed, the sandwich being removed from the substrate in a single peeling process, the sandwich being deposited in a container for disposal. The use of a film coating to form a sandwich with the mask, and removing the sandwich from the substrate by means of a peeling operation may be referred to hereinafter for simplicity as a “Seal-n-Peel” operation, and the film coating as a “sealing film”.

The same or similar methods as are described hereinafter to form the mask may be used to apply or form the film coating, provided that it is such that, when it is removed, as by peeling, it carries with it the mask and/or debris, as required. The sealing film is preferably more rigid than the mask.

The substrate may be rigid or flexible. Conveniently a flexible substrate may be made of a plastics material, such as a plastics sheet, metal foil, paper, coated paper, metallised plastic sheet, polymer coated card, or textiles. Alternatively, a rigid substrate may be formed from a rigid sheet or plate material such as glass, metal, reinforced fibre or wood, for example.

Methods in accordance with the invention may comprise treating or coating an outer surface of at least one of the masks with a substance or a treatment. The properties of such a surface may be different from that of the bulk of the material. Such altered properties may be wettability or attachability. Such a surface may be achieved using a surface chemical treatment, plasma irradiation, physical conditioning or chemical conditioning.

Methods in accordance with the invention may comprise unwinding the substrate from a roll. The method may comprise unwinding at least one of the masks from a roll. The method may comprise winding the processed substrate onto a roll.

The pattern formed in the mask may be such that the mask remains essentially continuously connected after its formation. In this respect, the mask may comprise an array of holes, the film being essentially continuously connected between the holes. Preferably the pattern comprises an array. Alternatively, the pattern formed in the mask may be such that the mask does not remain continuously connected after its formation

Preferably the pattern is formed in the mask by a direct write process such as laser etching, conveniently dry laser etching the pattern into the mask. The laser wavelength is preferably between infra-red and deep ultra-violet. The laser may be one of an Excimer, a diode pumped YAG, a diode pumped solid state Nd:YVO4 or a Ti:sapphire laser. The method may comprise using semiconductor diode laser or Q-switched laser technologies. The method may comprise using flashlamp-pumped lasers such as Nd:YAG or Nd:YLF lamp-pumped Q-switched.

The laser pulse duration may be in the range 1 femtosecond to several microseconds, conveniently of the order of 0.1 to 100 nanoseconds and preferably less than 10 nanoseconds.

Methods in accordance with the invention may comprise patterning the mask or the masks of a multiple mask arrangement (off-substrate patterning), before transferring it onto the substrate. The mask may be on a release liner that may be an energy controlled paper or plastic sheet film. Alternatively or additionally the mask may be covered with a similar release liner. Alternatively or additionally the mask may be coiled onto a drum where the rear surface of the single sheet release film is also so treated to provide very low bond strength to the mask. The release liner, or liners if the mask is sandwiched between two such materials, may be transparent to the wavelength of laser to be used to ablation pattern the mask (mask coating) so that a pattern may be generated in the mask (mask coating) by directing the laser light onto the mask surface directly or by passing it through the transparent release liner. The mask may be produced on the release liner before being patterned. The resulting patterned mask may then be applied to the substrate by a method such as pressure roller and/or lamination methods on to a substrate surface. If more than one liner is used, one or more of these liners may be removed prior to applying the mask to the substrate.

Methods in accordance with the invention may comprise removing debris from the pattern formation process. The debris may be removed using a method such as suction for example by a vacuum. Additionally or alternatively the debris may be removed using electrostatic attraction means for example suitably placed collection electrodes of a specific electrical potential and charge sign. Alternatively or additionally the debris may be removed by use of a second laser beam having different properties to the etching laser. Additionally or alternatively the debris may be removed using air transfer and blowing. Additionally or alternatively the debris may be removed using liquid spray cleaning.

Alternatively, laser ablation mask patterning debris may be removed by the use of multiple layers of materials, including a release liner coated with a transferable mask (mask coating), whereby the non-mask material (including the release liner or liners if the mask is sandwiched between two such materials) is transparent to the wavelength of laser to be used to ablation pattern the mask (mask coating) so that a pattern can be generated in the mask (mask coating) by directing the laser light onto the mask surface directly or by passing it through the transparent release liner. Any ablation plume/evaporated/explosive vapour debris may be collected by the transferable mask (mask coating) film and may be cleanly removed with it.

One or both surfaces may be altered independently during film manufacture including mechanical or physical changes.

Methods in accordance with the invention may include etching the substrate. The substrate may be etched as the pattern is formed in at least one of the masks. Such a method means that embedded features may be formed in the substrate, which may be automatically aligned with features formed on the substrate through use of a mask. This method may also provide conformal mapping of the feature generated in the mask so as to provide a substantially faithful reproduction of this feature directly into the substrate material.

Processing the substrate may comprise depositing material on the substrate or on a feature on the substrate or into a feature in the substrate to form a feature or further features. The method may comprise etching the feature.

Methods in accordance with the invention may comprise reducing curling or free edge lifting or buckling in the etched feature. The curling may be reduced through any or all of the following steps: capping the feature, depositing the feature on a thermally conductive film, selecting a feature having a molecular structure appropriate to the substrate material, depositing the feature on a series of vertically stacked ultra-thin films or termed quantum well stack. The thickness of each layer may be engineered to obtain specific electronic and photonic properties on an atomic scale; for example using high precision bandgap engineering. Alternatively a multilayer stack could be used with differing resultant properties where the layer thickness is more wide ranging.

At least one of the masks may have a thickness of between 0.1 to 200 μm, conveniently 0.5 to 25 μm, preferably less than or substantially equal to 10 μm. The mask can be in a sheet film form or a thin or thick film coating form.

A profile may be etched into at least one of the masks as the pattern is formed. Preferably the profile is etched into a cross-sectional wall of the mask. Preferably the profile comprises an undercut. Concave, convex, vertical, inverse or re-entrant features may be formed. Preferably the profile so-produced is such that the profile is substantially screened from material added to or into the substrate during processing. Alternatively or additionally, the profile may be screened by other means.

Methods in accordance with the invention may comprise treating or coating an outer surface of at least one of the masks with a substance or a treatment such as neutral argon plasma irradiation or physical conditioning or chemical conditioning such as conversion, termed nitriding, in nitrogen plasma to alter the wettability of the mask. Alternatively or additionally, the method may comprise treating or coating the inner surface of the at least one of the masks with a substance to alter the adhesive bond energy between the mask and the substrate. This may be achieved as a result of etching the mask in a controlled chemical ambient or as a separate process after the mask pattern has been formed.

Methods in accordance with the invention may be used for the manufacture of semiconductor devices, conveniently thin film transistors, preferably transparent thin film transistors. Such a method may be used for the manufacture of transparent, translucent, or opaque microstructures.

The processing step may comprise coating the mask (patterned mask) and the substrate with a material. Conveniently the method comprises coating the mask and the substrate by a process whereby a material in solid particle, liquid or vapour form is deposited as a coating onto the patterned mask and substrate. Preferably the coating process is a thick or thin film deposition process. Conveniently the method comprises coating the mask and the substrate by a process comprising one of closed-field magnetron sputtering, closed field unbalanced magnetron sputter ion plating, laser ablation, ion beam sputtering, ion beam assisted deposition, vacuum arc, multiple arc, electron beam evaporation, ion assisted electron beam evaporation, atomic layer epitaxy, molecular beam epitaxy, chemical vapour deposition, electron cyclotron resonance chemical vapour deposition, plasma enhanced chemical vapour deposition or laser dry transfer printing, pulsed magnetron sputtering, pulsed sputtering, pulsed biased sputtering, pulsed biased magnetron sputtering, laser-assisted chemical vapour deposition, electrostatic spray deposition, or electrostatic spray assisted vapour deposition.

The processing step may comprise coating further patterned masks and the substrate with different materials (deposited coatings).

The processing temperature may be between −100 to +540° C. Preferably the method may be carried out at a processing temperature of less than 100 degrees C. for the manufacture of transparent, translucent, or opaque microstructures. Conveniently the method may be carried out at a processing temperature of less than 100 degrees C. The processing temperature may be very wide ranging since one of the primary benefits of the invention is the ability to mix and/or match processes with substrate and masking film media for the manufacture of transparent, translucent, or opaque microstructures. By way of example the substrate and the masking film could both be transparent but yellow coloured polyimide that is thermally stable and would permit the use of processes that require thin film deposition temperature up to about 540° C. Conversely, a temperature-sensitive bio-degradable masking film could be used on a polyester substrate with an organic vapour deposition process, such as polymerisation at room temperature, so that the residual by-product of masking film and organic deposit would be a bio-degradable waste processed at room temperature.

The processing step may comprise coating further patterned masks and the substrate with different materials (deposited coatings)

Methods in accordance with the invention may comprise depositing a plurality of vertically aligned layers of different material. The multiple layer alignment is preferably within the resolution of the laser or other etching process. For laser etching the resolution is generally a fraction of the wavelength of the light used, although the nature of the processing system whether flatbed or roll-to-roll, or another will have an impact on the values that can be achieved in practice.

Methods in accordance with the invention may be employed in manufacturing transistors in which the semiconductor-substrate and semiconductor-gate insulator interfaces are produced in a single processing step.

Preferably such a method may be used for the manufacture of transparent, translucent, or opaque microstructures. Preferably the microstructures may be semiconductor devices. Preferably the devices are functionally equivalent, The semiconductor devices may be transistors, conveniently thin film transistors, preferably transparent thin film transistors or diodes or resistors or capacitors or inductors.

Further aspects of the invention include its applicability to the production of many other types of microstructures for example microelectronic, opto-electronic and photonic devices and circuits.

Methods in accordance with the invention may comprise forming an access window in a portion of the mask above the substrate.

According to a further aspect of this invention, there is provided a polymer mask for manufacturing a microscale structure comprising a thin, preferably ultra-thin, flexible film. Preferably the polymer mask has sufficient tensile strength and tear resistance to be removable from a substrate by peeling. The polymer mask may have a tensile strength of 100 to 300 MPa, conveniently 150 to 250 MPa, preferably substantially 200 MPa. The polymer mask may have a tear resistance of >5 g per μm as a continuous film. In use, the tear resistance may be affected as of a function of the masking film thickness used, the masking film material type, the size and distribution of the pattern features, the shape of the pattern features, the applied peel-off force used for the masking film—substrate scheme employed, and the nature of the deposition process to be used to coat the etched features (including coating coverage distribution, material type, coating thickness, and number of layers in a multilayer stack).

The aforementioned tensile strengths (as well as the other characteristics of the polymer mask, without limitation) apply to any appropriate aspect of the invention, including the methods described herein.

The polymer mask may have a thickness of 0.02 to 250 μm, 0.1 to 200 μm, conveniently 0.5 to 25 μm, preferably 1 to 10 μm, and also 5 μm. It may also have a thickness of 0.1 to 200 μm, preferably 1-10 μm

The polymer mask may be made of a material such as a polyethylene terephalate, a polypropylene, a polyethylene napthalate or a polyimide. It is also possible for the masking film to be a polymer treated paper or an inorganic coating treated polymer film.

The polymer mask may have a surface of a pre-determined particular wettability which is different from that of the bulk of the material. Alternatively, or additionally, the polymer mask may have a surface of a pre-determined particular attachability which is different from that of the bulk of the material. Such a surface may be achieved using a surface chemical treatment, an ultra thin film organic or inorganic deposit, or as a result of the manner in which the masking film was produced for example thinning roller surface induced masking film surface. One or both surfaces or both surfaces may be altered independently during film manufacture including mechanical or physical changes.

The polymer mask may have a high chemical stability. An FEP (Fluorinated Ethene Propene) or PTFE (Polytetrafluorethene) based polymer masking system preferably either in ultra thin sheet form or produced using a liquid source that when dried provides an ultra thin sheet of such a chemically resistant material.

One of the layers may comprise an adhesive. The adhesive may be a low tack pressure-sensitive or a low weight high tack permanent adhesive. Alternatively, a full weight permanent adhesive may be used if the mask is to remain in place after functional coating deposition The adhesive may be temporary semi-permanent which in this context means that the mask is peelable without restriction on time. Preferably it is not the time that the masking film is in contact with the substrate media but the adhesive strength. The adhesive strength preferably dictates the ease with which the masking film can be removed from the substrate after processing. This semi-permanent state may be maintained as a function of time and of subsequent processing events including etching and single or multiple layer deposition

All of the previous features described in relation to aspects and methods in accordance with the invention, or variants thereof, also apply to the array of isolated semiconductors aspect of the invention, as well, of course, as to any other aspect of the invention.

According to a still further aspect of this invention, there is provided an array of isolated semiconductor devices formed on a common substrate. Preferably the devices are functionally equivalent.

The devices may be transistors, conveniently thin film transistors, preferably transparent thin film transistors or diodes or resistors or capacitors or inductors.

According to a further aspect of this invention, there is provided an integrated circuit comprising an array as described above in which selected devices are interconnected. The interconnections may be essentially electrical in nature or alternatively or additionally may comprise optical or thermal interconnects.

Preferably the interconnections are laid down by a direct write method such as printing, preferably digital ink-jet or laser dry transfer printing.

A substantial proportion of the devices may be redundant. Substantially 20%, conveniently substantially 40%, preferably substantially 60% or even substantially 80% may be redundant. For example an application may comprise a universal switching backplane comprising a number of transistors and capacitors for each display pixel (universal cell circuit), preferably comprising 6 transistors and 2 capacitors. For a liquid crystal display (LCD) only one transistor and one capacitor are preferably used with the remaining devices being redundant for this display type. Using the same universal cell circuit but for an OLED display preferably 5 transistors and 1 capacitor are used with the remaining devices being redundant for this display type. By redundant it is meant that the devices perform no useful function in the interconnected integrated circuit.

According to a further aspect of this invention, there is provided a display comprising an integrated circuit as described above.

Such a display may comprise an array of addressable pixels, each pixel comprising such an integrated circuit and an electrode. The electrode may comprise a flexible portion. Each pixel may be individually addressable.

According to a further aspect of this invention, there is provided a method of manufacturing an integrated circuit comprising: forming a plurality of isolated semiconductor devices on a common substrate; and connecting some of the devices.

The method may comprise connecting the devices by a direct write technique. The method may comprise connecting the devices using one of ink jet printing, offset lithographic printing, soft lithography contact stamp printing, laser dry forward transfer printing, robocast printing, nib writing, or laser focussed beam conversion. For laser focused beam conversion the mask may have chemistry such that the laser converted material remains in place when the peelable sheet is removed.

The method may comprise direct writing of electrical insulator or isolation structures adjacent to the location of, and prior to the direct writing of the electrical interconnects. This is to ensure that devices are not electrically short circuited.

According to a further aspect of this invention there is provided apparatus for manufacturing microstructures comprising: a laminator for laminating a substrate with a mask, which may be in the form of a masking film; and a roller for winding the laminated structure onto a roll.

Preferably the apparatus is adapted to be used for the manufacture of semiconductor devices.

The apparatus may comprise a mechanism for unwinding both the substrate film and the mask from respective rolls. The apparatus may be adapted to be used for the manufacture of semiconductor devices.

According to a further aspect of this invention there is provided apparatus for manufacturing microstructures comprising: a mechanism for unwinding at least one of a substrate film or a mask, which may be in the form of a masking film, from a roll; and a laminator for laminating the mask with the substrate film.

The apparatus may comprise a mechanism for unwinding the substrate from an input roll. Preferably the mask removing mechanism is operable to peel the mask from the substrate. Preferably the peeling mechanism provides for a controlled pull-off force and peeling angle. This helps to ensure that the masking film does not rip or tear.

According to a further aspect of this invention there is provided apparatus for manufacturing microstructures comprising: a mechanism for coating a masked substrate to create a structure; a mechanism for removing a mask from the substrate; and a mechanism for winding the coated substrate onto an output roll.

According to an further aspect of this invention there is provided apparatus adapted to be used for a method as described herein, the apparatus comprising: a mechanism for applying a mask to a substrate; a mechanism for forming a pattern in the mask; a mechanism for processing the substrate according to the pattern; and a mechanism for mechanically removing the mask from the substrate.

According to a further aspect of the invention, in a method of manufacturing transistors, semiconductor substrates and semiconductor insulation interfaces may be produced in a single processing step.

According to a further aspect of the invention, there is provided a thin film transistor comprising drain, source and gate electrodes, the drain and source electrodes being separated by a semiconductor, and the gate electrode being separated from the semiconductor by an insulator, comprising a bandgap alignment layer disposed between the semiconductor and the insulator.

Preferably the bandgap alignment layer is adjacent to the semiconductor and to the insulator. Preferably the product of the dielectric constant and the [thickness or average thickness of the bandgap alignment layer is of the order of 10, conveniently 50, preferably 100 times lower in value than the product of the dielectric constant and the thickness of the insulator. Both layers in the dielectric stack may have similar thickness variations that are likely to be a small element of either product used in the ratio.

The bandgap alignment layer may be an ultra thin film of the order of 10 nm, conveniently 5 nm, and preferably 3 nm or less.

Conveniently the insulator is a wide bandgap, and/or high dielectric constant material, such as Strontium Titanate SrTiO₃ preferably a Perovskite (general formula A²⁺B⁴⁺O₃) Hafnium oxide (HfO₂), Lanthanu sesquioxide, (La₂O₃), Zirconium oxide, (ZrO₂) are other examples of suitable materials. Preferably the insulator is transparent.

Preferably the insulator has a dielectric constant that is greater than, preferably twice or more, the dielectric constant of silicon dioxide. Such an insulator is generally known as a “high k” (or high dielectric constant) insulator.

Preferably the bandgap alignment layer has a dielectric constant that is similar to, or less than, that of silicon dioxide. Such a layer is generally known as a “low k” layer. Preferably the bandgap alignment layer has a bandgap energy larger than the transistor, and/or the materials it is trying to align with the gate insulator. Conveniently the bandgap energy is larger by at least substantially 1 eV above the conduction band and/or substantially 1 eV below the valence of the semiconductor

The transistor may comprise a growth layer adjacent the semiconductor. The growth layer is conveniently between the semiconductor and the substrate. The growth layer may be made of the same material as the bandgap alignment layer.

Suitable materials include wide bandgap dielectric materials such as the insulator silicon dioxide (conveniently SiO₂ that has a bandgap of 9 eV) or aluminium oxide (conveniently Al₂O₃ that has a bandgap of 8.8 eV)

The preferred structure for a surface or embedded transistor or other device/circuit build makes use of one or more of the following sequence of layers:
a liquid or vapour planarising polymer (if the substrate is not smooth enough after the laser mask removal process interacts with the exposed substrate surface)
an adhesion promoting inorganic coating or graded organic-inorganic nanocomposite (the latter used to achieve greater chemical interaction with the smoothing polymer or substrate polymer surface—hence greater adhesive bond strength)
an inorganic/organic-inorganic nanocomposite environmental barrier layer that alternates with a second inorganic coating/organic-inorganic nanocomposite layer to form a multilayer or quantum layer stack to provide effective oxygen/water vapour ingress resistance
terminating in an inorganic oxide coating that provides a controlled chemistry/morphology growth surface for the subsequent device build (specifically provides an oxide growth surface that can be equivalent to the low-k gate insulator that contacts the Semiconducting film in the thin film transistor fabrication).

The transistor may be transparent.

The transistor may comprise an adhesive layer between a substrate and the semiconductor. The transistor may comprise a barrier layer between a substrate and the semiconductor. The adhesive layer may also be the barrier layer and may serve as an inorganic material growth surface onto which the transistor is built-up.

According to a further aspect of this invention there is provided a semiconductor thin film switch comprising a layer of insulator sandwiched between two layers of metal. Preferably the switch is transparent. This aspect of the invention provides a non-linear resistance device for use with high capacitance pixels. The thin film multi-layer structure is relatively simple, and it may be manufactured cost-effectively. Having a transparent switch means that the whole aperture of a pixel may be used. The switch is conveniently a metal-insulator-metal (MIM) switch. Preferably the switch operates as a two-terminal capacitor or pin diode. Such a device is particularly suitable for applications that require no grey scale display processing.

According to a further aspect of this invention, there is provided a thin film transistor comprising gate source and drain electrodes, disposed in generally parallel trenches in a substrate. The transistor may comprise a single source (or drain) electrode having two adjacent gate electrodes. Two drain (or source electrodes) may be disposed adjacent the gate electrodes.

By means of this invention, an independently modifiable semiconductor contacting method is provided. With conventional thin film transistor technology, such as that termed amorphous silicon, a degenerately doped n⁺ amorphous silicon layer is interposed between the semiconducting film and the drain-source contacts in order to improve charge injection and removal characteristics—providing better ohmic contacts. Preferably independently accessible trenches or elongated containment wells are provided that means degenerate material can be deposited separately in each well. This removes the need to pattern such a layer as would be the case in the amorphous silicon device and provides for subtle adjustment of the contact interfacing material to improve the barrier height properties for each contact (source and drain) separately so as to optimise charge transfer behaviour.

The trenches may be laser etched, stamped, or embossed. The drain electrode(s) may be offset for high variable voltage output. The transistor may be source-gated for lower voltage higher gain operation.

According to a further aspect of this invention there is provided a thin film transistor comprising a stack comprising a gate electrode, a gate insulator and a semiconductor, the stack being disposed in a trench in a substrate. Preferably the gate electrode is laid down first, the gate insulator being the middle layer, and the semiconductor being laid down last. This is known as a “bottom gate” or inverse staggered design. The semiconductor layer may be wider than the other two layers. A drain electrode and source electrode may be disposed on the substrate, conveniently adjacent and/or below the semiconductor layer.

Preferably the transistor comprises a liquid supply reservoir, conveniently a single reservoir. The reservoir may be laser etched, stamped, or embossed. The reservoir may be processed in-situ, conveniently to minimise processing error. A profile, conveniently a cross-sectional profile of the reservoir may be shaped to control layer thickness and/or to cater for drop placement or volume errors. The reservoir may be fabricated in the peelable masking film. This provides a means of using conventional ink jet printhead technology with its inherent limitations in drop volume and drop placement accuracy (due to nozzle straightness and ejection cone angle errors) to provide a source of material that can be used in the building of a device. The geometry of the reservoir may take into account droplet damping and Tsunami wave splashing and spill-over to retain the ink in the reservoir. Preferably the entrance to central device trench has a lip edge height that controls the amount of reservoir liquid that can be fed into the trench. Such control may use a difference in the reservoir liquid height relative to a height of the lip edge that permits the liquid to enter the trench. Alternative versions of this reservoir include providing surface tension restrictor features that terminate the flow of liquid about a surface contact line and trench fill flow surface gradient on the basis of opposing surface tension forces for example one such feature may be in the reservoir pulling the liquid back and/or one such feature may be in the trench pulling liquid in.

Alternatively, independent reservoirs may be provided for the semiconductor, insulator and gate layers. The semiconductor, insulator and gate electrode layers may be auto-aligned. This provides a very flexible device design and manufacturing approach with minimisation of contact overlap, and thus parasitic capacitance and leakage current.

In a further preferred embodiment the semiconductor may be laid down first followed by the insulator and then the gate electrode. This is known as a “top gate” or staggered configuration design. Independent supply reservoirs may be provided for the semiconductor, insulator and gate electrode layers. Such reservoirs may be defined by laser etching directly into a masking film, preferably a peel-off masking film. This design provides a very flexible device design and manufacturing approach, is tolerant of large mask window positional error, and provides minimisation of contact overlap, and thus parasitic capacitance and leakage current. Accordingly, it is of assistance in increasing the performance of a liquid crystal display pixel.

According to another aspect of this invention there is provided a method of manufacturing microstructures comprising: applying a mask to a substrate to form a deposition area; forming a pattern in the mask; forming a reservoir for fluid in the deposition area; depositing material on the deposition area to form a microstructure; and removing the mask.

Methods in accordance with the invention may comprise forming a reservoir for fluid in the mask. The method may comprise forming two or more reservoirs for fluid in the mask. The volume of the reservoir may be of the order of 5 to 15 picolitres, conveniently of the order of 7 to 13 picolitres, preferably of the order of 9 to 11 picolitres, in a preferred embodiment substantially 10 picolitres.

Methods in accordance with the invention may comprise forming a reservoir for fluid in the substrate.

The volume of the reservoir may be of the order of 14 to 34 picolitres, conveniently of the order of 19 to 29 picolitres, preferably of the order of 23 to 25 picolitres, in a preferred embodiment substantially 24 picolitres.

The method may comprise depositing a fluid in at least one of the reservoirs. The method may comprise depositing a second fluid in at least one of the reservoirs. The method may comprise that the fluid is or fluids are deposited by ink jet printing. The method may comprise depositing fluid onto the substrate from at least one of the reservoirs. The method may comprise forming an interconnecting duct between a reservoir and desired deposition site. The method may comprise controlling the height of the reservoir

According to a further aspect of this invention, there is provided a method of manufacturing an array of isolated semiconductor devices on a common substrate and connecting some of the devices. Preferably the devices are functionally equivalent.

All of the previous features described also apply to the array of isolated semiconductors aspect of the invention, as well, of course, as to any other aspect of the invention.

The array (regular or irregular), including the devices formed thereon, may be opaque, translucent, or transparent. The array may be regular, by which is meant that the array comprises a plurality of rows and columns which are substantially equally spaced apart. The array may be three-dimensional. The array may comprise a flexible substrate.

Further aspects of the invention include its applicability to the production of many other types of microstructures for example microelectronic, opto-electronic and photonic devices and circuits.

Other applications include display panel switching backplanes, intelligent touchscreens, large area sensor arrays, bioelectronic sensors, opto-electronic and optical waveguides, radio-frequency identification circuits, MEMS devices, MOEMS devices, fluidic actuators, digital print heads, integrated ferroelectrics, microelectronic ceramic packaging.

According to a further aspect of the invention there provided a method of manufacturing a flexible conductor comprising a series of sections and gaps, wherein individual conductors are joined by means of a flexible link.

The flexible link may be constructed from PEDOT-PSS, nanoparticle conductive ink, high purity carbon nanoparticle conductive composites, and/or other conducting nanocomposites, and may be applied by means of a direct write technique.

Preferably, the flexible conductor will comprise an insulating layer, where appropriate, to allow overlap with other conductors.

Further aspects of the invention include its applicability to the production of many other types of microstructures for example microelectronic, opto-electronic and photonic devices and circuits.

Methods in accordance with the invention provide a manufacturing process which provides self-aligning structures and fault tolerant processing and the production of high precision devices from low precision processing. This invention permits the manufacture of high performance devices based on a highly flexible production strategy that permits a wide selection of wet and dry processes to be mixed and/or matched. Such cost and performance selective manufacturing uses simple position-tolerant feature patterning.

The further disclosed invention is a flexible conductor comprising a series of sections and gaps, wherein individual conductors are joined by means of a flexible link.

The selectable interconnect array integrated circuit provides for high resolution patterns using a high tolerance pattern alignment process.

This invention provides a concept for a universal device platform that can be used for a variety of applications, allowing for the inclusion of a set of components such as resistors, capacitors, transistors, diodes and contact pads. These may be defined as a “unit repeat cell” which may be repeat patterned onto selected substrate media to form a “universal device platform array”. This invention may thereby provide a set of components that can be so interconnected to provide many different applications and built-in component redundancy in each unit repeat cell.

The manufacturing process provides self-aligning structures and fault tolerant processing, and the production of high precision devices from low precision processing. It is particularly suited for energy efficient logic processing circuits.

This manufacturing process enables the use of a wide range of liquid, vapour, and solid particle processes to provide a very wide range of materials that permits the construction of all-inorganic, all-organic or hybridised inorganic-organic devices even mixing liquid, vapour and solid particle processes in one manufacturing sequence.

The manufacturing process enables “Cassette-to-Cassette Manufacturing” of semiconductor devices, using a cassette transport system for a roll of substrate material such that the cassette is inserted into a lamination machine. The cassette may then be processed further in subsequent manufacturing steps.

The invention extends to methods and/or apparatus substantially as herein described with reference to the accompanying drawings.

Any feature according to any one aspect or preferred feature of the invention may be applied to other aspects of the invention, in any appropriate combination. In particular, method aspects may be applied to apparatus aspects, and vice versa.

Any of the methods or apparatus, masks and substrates and sealing films outlined above may be of use in the manufacture of any of the devices outlined above. Preferred features described above in relation to any aspect of the invention may be combined with a different aspect of the invention, or provided independently.

In the drawings:

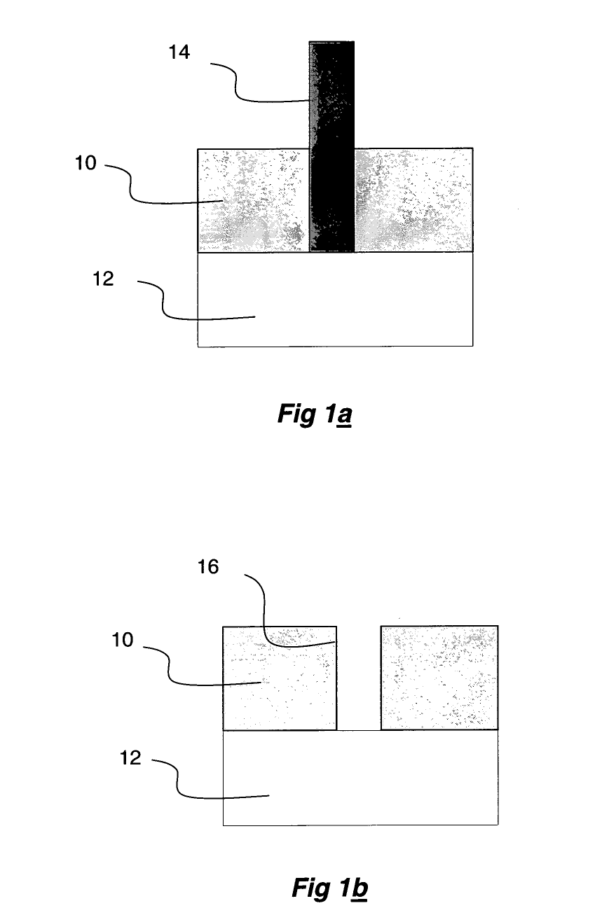

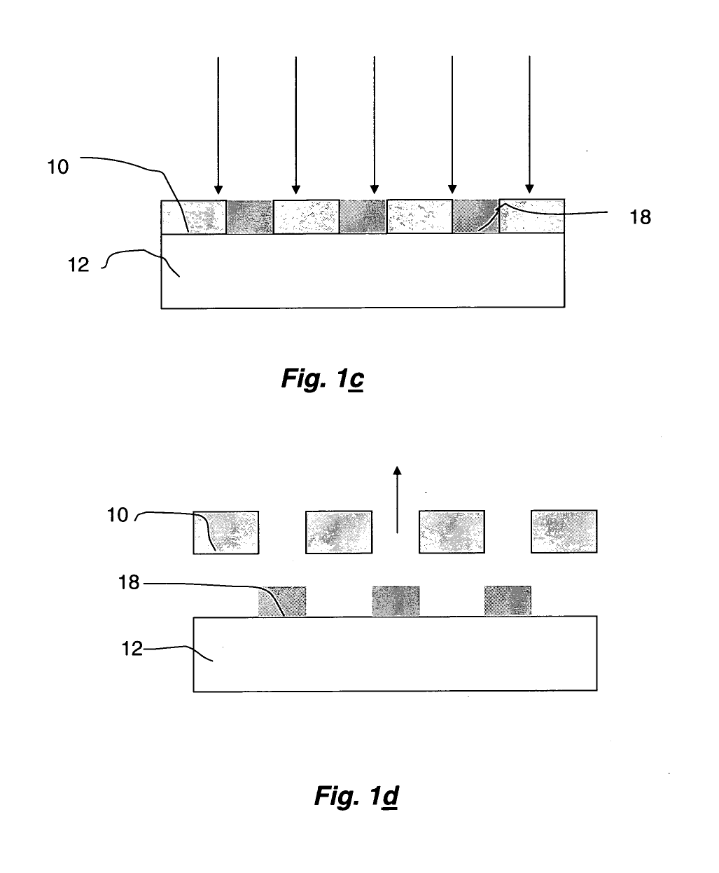

FIG. 1 shows schematically a number of stages in an embodiment of a process using a peelable mask;

FIG. 1a shows schematically a pattern being formed in the mask by a laser beam;

FIG. 1b shows schematically a trench so formed;

FIG. 1c shows schematically a plurality of trenches having material deposited therein; and

FIG. 1d shows schematically removing the mask;

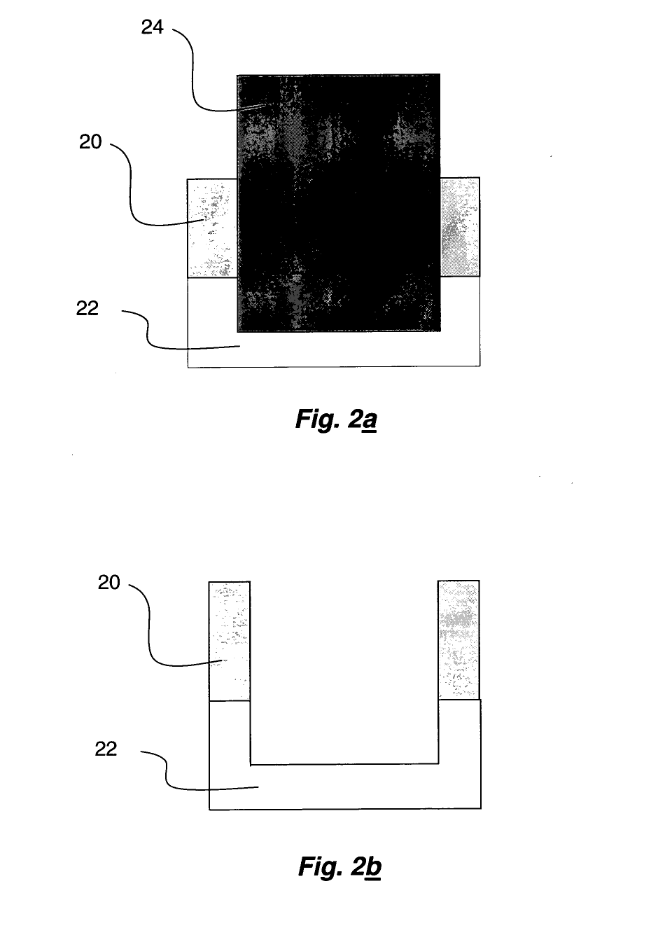

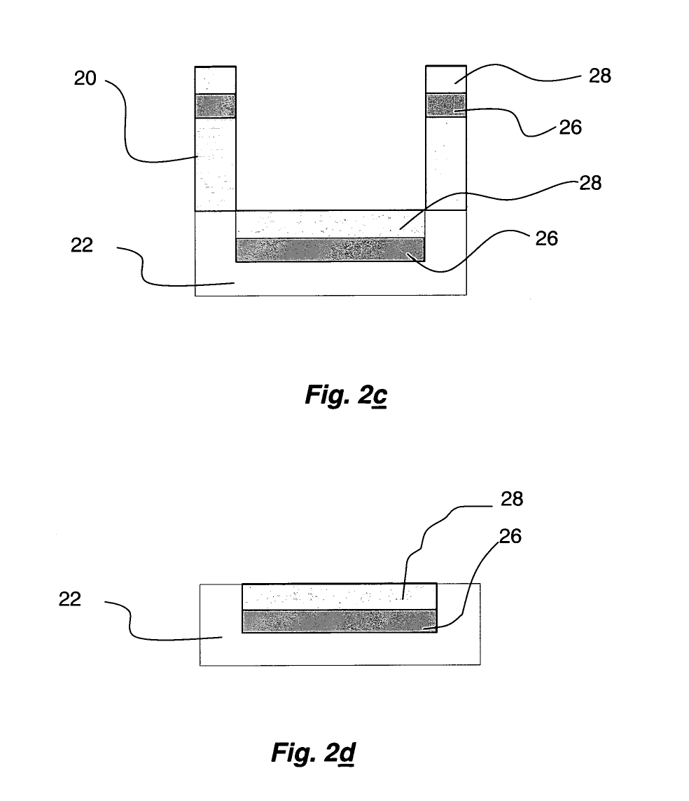

FIG. 2 shows schematically a number of stages in an embodiment of a process using a peelable mask;

FIG. 2a shows schematically a process of forming a trench in a mask and a substrate using a laser beam;

FIG. 2b shows schematically a trench so formed;

FIG. 2c shows schematically material deposited on the substrate; and

FIG. 2d shows schematically the substrate with the mask removed;

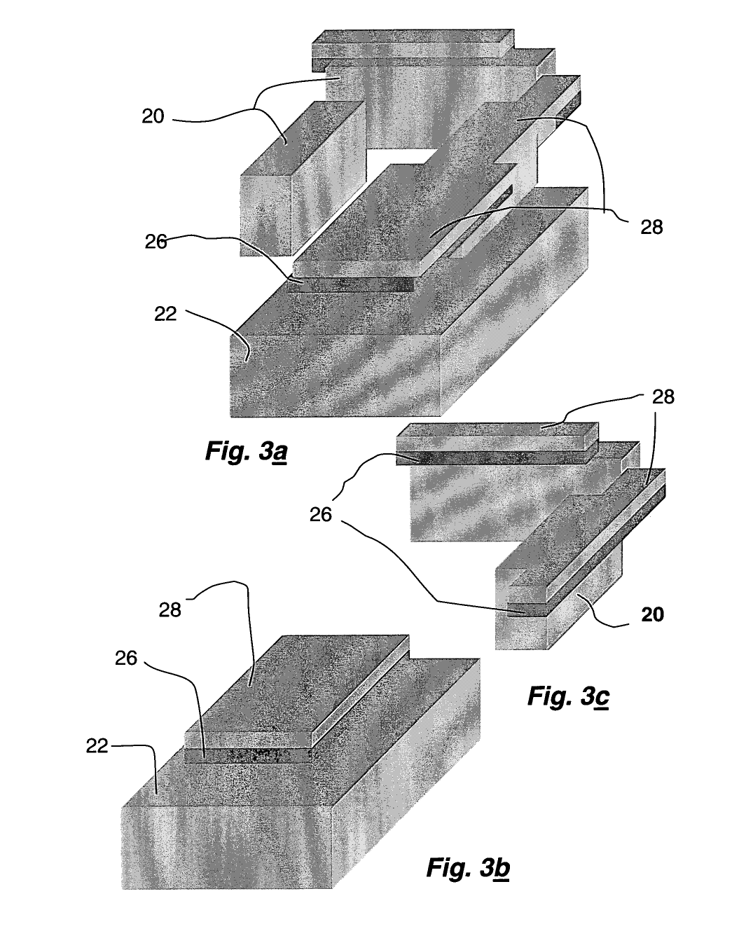

FIG. 3 shows schematically a number of perspective views of a structure formed by the process shown in FIG. 2;

FIG. 3a shows schematically a first structure;

FIG. 3b shows schematically a second structure, having had waste material removed; and

FIG. 3c shows schematically removed waste material;

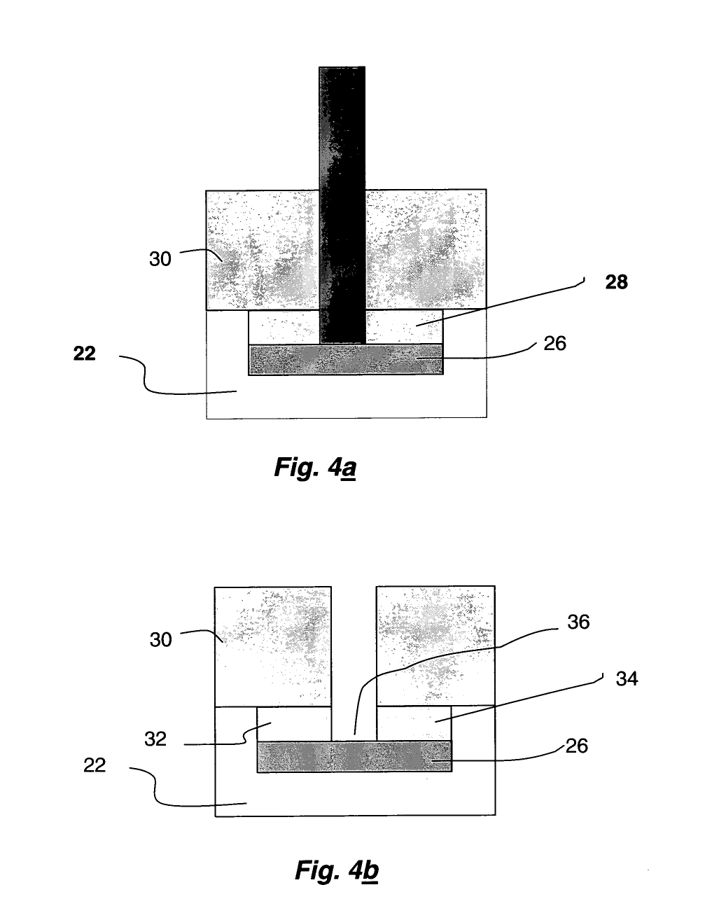

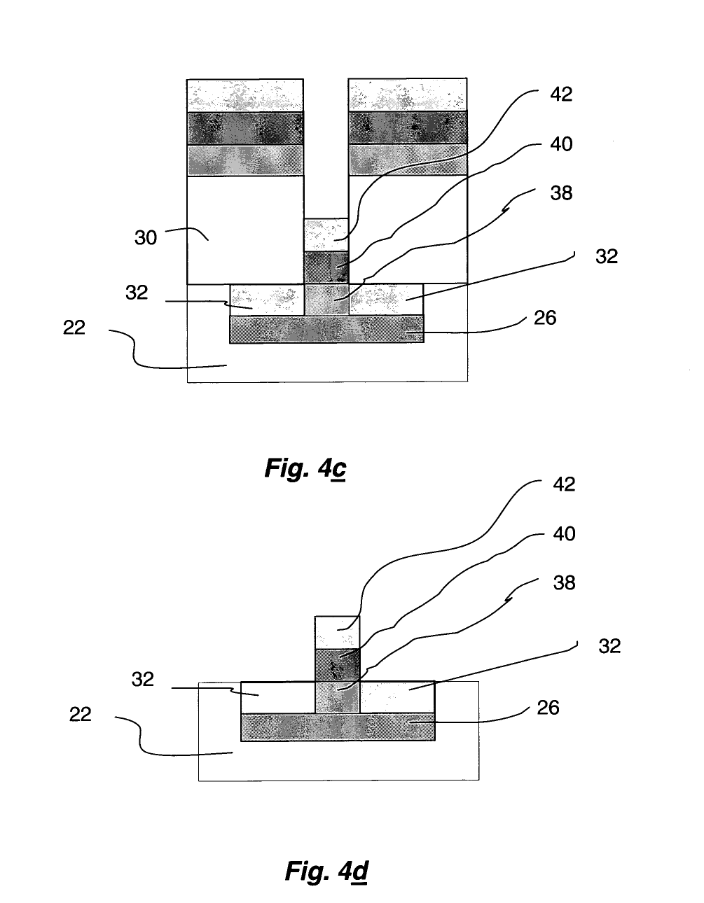

FIG. 4 shows schematically a number of stages in an embodiment of a process using a peelable mask;

FIG. 4a shows schematically etching of the mask and material;

FIG. 4b shows schematically a trench formed in the mask and material;

FIG. 4c shows schematically a structure after a number of layers have been deposited; and

FIG. 4d shows schematically a structure having had the peelable mask removed;

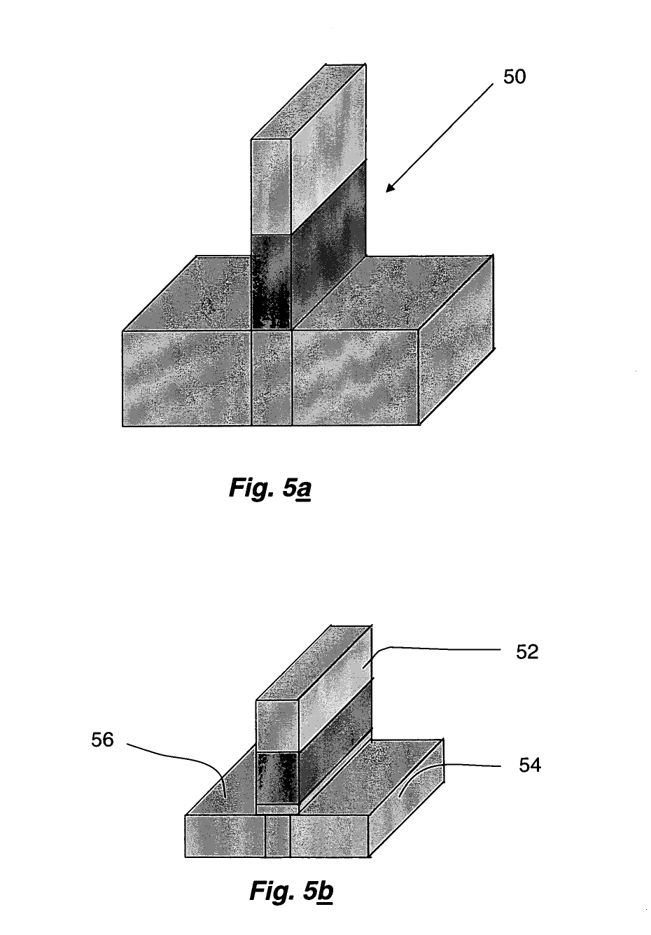

FIG. 5 shows schematically a number of perspective views of transistors;

FIG. 5a shows schematically a perspective view of a transistor formed by the process shown in FIG. 4; and

FIG. 5b shows schematically a perspective view of a prior art transistor;

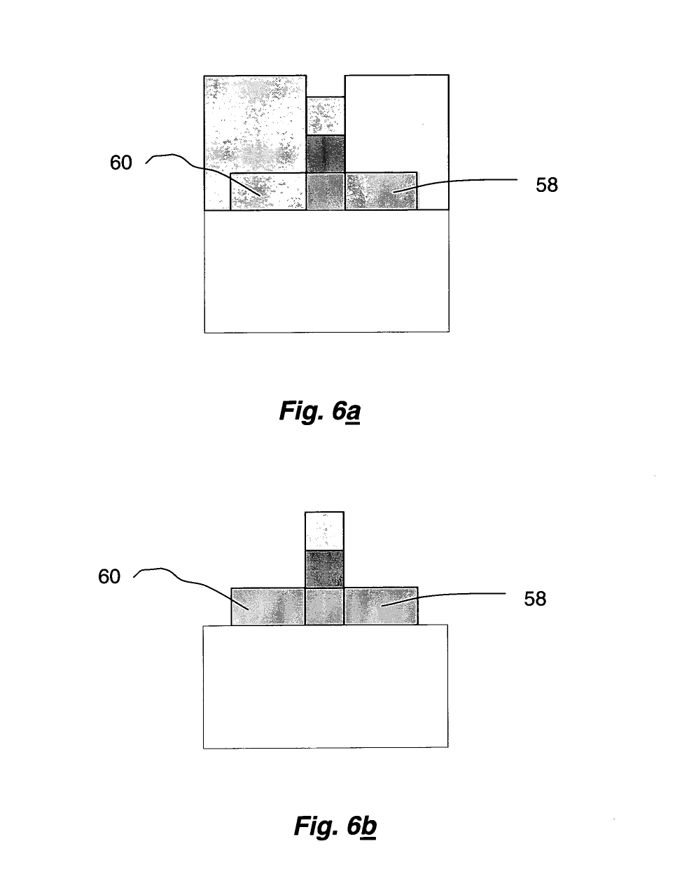

FIG. 6 shows schematically a further embodiment of a process using a peelable mask;

FIG. 6a shows schematically the mask in place; and

FIG. 6b shows schematically a structure having had the mask removed;

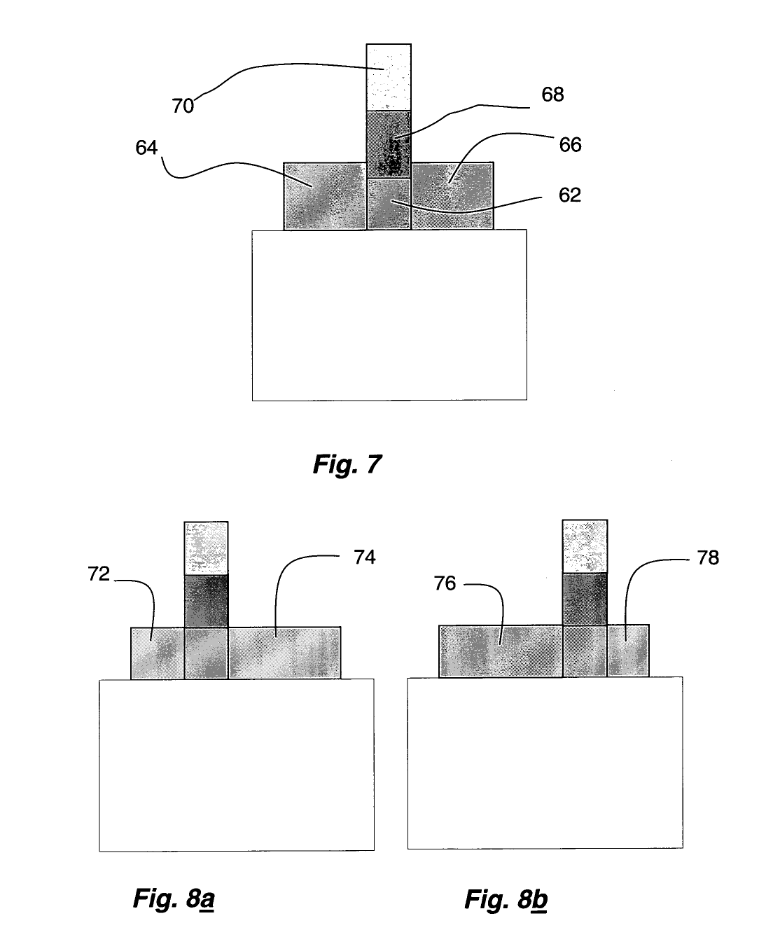

FIG. 7 shows schematically a structure formed from a similar process as that shown by FIG. 6, having slightly different scaling;

FIGS. 8a and 8b show two further different embodiments of transistors made by the process shown in FIG. 6, illustrating flexibility of positioning;

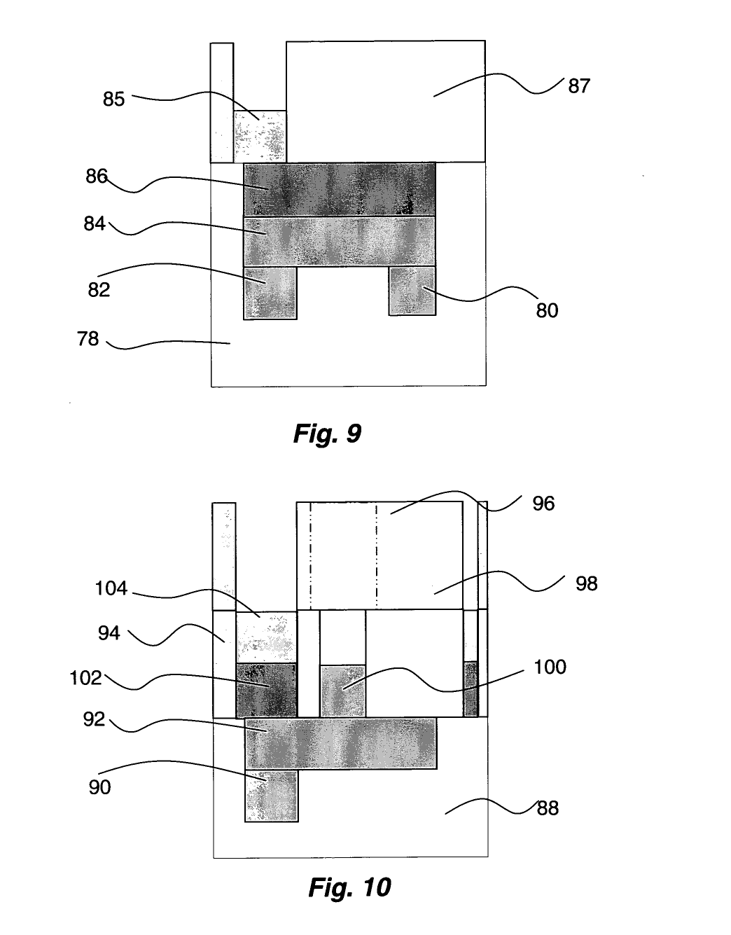

FIG. 9 shows schematically an example of a drain offset thin film transistor being manufactured using a peelable mask process;

FIG. 10 shows schematically an example of a source-gated thin film transistor being manufactured by a dual peelable mask process;

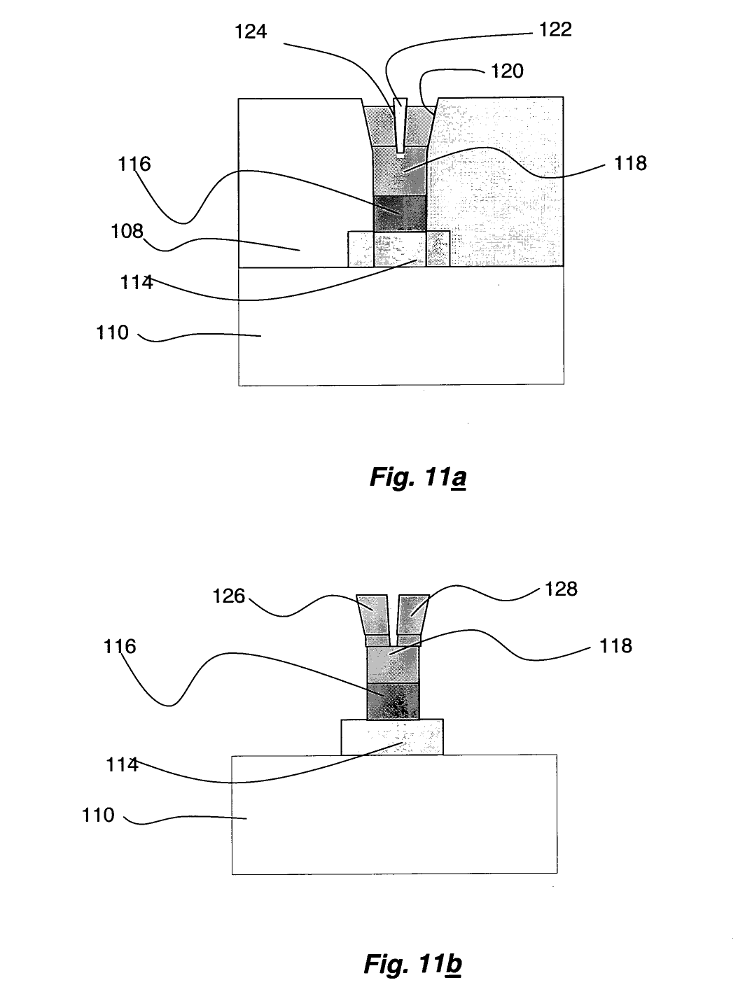

FIG. 11 shows schematically an example of an auto-aligned bottom gate thin film transistor, manufactured using a peelable mask process;

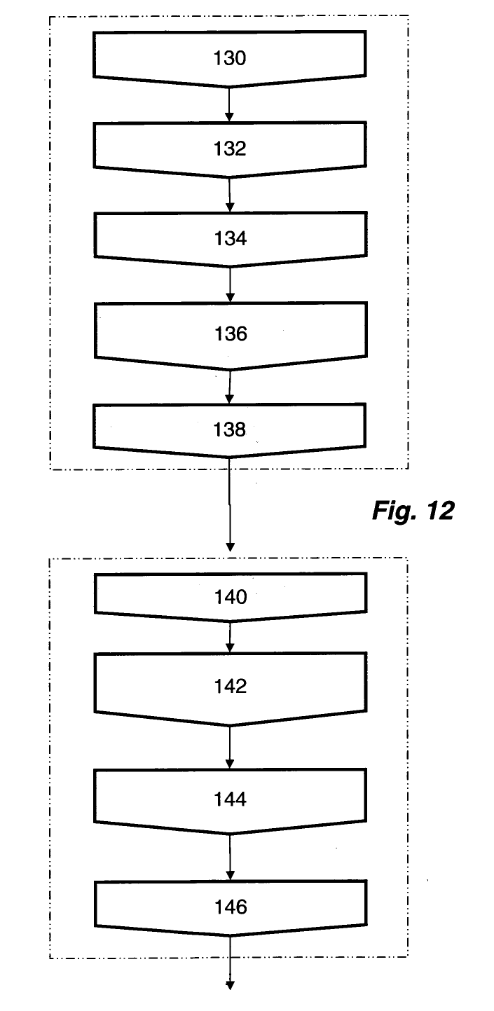

FIG. 12 shows schematically a flow diagram of an embodiment of a method of manufacture;

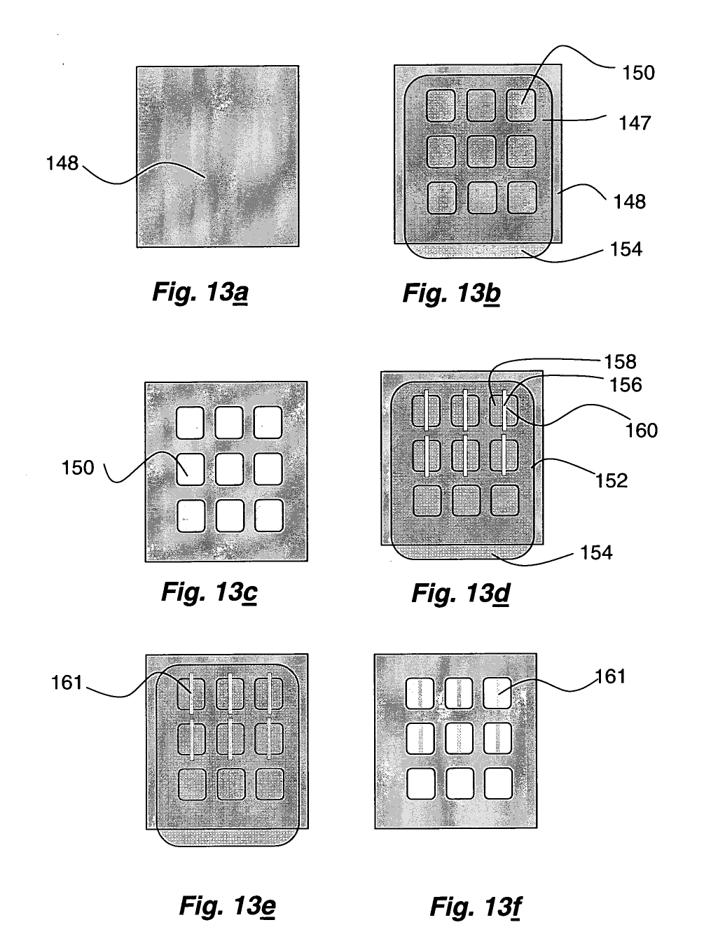

FIG. 13 shows schematically a number of cross-sections of stages in a fabrication process using a peelable mask:

FIG. 13a shows schematically a substrate for the process;

FIG. 13b shows schematically a structure after a sputtering stage;

FIG. 13c shows schematically the structure after a peelable mask has been applied;

FIG. 13d shows schematically the structure having undergone laser etching;

FIG. 13e shows schematically the structure after a deposition step; and

FIG. 13f shows schematically the structure after peeling off the mask;

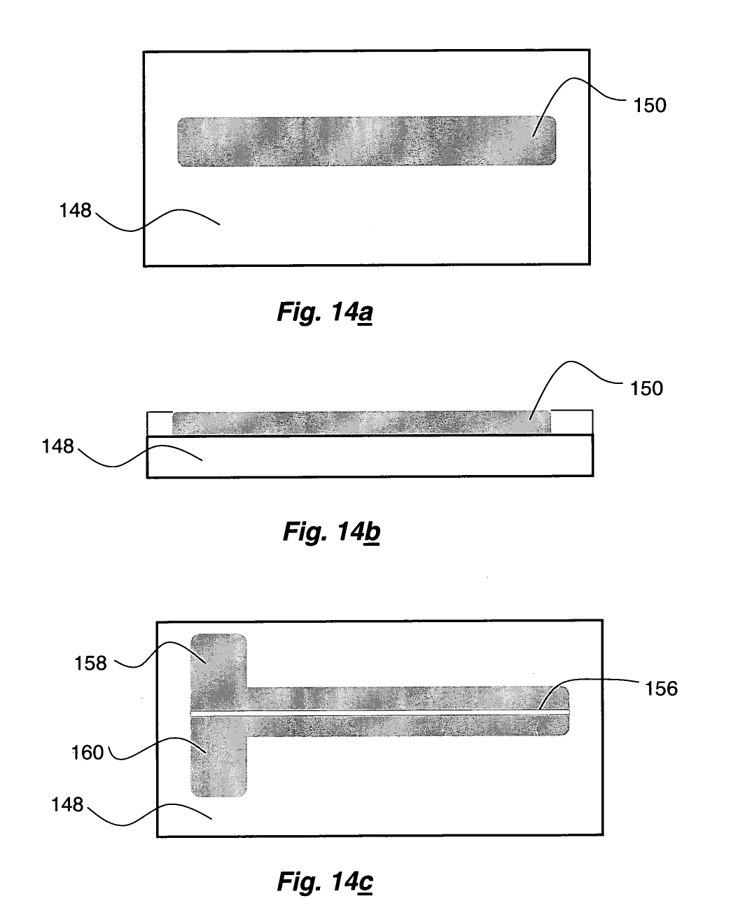

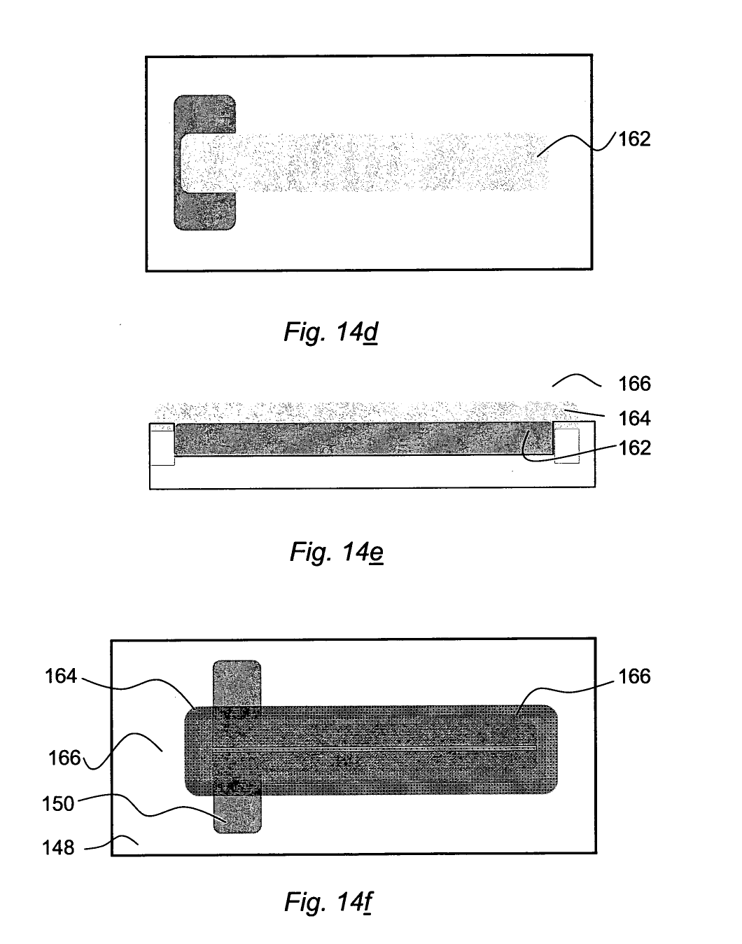

FIG. 14 shows schematically a number of top views and corresponding cross-sections in a fabrication process using a peelable mask:

FIG. 14a shows schematically a top view of a printed structure;

FIG. 14b shows schematically a cross-section of a printed structure;

FIG. 14c shows schematically a top view of the structure after an etching step;

FIG. 14d shows schematically a top view of the structure after a number of deposition steps;

FIG. 14e shows schematically a cross-section through FIG. 14d; and

FIG. 14f shows schematically a top view of the structure after further deposition steps;

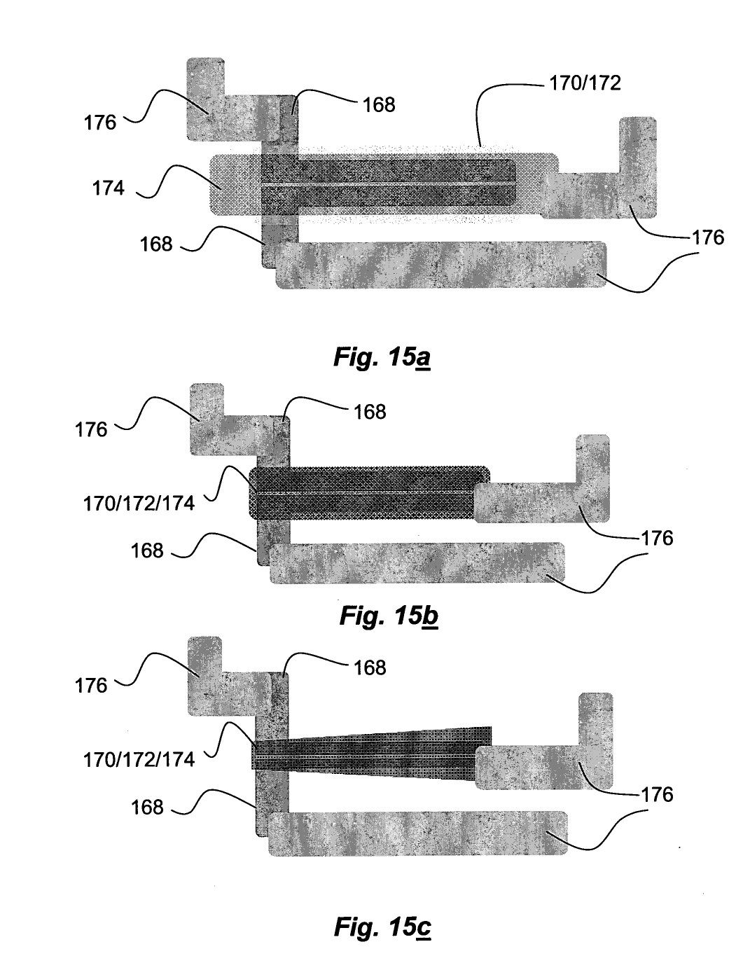

FIG. 15 shows schematically top views of different structures:

FIG. 15a shows schematically a top view of a bi-layer structure;

FIG. 15b shows schematically a top view of a tri-layer structure; and

FIG. 15c shows schematically a top view of a tri-layer structure having an alternate shape;

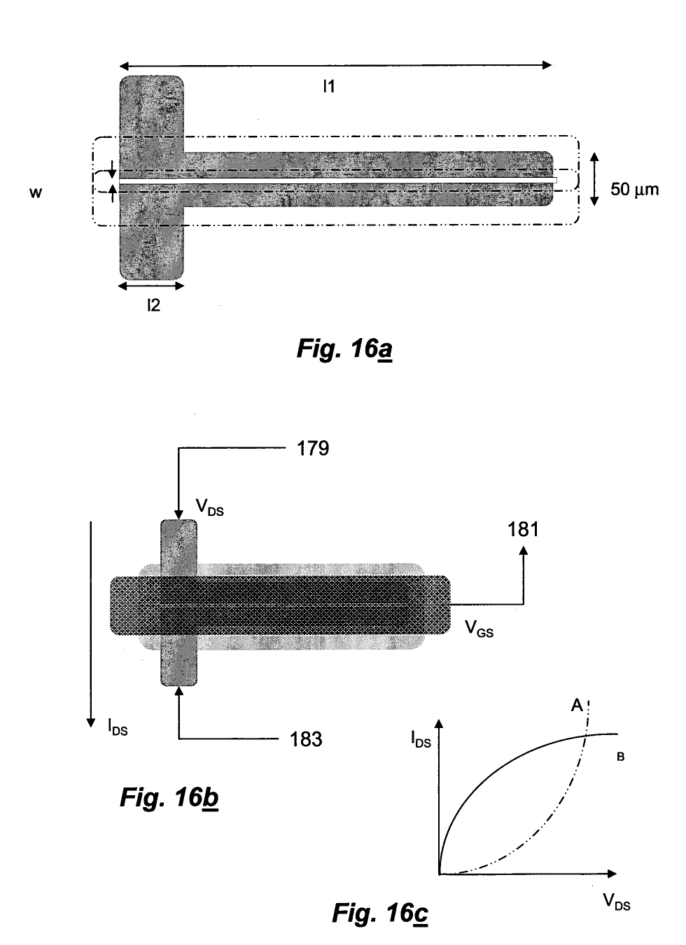

FIG. 16a shows schematically a view of FIG. 14c with indication of alignment tolerances; FIG. 16b shows schematically relevant voltages and currents in a transistor; and FIG. 16c shows schematically a graph of these;

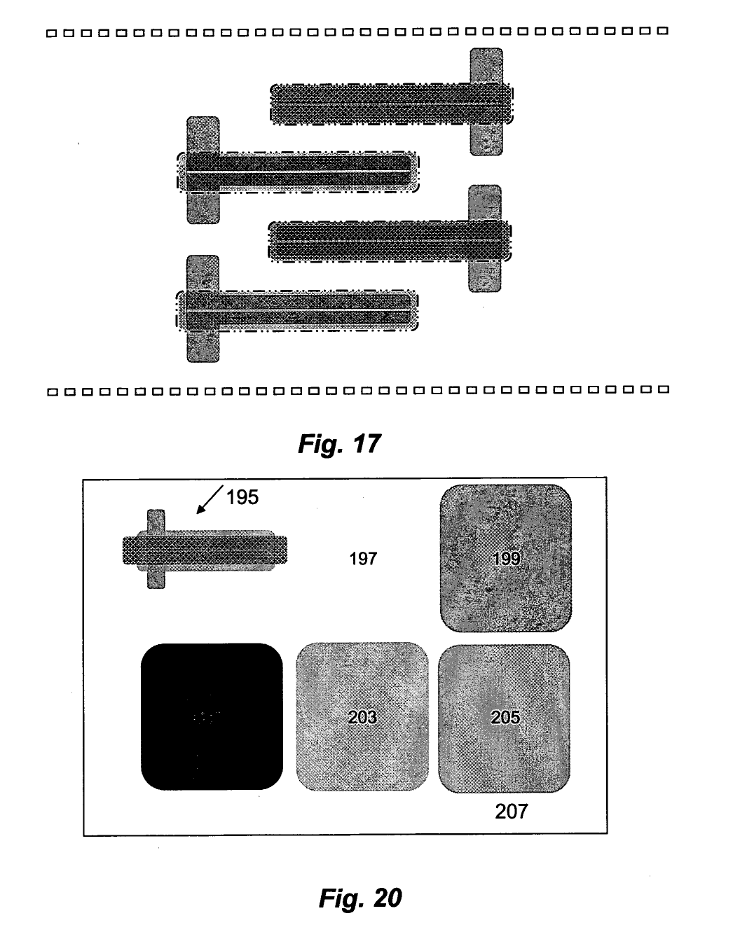

FIG. 17 shows schematically a view of a peelable mask having alignment markings;

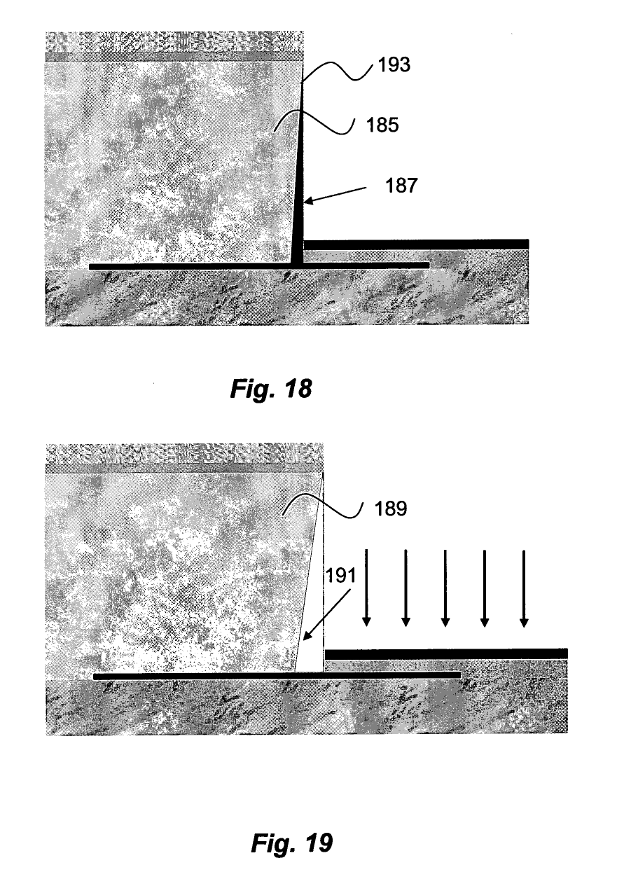

FIG. 18 shows schematically a cross-section through a peelable mask, the peelable mask having a straight edge;

FIG. 19 shows schematically a cross section through a peelable mask during a fabrication process, the peelable mask having an undercut edge;

FIG. 20 shows schematically a test pad for optical transmission analysis;

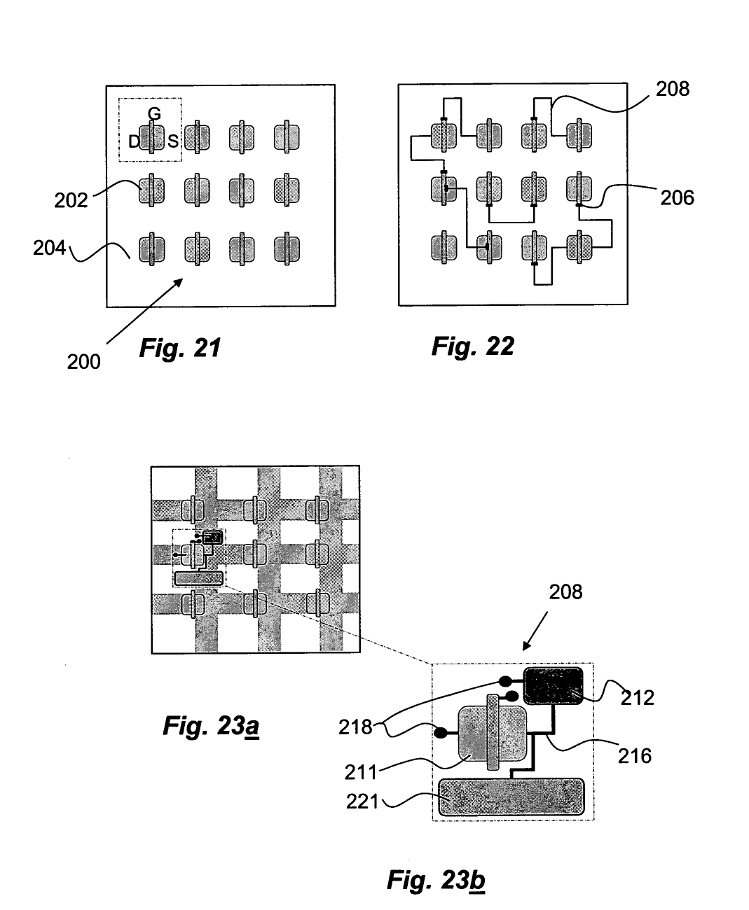

FIG. 21 shows schematically an embodiment of an array of semiconductor devices;

FIG. 22 shows schematically an embodiment of an integrated circuit comprising the array of FIG. 21;

FIG. 23 shows schematically views of a further example of an integrated circuit comprising the array of FIG. 16, and making up a display;

FIG. 23a shows schematically an overview of the array; and

FIG. 23b shows schematically a single pixel;

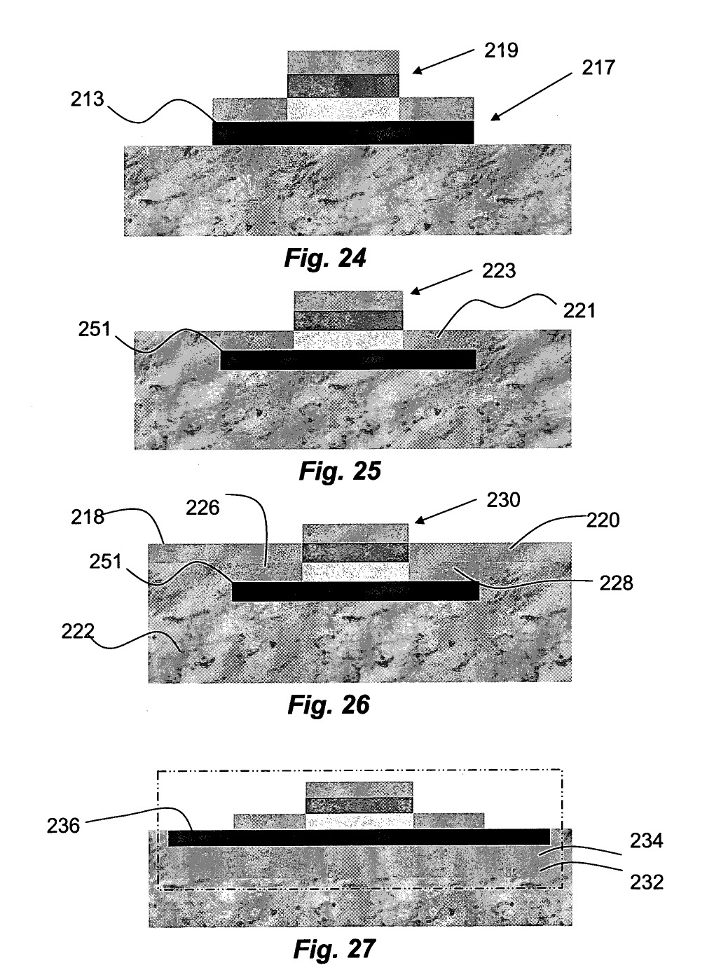

FIG. 24 shows schematically a cross-section through a transistor having an environmental barrier;

FIG. 25 shows schematically a cross-section through a transistor having a sub-surface deposited environmental barrier;

FIG. 26 shows schematically a cross-section through an addressable transistor having printed gate and data bus lines;

FIG. 27 shows schematically a cross-section through a transistor which comprises a single pixel element of a display;

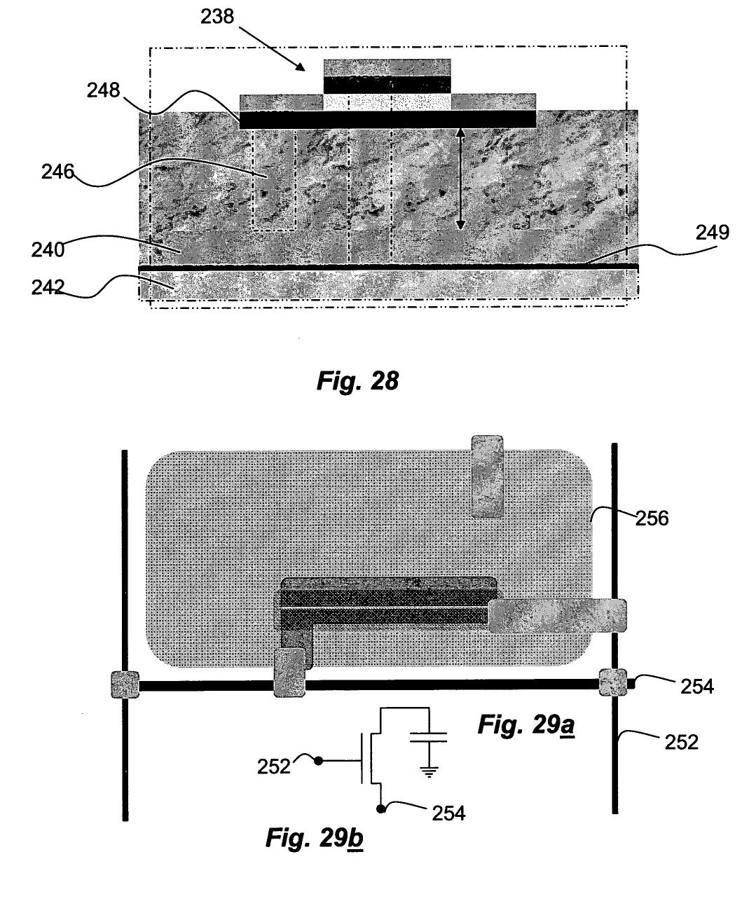

FIG. 28 shows schematically a cross-section through a further transistor which comprises a single pixel element of a display;

FIG. 29 shows schematically views of a further structure which includes a pixel element of a display:

FIG. 29a shows schematically a top view; and

FIG. 29b shows schematically an electrical diagram;

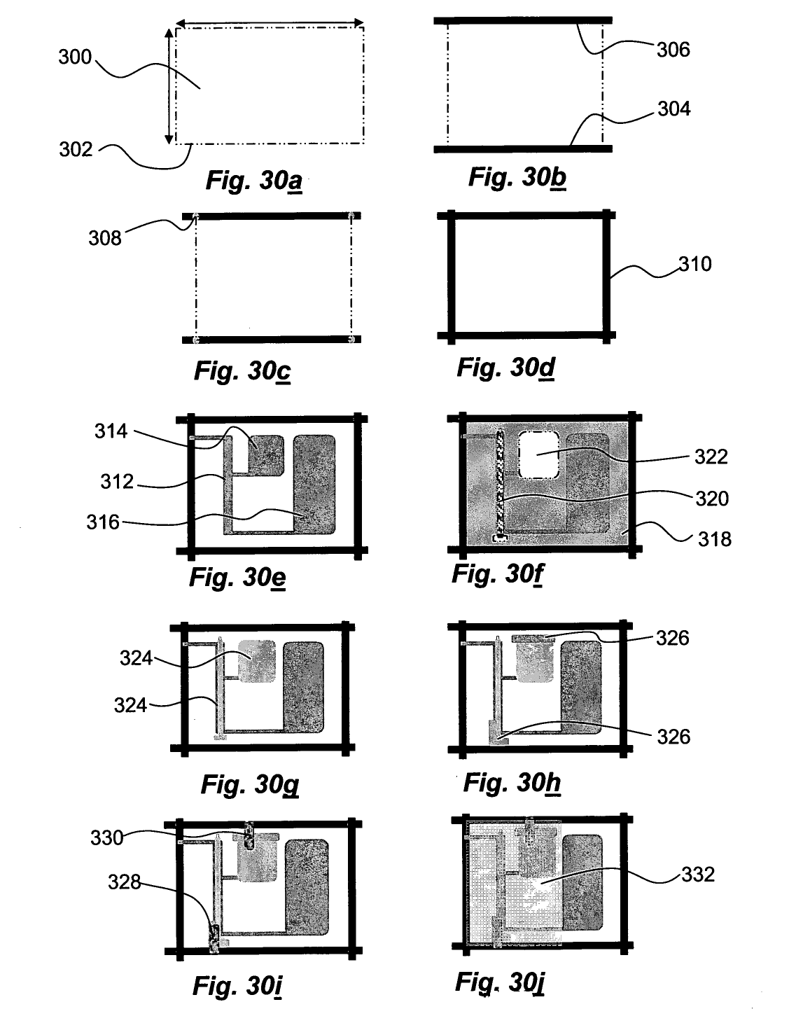

FIG. 30 shows schematically views of a structure during the process of manufacturing a display;

FIG. 30a shows schematically a substrate;

FIG. 30b shows schematically a substrate with deposited electrodes and bus lines;

FIG. 30c shows schematically addition of interlayer isolation;

FIG. 30d shows schematically addition of data bus lines;

FIG. 30e shows schematically deposition of contact pads;

FIG. 30f shows schematically deposition of a masking film;

FIG. 30g shows schematically deposition of a semiconductor, a gate insulator and a gate metal;

FIG. 30h shows schematically deposition of printed edge insulation land;

FIG. 30i shows schematically printing of a gate bus line and a storage capacitor; and

FIG. 30j shows schematically printing of interlayer insulation;

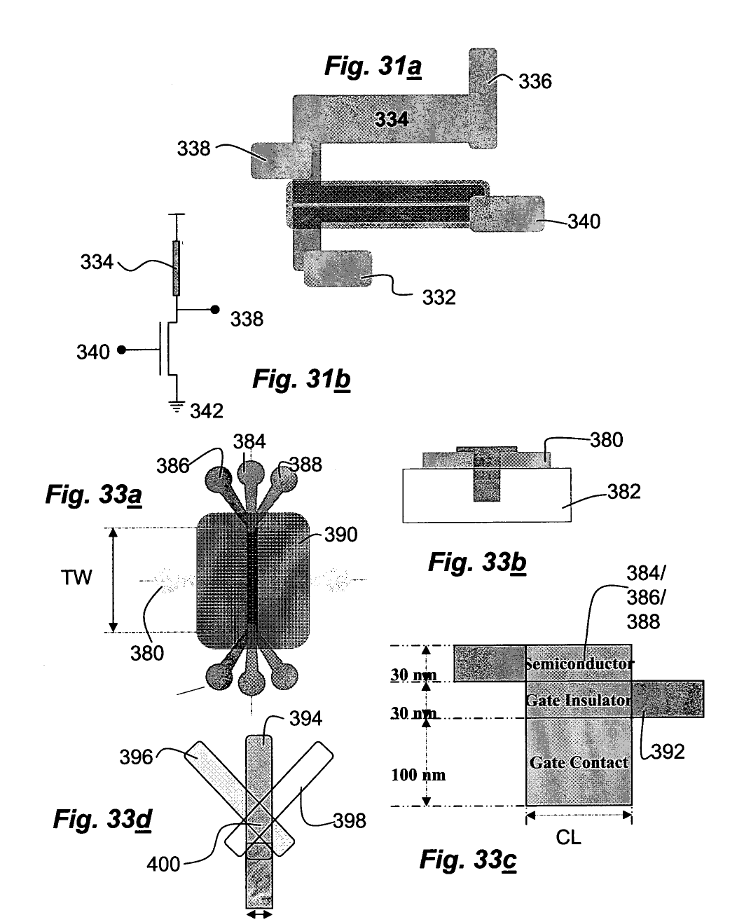

FIG. 31 shows schematically views of a further structure in a further application:

FIG. 31a shows schematically a top view; and

FIG. 31b shows schematically an electrical diagram;

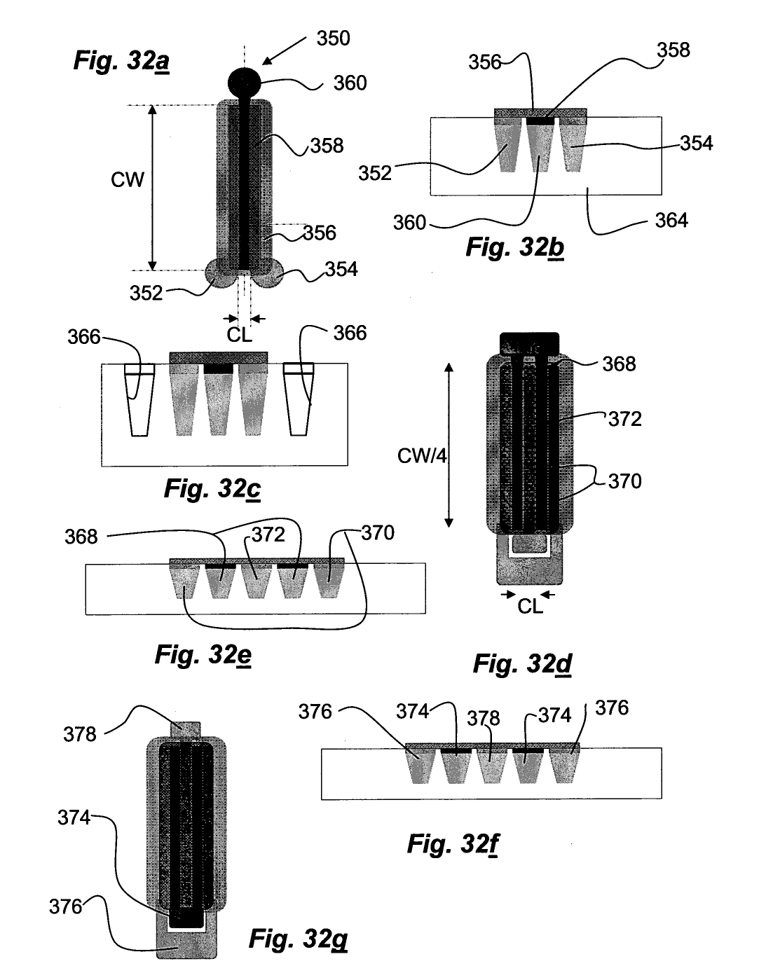

FIG. 32 shows views of an embodiment of co-planar in-line structures produced by a fabrication process:

FIG. 32a shows schematically a top view of a structure during the process; FIG. 32b shows schematically a cross section through FIG. 32a;

FIG. 32c shows schematically a top view of a further structure, having a dual gate-drain;

FIG. 32d shows schematically a cross-section through FIG. 32c;

FIG. 32e shows schematically a top view of a further dual gate-drain structure; and

FIG. 32f shows schematically a cross section through FIG. 32e;

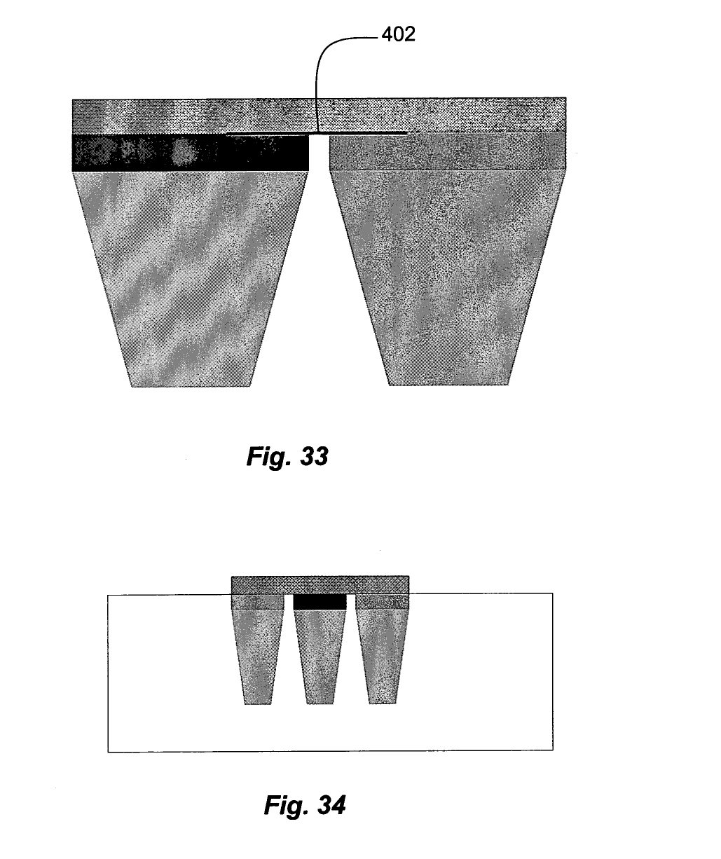

FIG. 33 shows schematically a cross-section through deposited elements of a thin film transistor, indicating a bandgap alignment layer;

FIG. 34 shows schematically a cross-sectional view of a structure;

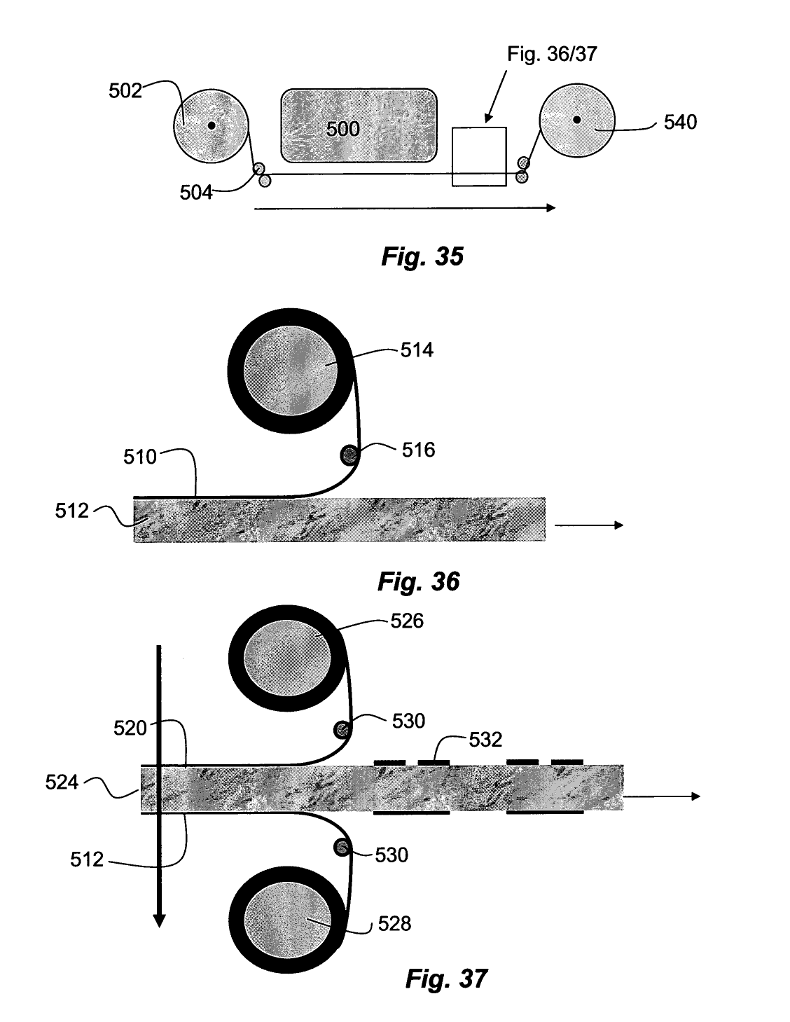

FIG. 35 shows schematically an embodiment of apparatus for roll-to-roll processing;

FIGS. 36 and 37 shows schematically embodiments of apparatus for removing a mask;

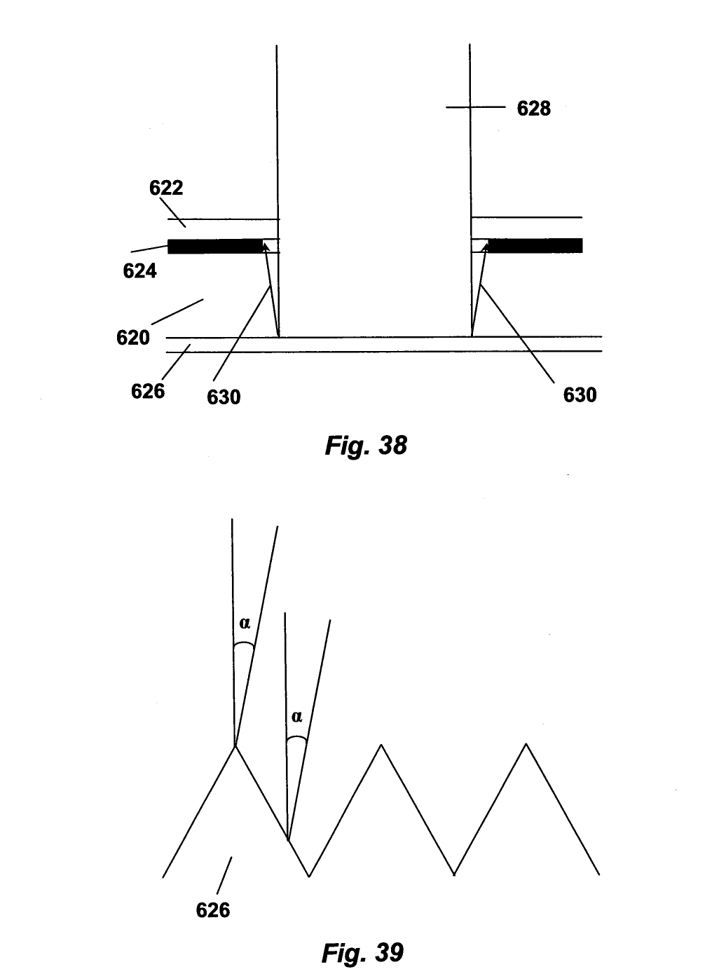

FIG. 38 shows schematically a cross section through a peelable mask undergoing etching with adhesive bond line removal;

FIG. 39 shows schematically a surface of a reflective film;

FIG. 40 shows schematically an undercut peelable mask;

FIG. 41 shows schematically a type of structure which may be produced using variable angle deposition;

FIG. 42 shows schematically a type of structure which may be produced using variable angle deposition;

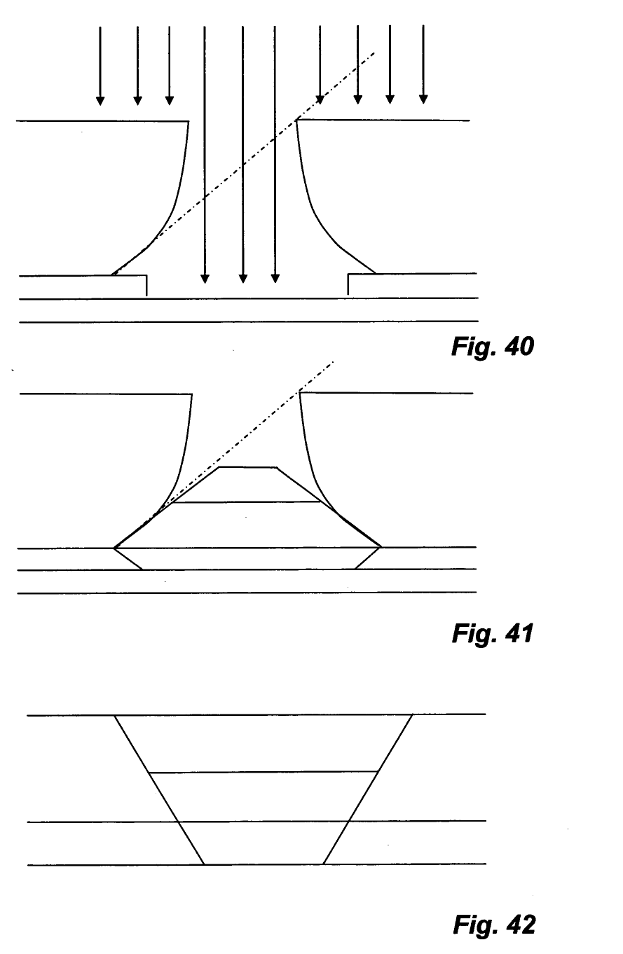

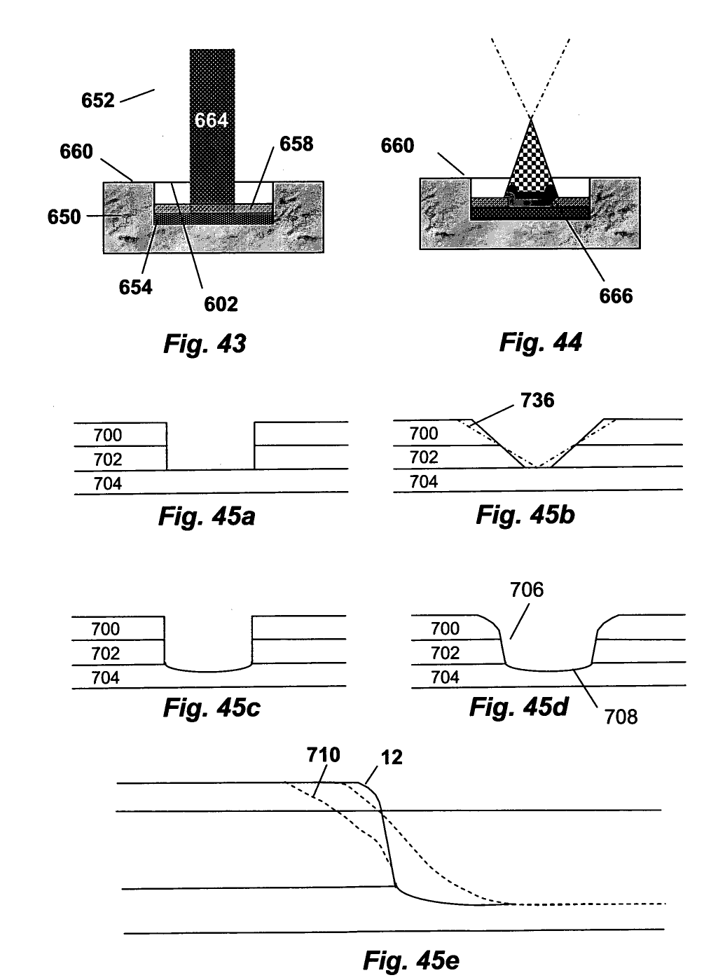

FIG. 43 shows schematically etching substances deposited in a well; and

FIG. 44 shows schematically depositing substances in a well through an etched undercut film;

FIG. 45 shows schematically different types of trench profile that may be produced by a laser beam:

FIG. 45a shows schematically a straight-sided trench;

FIG. 45b shows schematically a “V” trench;

FIG. 45c shows schematically a “U” trench;

FIG. 45d shows schematically a variable sided trench; and

FIG. 45e shows schematically a wall of a variable sided trench in more detail;

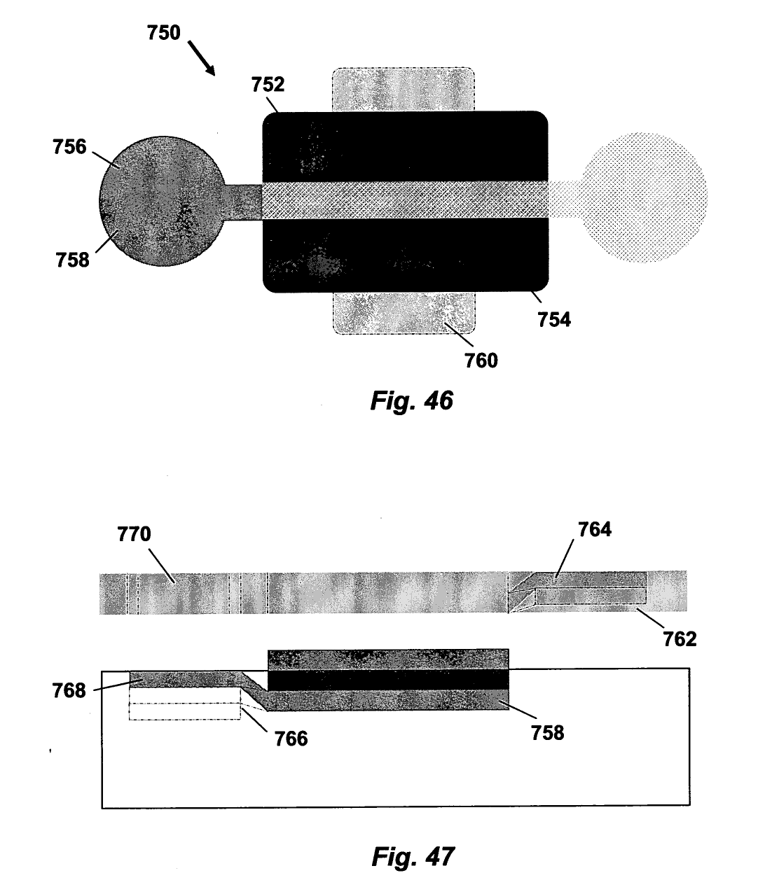

FIG. 46 shows schematically a transistor with reservoirs;

FIG. 47 shows schematically a transistor and peelable film, both having reservoirs;

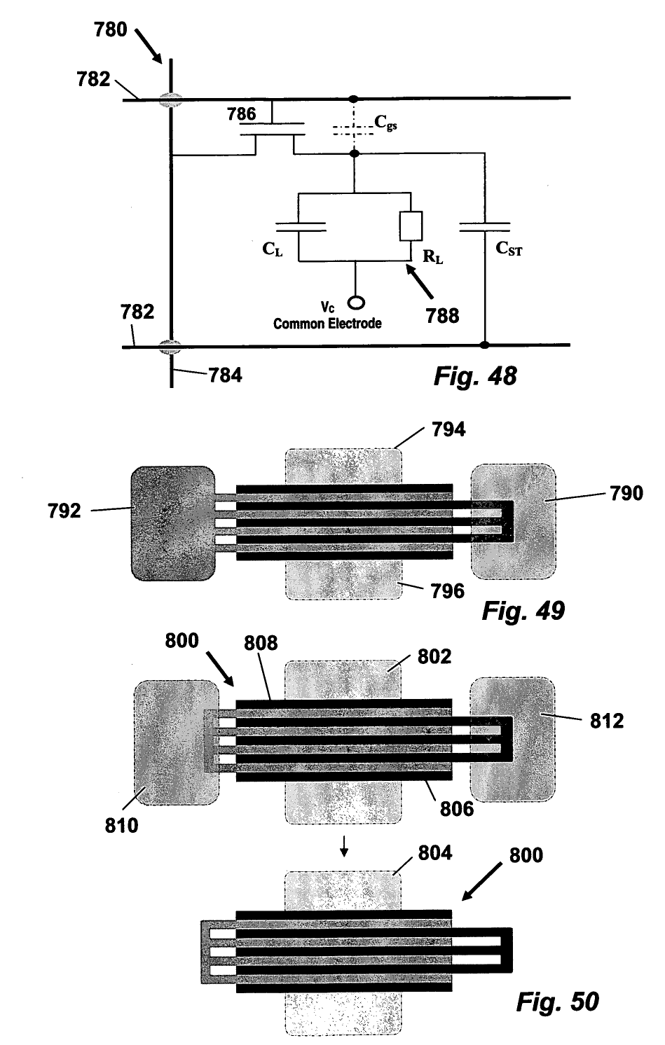

FIG. 48 shows schematically a circuit diagram for a single pixel of a structure;

FIG. 49 shows schematically a top view of a structure having a removeable reservoir;

FIG. 50 shows schematically views of a further structure having two removeable reservoirs:

FIG. 50a shows the structure with reservoirs;

FIG. 50b shows the structure with the reservoirs removed;

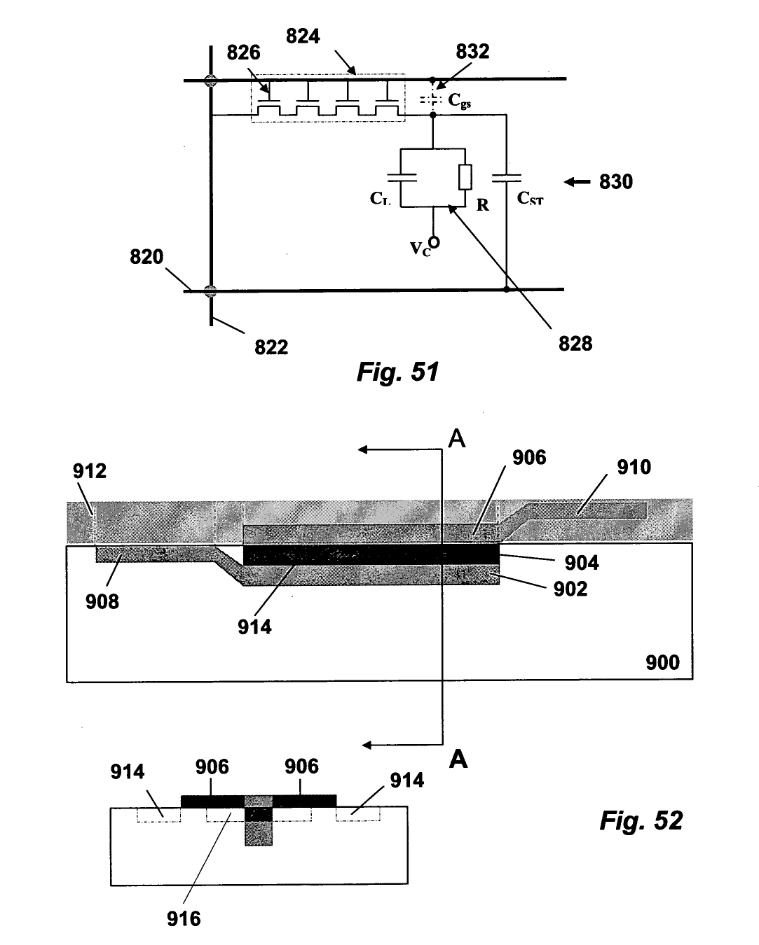

FIG. 51 shows schematically a circuit diagram for a structure;

FIG. 52 shows schematically views of a structure:

FIG. 52a shows schematically a structure and peelable film with reservoirs; and

FIG. 52b shows schematically a cross-section through FIG. 52a;

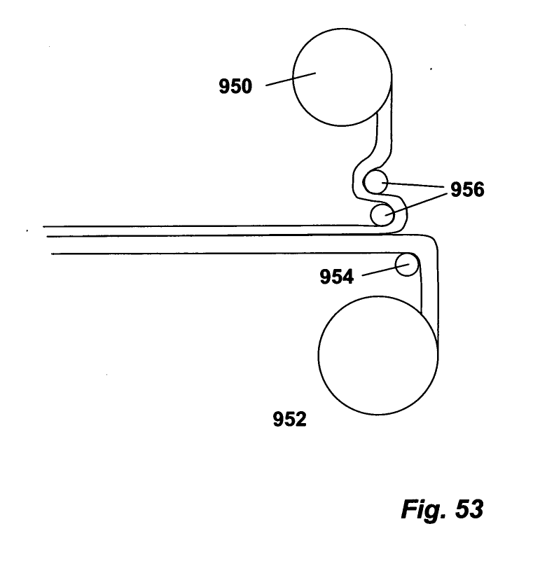

FIG. 53 shows schematically roller apparatus for peeling off a masking film;

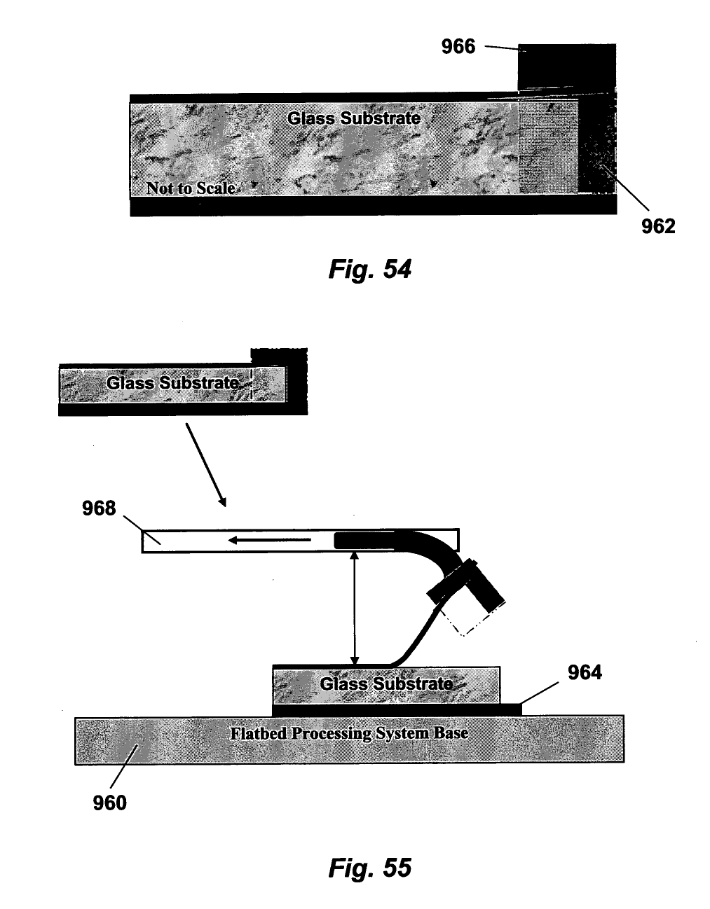

FIG. 54 shows schematically flatbed apparatus for peeling off a thin film; and FIG. 55 shows schematically flatbed apparatus for peeling off a thin film.

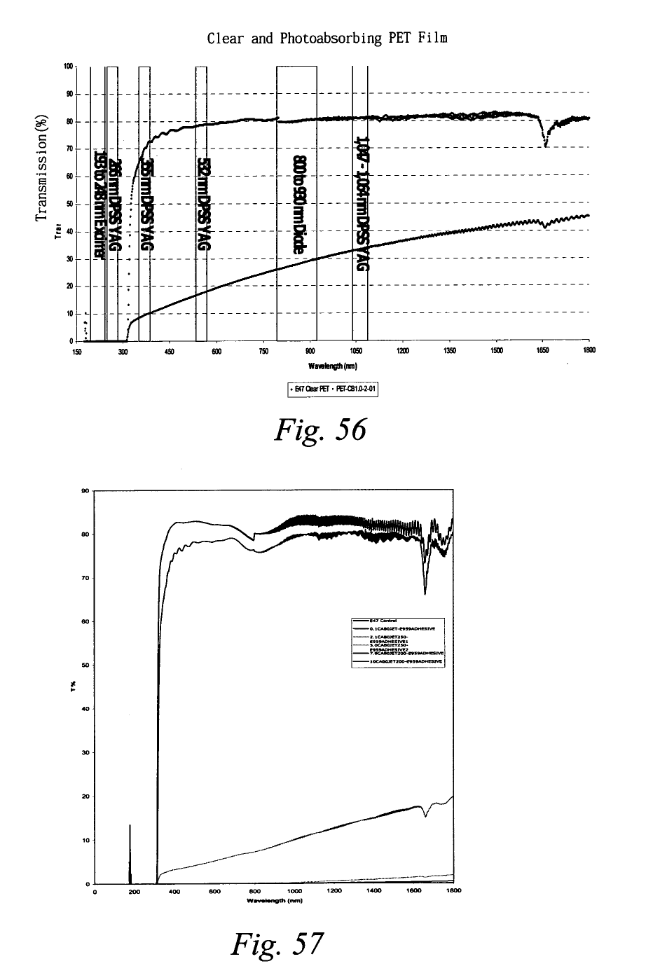

FIG. 56 indicates the types of laser which may be used in preparing PER-based masking films,

FIG. 57 is a graph depicting absorbtivity of an adhesive coating over the 175 nm to 1,800 nm waveband,

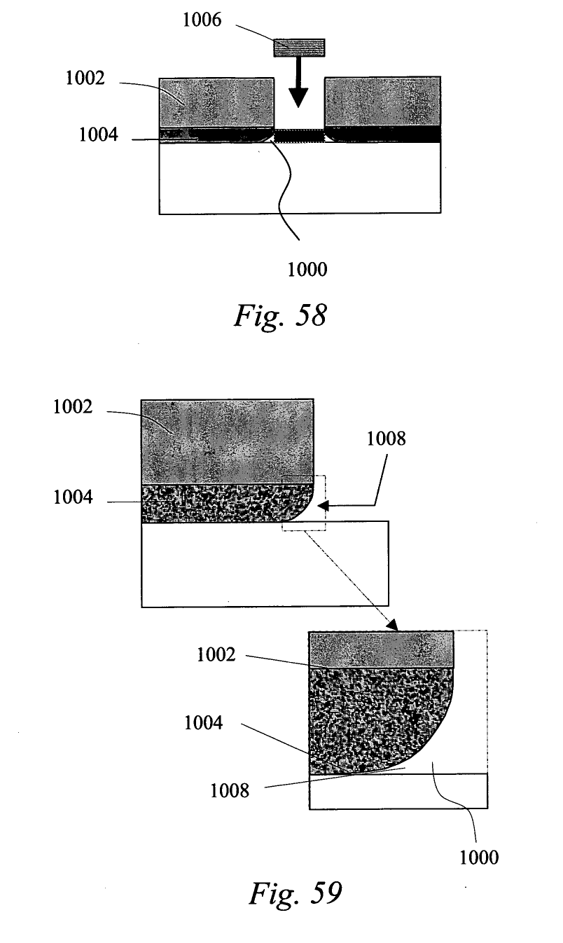

FIG. 58 depicts a further embodiment for producing an undercut,

FIG. 59 shows the undercut of FIG. 59 to a larger scale,

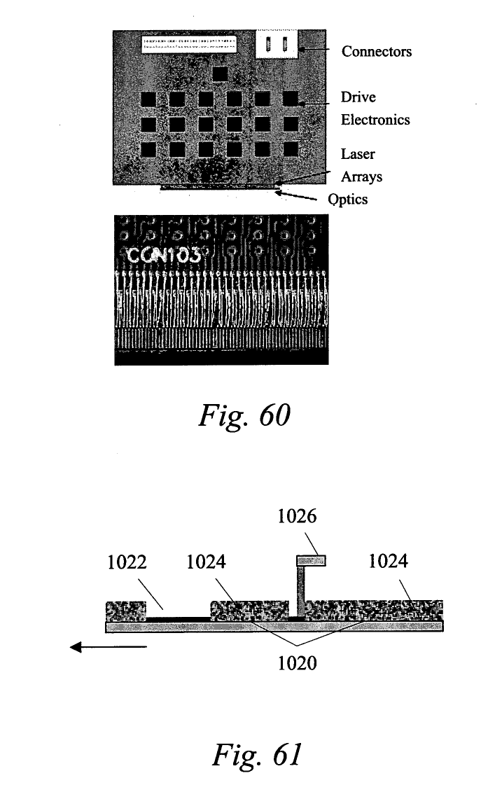

FIG. 60 shows an array of individually addressable laser elements,

FIG. 61 depicts the formation of windows to provide access to contacts pads on a silicon wafer.

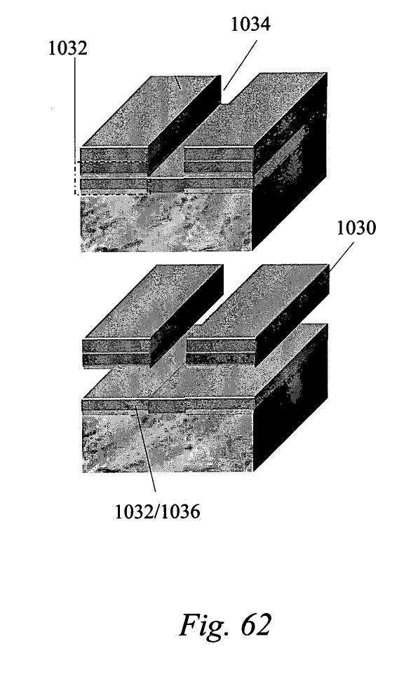

FIG. 62 shows a multiple layer masking system,

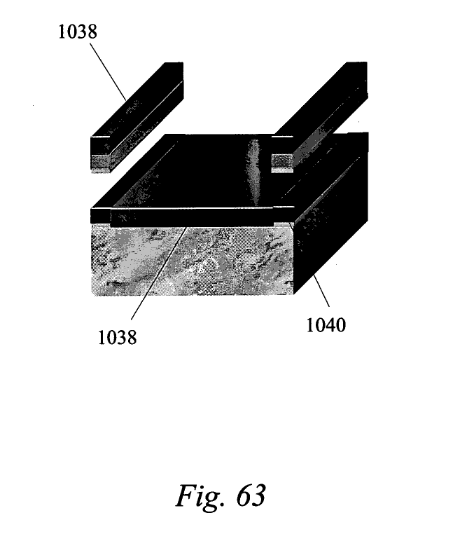

FIG. 63 depicts the production of a transmissive display colour filter,

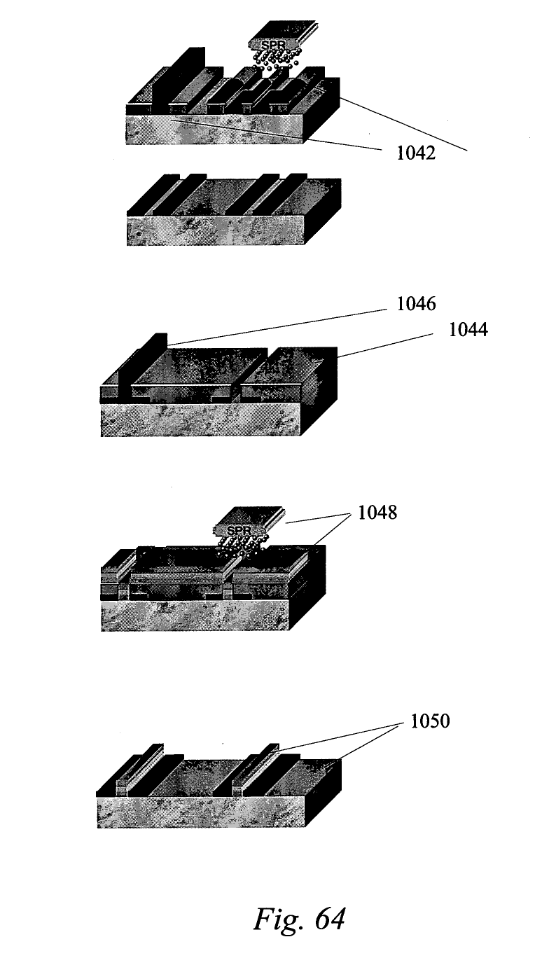

FIG. 64 shows a so-called top gate device,

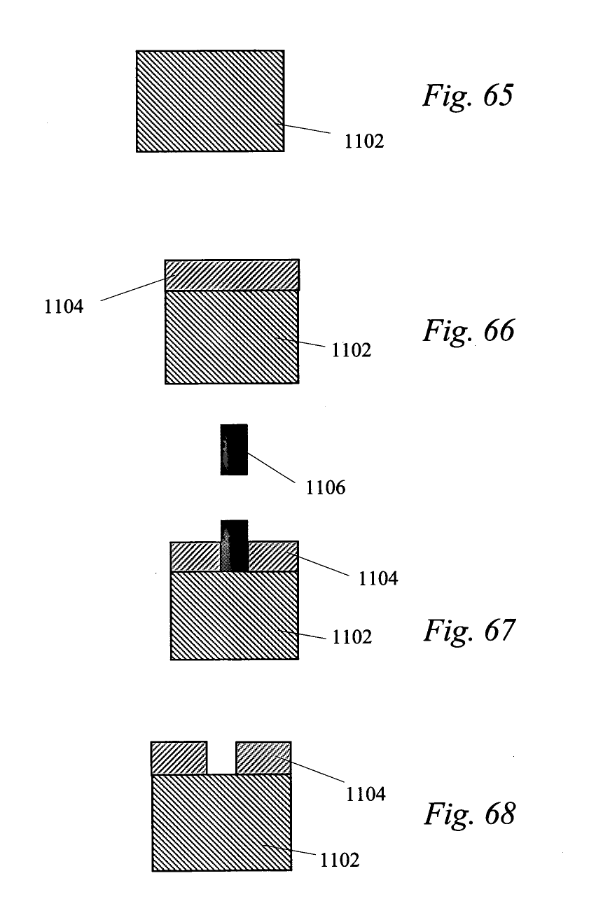

FIGS. 65 to 72 are a series of figures to illustrate use of a sealing film,

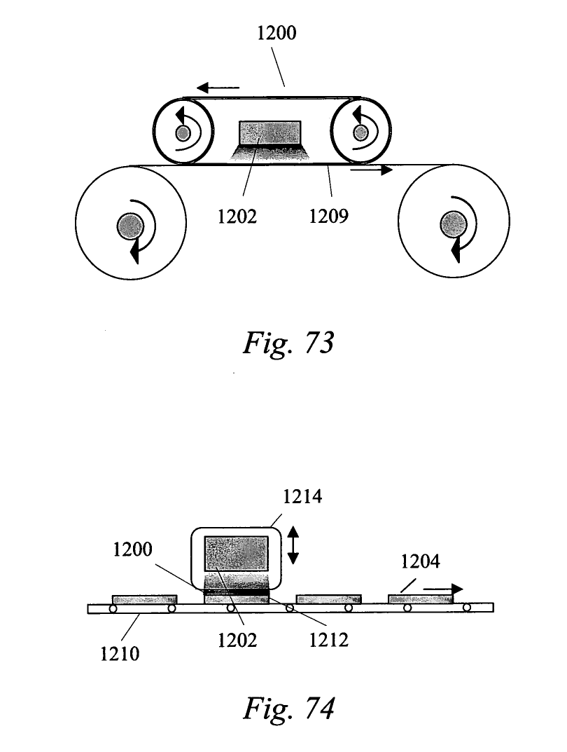

FIG. 73 depicts the use of a deposition apparatus which makes use of a continuous loop,

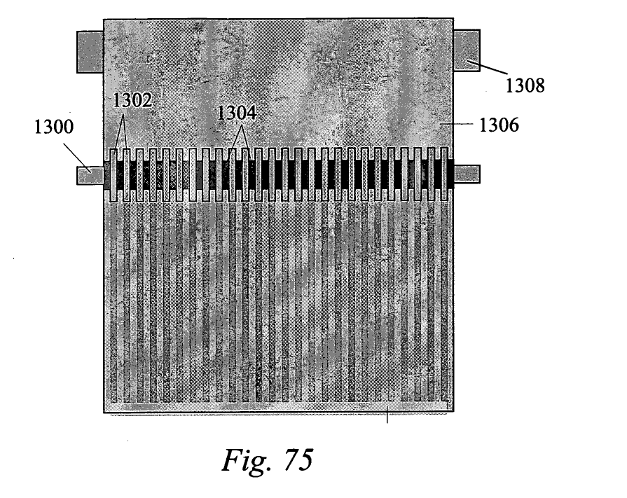

FIG. 74 shows an apparatus in the form of an assembly like for circuit manufacture,

FIG. 75 shows a tape array on a processing mandrel,

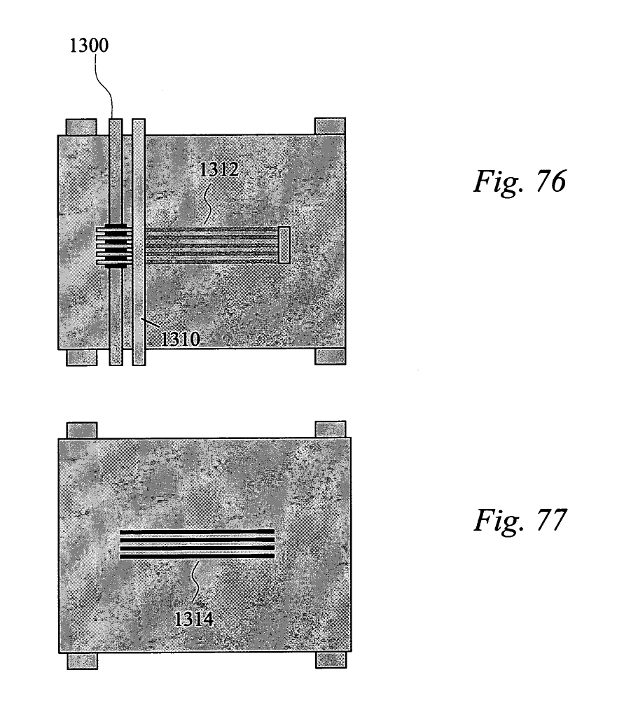

FIG. 76 depicts the use of hot or cold roller technology,

FIG. 77 shows a set of parallel conductors produced using a processing mandrel,

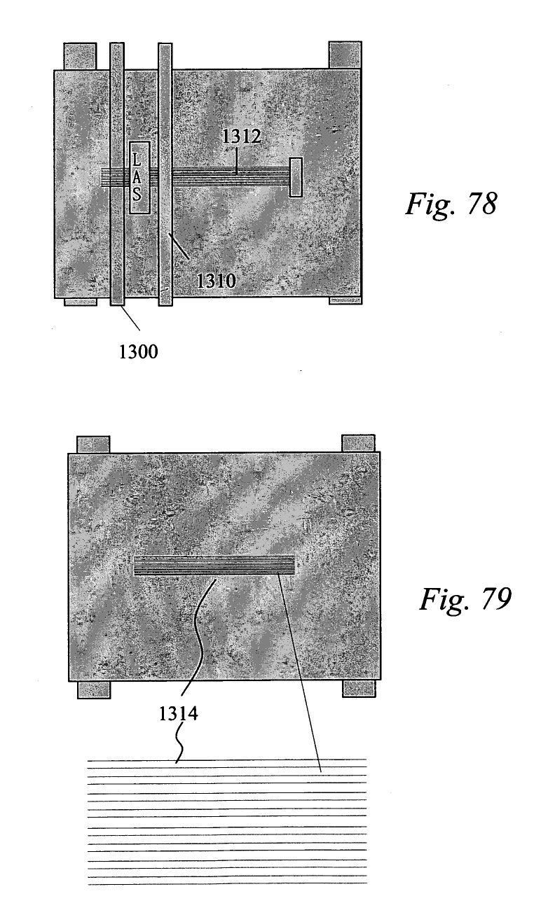

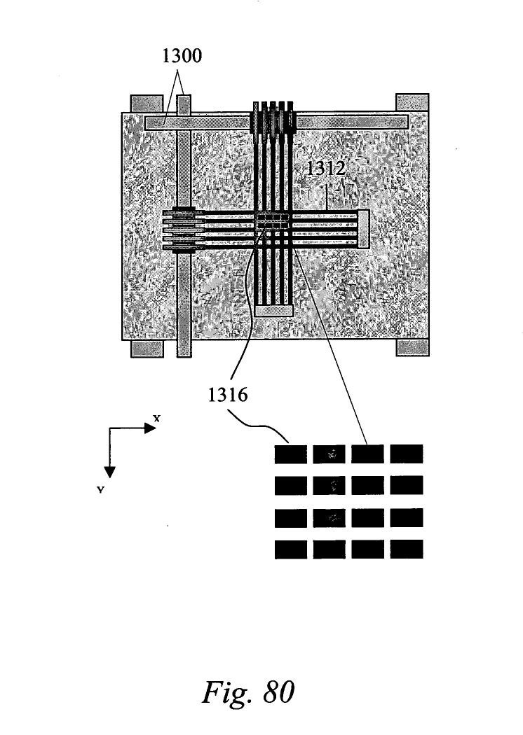

FIGS. 78 to 80 show a system for defining patterns of rectangular contact pads or electrodes,

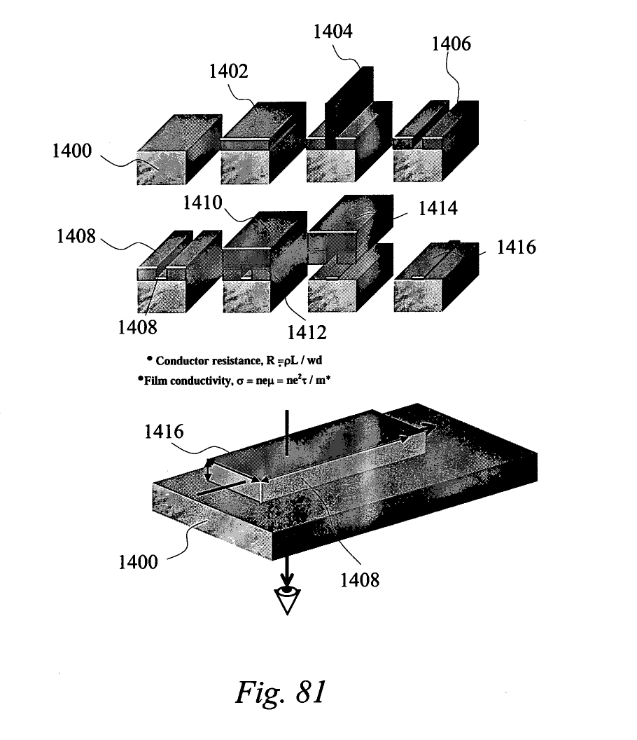

FIG. 81 depicts the sequence of processing steps after a masking tape or film has been attached to a substrate,

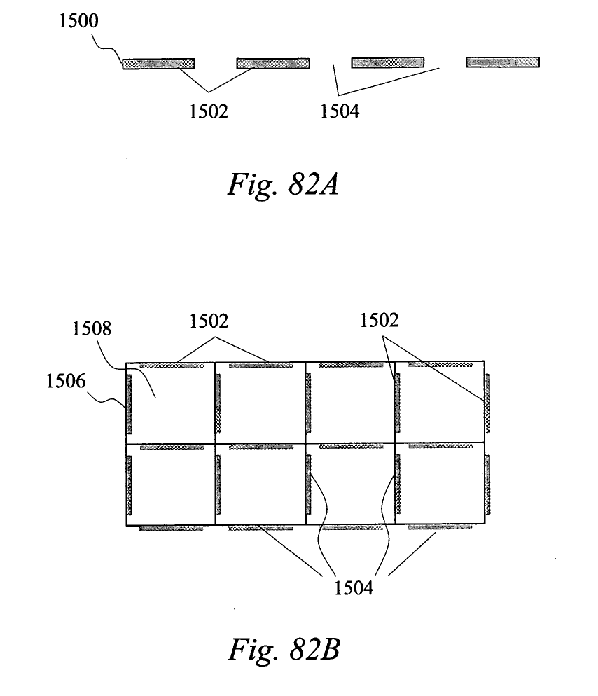

FIGS. 82A and B depict bus bar electrodes,

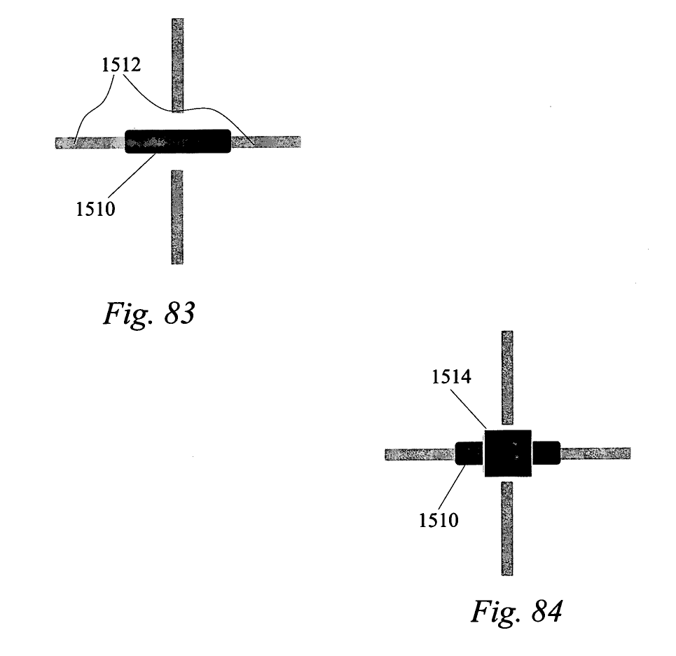

FIG. 83 shows a flexible link connecting electrode,

FIG. 84 depicts isolation of electrodes

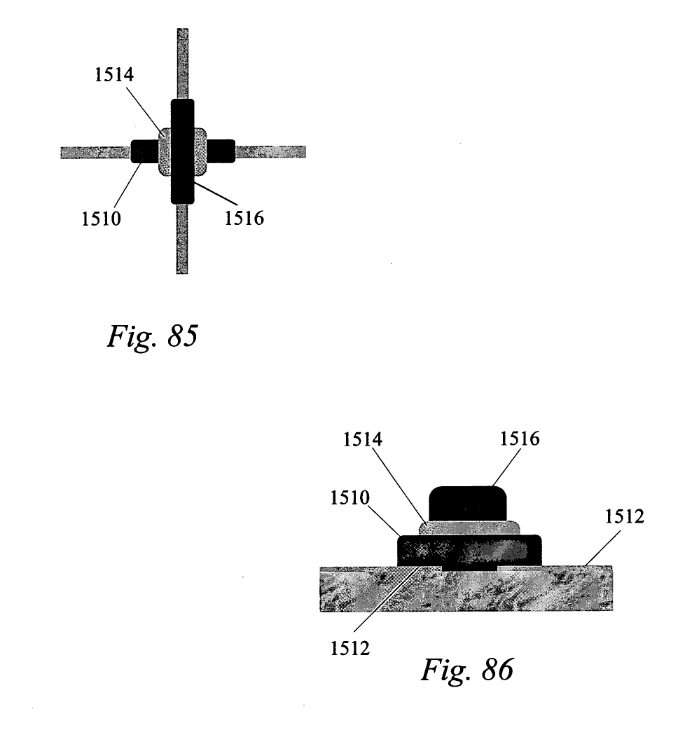

FIGS. 85 and 86 depict further aspects of isolation of electrodes,

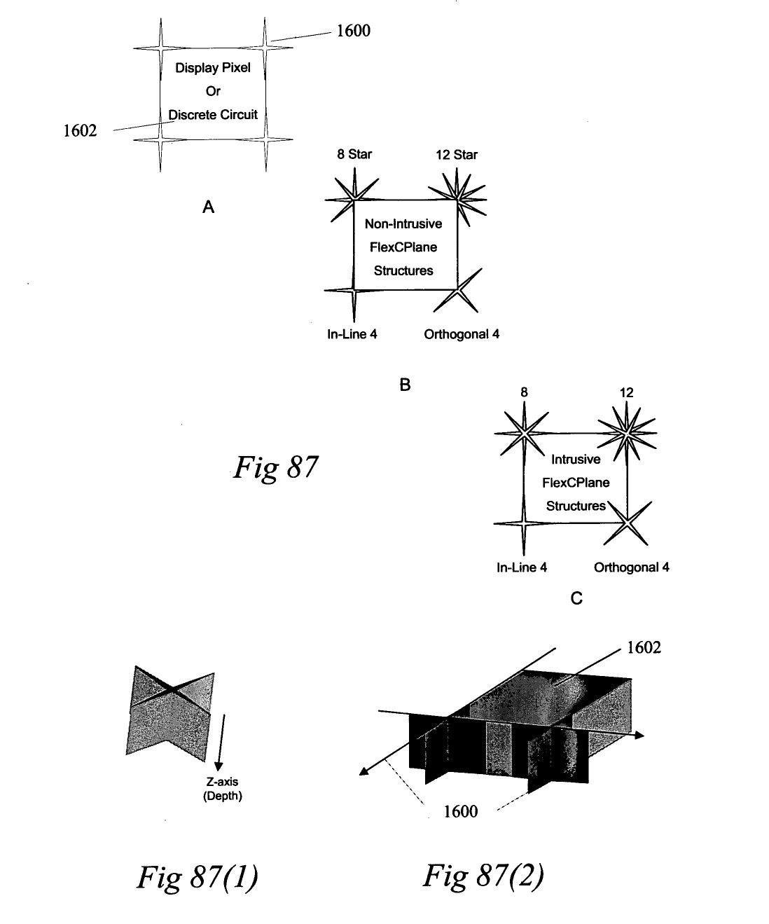

FIG. 87 shows the positioning of micro hinges at the corners of a ket device or circuit element,

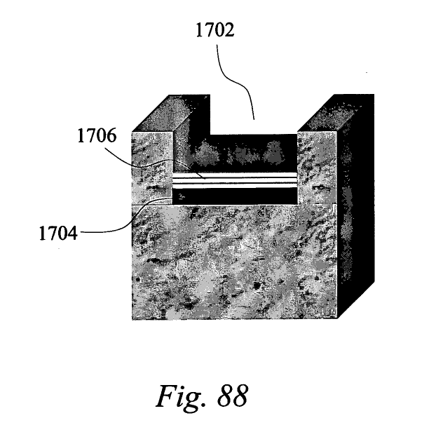

FIG. 88 shows a completed laser ablation patterned trench,

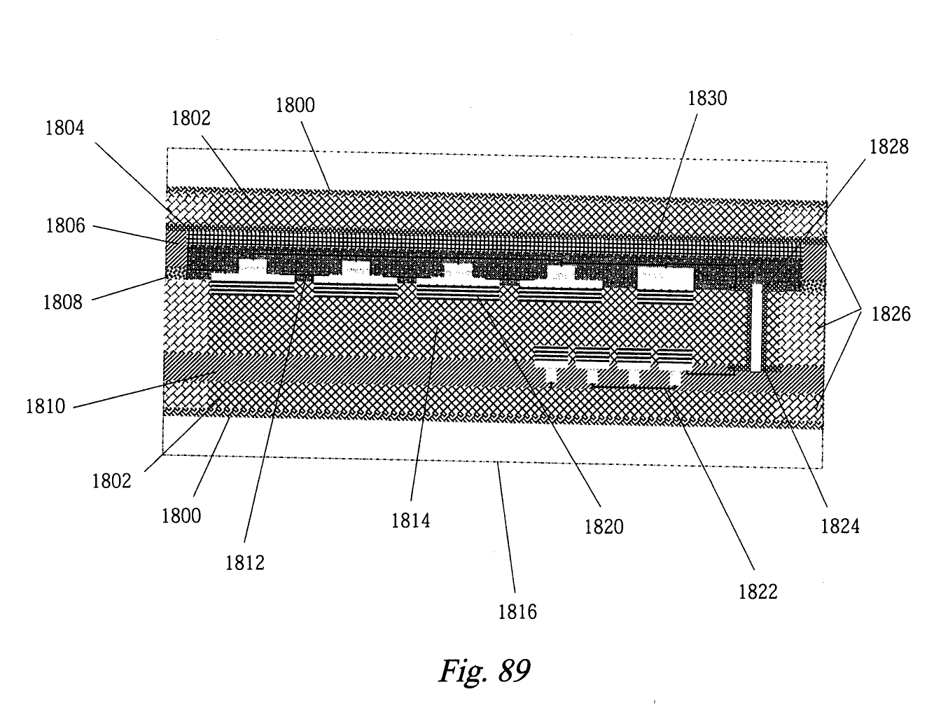

FIG. 89 shows an all-transparent large area flexible substrate display panel,

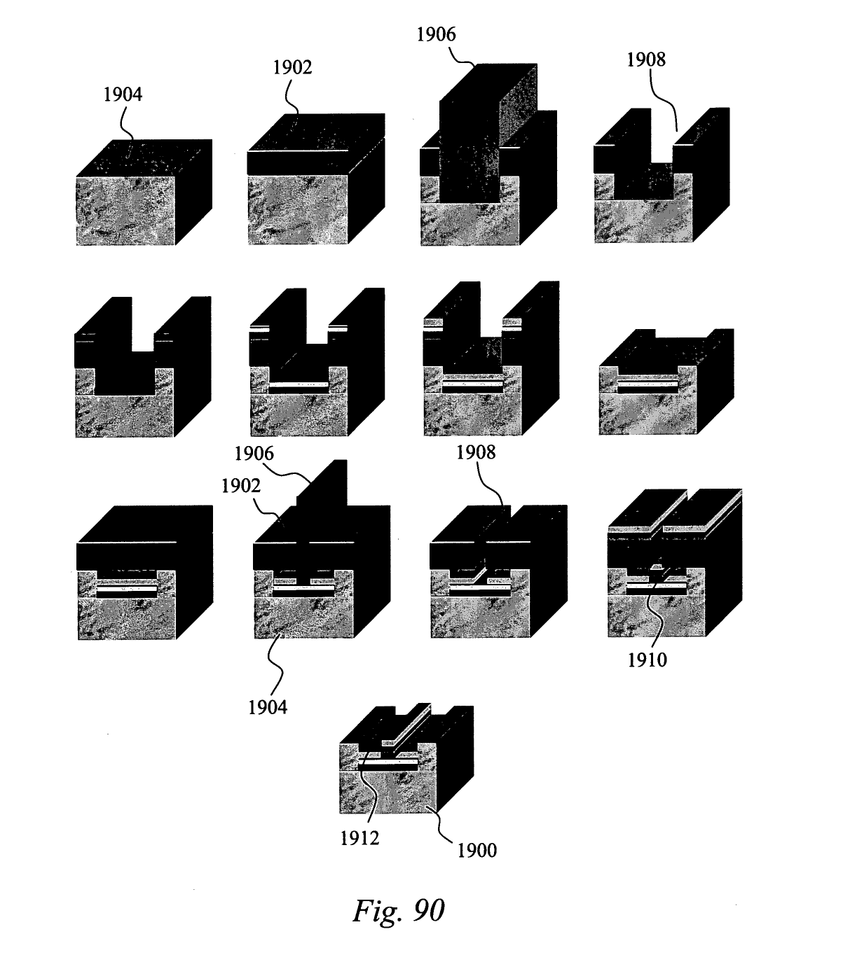

FIG. 90 shows an auto-aligned LPM mask,

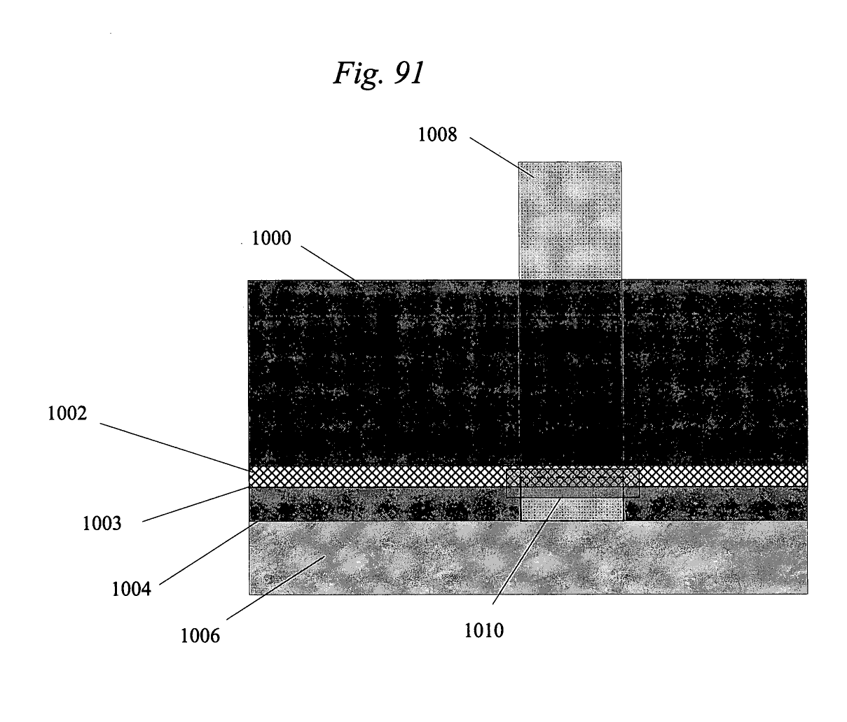

FIG. 91 shows schematically a release liner system,

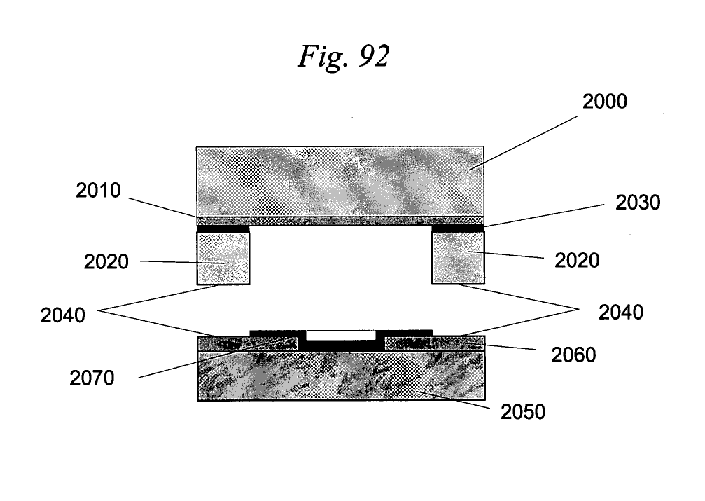

FIG. 92 shows schematically the Seal-n-Peel removal system

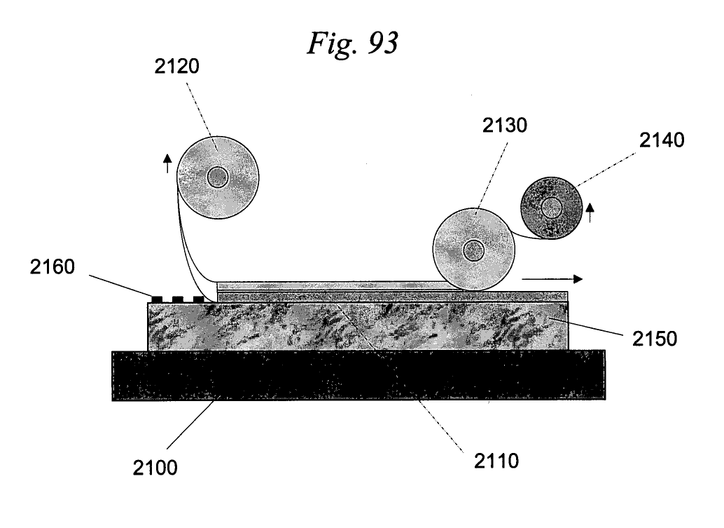

FIG. 93 shows schematically apparatus for Seal-n-Peel removal.

### AN EMBODIMENT OF A FABRICATION PROCESS

FIG. 1 shows schematically a number of stages in an embodiment of a process using a peelable mask. A peelable mask 10 which in this illustration is a thin polymer film (but could be a thin or thick coating, for example a polyethylene terephalate, a polypropylene, a polyethylene napthalate, a polyethersulphone, or a polyimide, is laminated to a substrate 12, for example a glass material or a plastic material. The material may be rigid or conformable. The peelable mask 10 is laminated, or sprayed onto the substrate 12 and held thereon by electrostatic attraction and weak mechanical interlocking. Such a masking film can have a wide ranging selectable cross-sectional thickness in the range 0.1 to 200 μm, in this embodiment around 10 μm, that is preferably applied dry in sheet form for roll-to-roll or roll-to-substrate coverage applications. Some of the dry film polymers, such as 0.9 micron thick PET can be obtained in 4 metre wide rolls thereby providing for very large area array processing.

Alternatively the film 10 could be applied in dip cast, spray, ink jet printed, or liquid shower cast or doctor blade forms where the coatings could be based on acrylic, polyurethane, or silicone materials.

A laser beam 14 is used to dry etch the mask 10 using a direct write technique. The laser beam 14 forms a pattern in the mask 10 comprising a plurality of trenches 16, one of which is shown in FIG. 1b. In order to make peeling the mask off easier, the pattern is formed such that a continuous connection between portions of the mask remains after the pattern has been formed therein. For example the pattern may be an array of squares in cross-section.

In the preferred embodiment of this invention this fabrication process is sometimes referred to as laser patternable peelable masking process or by the abbreviation—(LPM)

In this example, since each device is separate and there is a finite space between adjacent devices the masking film remains essentially continuously connected, as in a shaver foil that has an array of holes produced in it. This means that no islands of masking material are created that would be left behind when the peelable mask was removed.

The pattern formed in the mask may be such that the mask does not remain continuously connected (both contiguous structures like an annulus and non-contiguous structures like simple circular or square holes can be produced in the mask). This means that for the former example the mask has elements separated from the main sheet film or coating mask whilst the latter has mask connected everywhere with isolated holes produced in it).

The pattern thus transferred into the masking film defines a series of isolated devices. Isolation, in this context, means that each patterned device is not electrically connected to any other device (unless the substrate itself is electrically conducting). Additionally, the devices are physically isolated, comprising islands of material on, or in, the substrate.

The pattern may include interdigitated portions, such as comb fingers, if desired. Care must be exercised in selecting the masking film properties in order to ensure that isolate ribbons of masking film, such as would be produced in patterning a “comb-like” electrode, are not torn off the masking film and left on the substrate surface during the masking sheet peel-off process.

Material, for example semi-conductor material or insulator material, or protective material is then deposited in the trenches, as shown in FIG. 1c. A wide variety of deposition techniques can be used. The mask is then peeled away to leave the substrate 12 having a layer of material 18 deposited thereon, as shown in FIG. 1d.

This production approach, using specific modification in surface and bulk properties as required, can be used for producing, for example, a thin film transistor based on, for example: organic materials (for example pentacene organic field-effect transistors O-FET), inorganic materials (for example amorphous silicon thin film transistors) or inorganic-organic hybrid materials (for example, an O-FET using an inorganic gate insulator).

This processing method is suitable for transparent materials, translucent materials, opaque materials, and combinations thereof in dry and liquid deposition source forms.

Therefore, the peelable mask manufacturing method can be used to produce thin film transistors based on, but not limited to: amorphous silicon, plastic polythiophene, organic pentacene, diamond-like carbon or zinc oxide and alternate inorganic oxide systems such as indium, gallium, magnesium, phosphorous, and nitrogen doped zinc-oxide, copper indium oxide (CulnO₂).

Moreover, the peelable mask manufacturing method is also applicable to the production of many types of microstructures, for example microelectronic, opto-electronic, and photonic devices and circuits. Some examples are polymeric or inorganic oxide optical waveguides, transparent conductive oxide heater elements, and lenticular and graded index lens arrays.

The Masking Film

Preferred features of the proposed masking film include: a simple masking film; bubble-free application and tear-free removal; masking film process compatibility with rigid and flexible media; a masking film process compatible with individual substrate, batch, and roll-to-roll manufacturing; masking film compatibility with liquid, vapour, and solid particle-based deposition media; high resolution feature generation in the masking film via selectable wavelength laser direct write etching; clean removal and controlled disposal of unwanted thin film deposits; and auto-aligned vertically stacked coatings deposited within the laser etched windows and substrate sub-surface wells and trenches.

Although a temporary or semi-permanent adhesive bonding material could be used to attach the masking film to the substrate with an appropriately chosen ultra thin polymer sheet such as polyethylene terephalate or polypropylene, the material and thickness of the masking film preferably is chosen so as to adhere to the substrate surface using electrostatic potential (Van der Waals forces) only. Moreover, having an ultra thin film, which in this embodiment means preferably less than or equal to 10 μm and most preferably less than or equal to 1 μm, means that the masking film will readily take-up the contours of any surface structures such as previously deposited thin film coatings and layers comprising complete or incomplete devices.

As well as the process parameters which define the film, it preferably has the following mechanical properties: possesses high mechanical strength; is tear resistant in ultra thin and thin film form; is easily laser etched with no etching residue left behind (Clean etch process); has high chemical stability (primarily for use with liquid deposition processes such as ink-jet printing and spraying); the pattern to be etched preferably forms an array of discrete features that are not connected, so that no part of the mask forms an isolated island of masking material that is left behind during the peel-off process; the outer surface is adapted to be so treated as to provide a highly wetting or highly non-wetting or intermediate wettability behaviour to a wide range of liquids and vapours; and the inner surface can be so treated as to provide a variation in adhesive bond energy from purely electrostatic (Van der Waals) to permanent chemical interacted bonding to cater for attachment to a range of substrate types including where the masking film forms an integral and permanent part of the device being manufactured.

The peelable mask has a tensile strength of substantially 200 MPa, films having a tensile strength of from between 100 to 300 MPa are also suitable. The actual tear strength of the peelable mask depends on a number of factors, including the mask film thickness used, the mask film material type, the size and distribution of the pattern features, the shape of the pattern features, the applied peel-off force used for the masking film-substrate scheme employed, and the nature of the deposition processes to be used to coat the etched features (including coating coverage distribution, material type, coating thickness and number of layers in a multiplayer stack).

The construction of the process bearing in mind all of these features can be manipulated to provide suitable value for the tear strength of the film.

Due to the penetrating nature of the laser beams used to etch the masking film and substrate media and the methods and optics used to shape the laser beam there are certain desirable properties of material type and mask thickness that can be used in combination with laser etching for a particularly cost-effective process.

In this regard such properties and associated ranges include a masking film thickness range of 0.1 to 10 microns. In a preferred embodiment, sheet processed polyetheylene terephalate (PET) is used having a thickness in the region of 0.4 to 0.6 microns. Other ultra thin film plastic sheet materials may be used having similar or greater cross-sectional thickness.

It will also be appreciated that the masking film thickness is chosen to be commensurate with a specified lower limit of feature resolution. The processes of the present inventions may be thought of having 4 distinct masking film formats which take account of the patterning feature resolution (minimum width of pattern required designated as “x”) to be achieved—such resolution ranges and associated masking film formats are preferably:

| | | |
|---|---|---|
| 1. | 5 μm ≦ x ≦ 250 μm | Sheet film lamination |
| 2. | 1 μm ≦ x ≦ 5 μm | Liquid (and Powder) coating deposition |
| 3. | 0.02 μm ≦ x ≦ 1 μm | Vapour coating deposition |
| 4. | 0.02 μm ≧ x | Atomic (ALD) or molecular (MBE) |
| | | deposition |

The masking films are described below in further detail. However, more generally, it should be noted that:
Masking properties may vary for non-contiguous versus contiguous pattern layouts
The “Seal-n-Peel” process, in some embodiments, relaxes the mechanical properties required for a stand-alone peelable masking film to the point that the masking film can actually be the attachment adhesive only since it provides a suitable means of bonding the residual coating to the masking film prior to be interlocked between the “Seal-n-Peel” film and the masking film. This provides a means of depositing a controlled attachment strength coating that is in intimate contact with the substrate without the need for applying attachment pressure as in the case of an adhesive coated polymer film

It is envisaged that for a large proportion of applications requiring micro patterning, spanning many industrially important markets, a laminated polymeric film is preferable as the masking material, and both low-tack adhesive and electrostatic bonding techniques may be used to attach such a film to the substrate surface requiring a patterned mask.

As discussed in this application, it is anticipated for some applications the masking film may comprise two or more layers wherein the outermost layers have differential low-tack adhesive strength attachment to each sub-masking film. The masking layer closest to the substrate surface may include a permanent attachment adhesive coating so that once the feature patterning has been accomplished the outer layer of masking stack remaining is removed leaving the inner most layer in place to effectively embed the patterned material using the masking film/adhesive.

As discussed above the laminating film mask may be produced in a range of film and adhesive thicknesses, and formed using a number of materials for the base media and attachment adhesive. Although PET is disclosed as one preferred material, others include:
Latex (a dispersion of minute polymer particles in water—a milk-like liquid with a water content of 30 to 60%, preferably 40 to 55%, more preferably about 50%. The latex particles have diameters measuring between 1 and 50 nm, preferably 5 and 40 nm. The particles are most preferably less than about 10 nm. The particles preferably comprise a polymer core that is surrounded by a polar shell that interacts with the water thereby stabilising the dispersion)
Nanocomposites (nanoparticulate added for photo absorption, surface roughening, electrical/thermal conductivity, etc. requirements)
Polycarbonate (PC, Lexan, etc.)
Polyethylene terephalate (PET, P-ETE, polyester, Mylar, Arnite, Impet and Rynite, Ertalyte, Hostaphan, etc. covering pure and particulate loaded variations)
Polyimide (PI, Kapton, Upilex, etc.)
Polylactide (PLA)
Polymethyl methacrylate (PMMA, acrylic, cyanoacrylate, etc.)
Polypropylene (PP)
Polytetrafluoroethylene (PTFE, FEP, PFA, Teflon, etc.)
Polythene (polyethene, PE, etc.)
Polyurethane (including oligomers)
Rubber
Silicone (methyl silicones, etc.)

There are typically 2 main types of adhesive base used for the manufacture of pressure sensitive adhesive (PSA) tapes, namely:
Rubber/resin (a material mixture of a natural or synthetic rubber and a natural or synthetic resin)
Acrylic (fully synthetic custom designed polymer)

The PSA's are preferably combined with a carrier liquid (water to form an emulsion or dispersion or dissolved in a solvent) or heated (Hot-melt adhesive) to a material flow temperature in order to assist application of the adhesive onto the surface requiring the adhesive. It will be appreciated that other suitable adhesive materials are known to persons skilled in the art and may be employed as appropriate.

It is anticipated that the adhesive coated masking films may have heat (including infrared radiation), ultra violet (UV) light, and/or pressure activated assisted attachment processing; and that for the low-tack materials used from a roll or in single sheet use of a release layer, typically fluorosilicone based, may be required to cleanly remove the masking film from the roll or source stack prior to attachment to the substrate surface.

From a process efficiency point-of-view it is advantageous for the masking film to be as thin as is practically possible. For example, a YAG laser, having operating parameters as outlined above, will remove about a 0.25 micron depth of PET masking film for each laser pulse. The same laser would remove around 0.1 microns of indium tin oxide (ITO) film in a single pulse (depending on a number of factors, such as wavelength absorption behaviour of the ITO film), which is of use in dual peelable mask processes, such as those shown in FIGS. 2 to 4 and described below.

In a preferred embodiment, the material used for the mask film 10 is wavelength matched to the wavelength of the laser light to be used to etch the masking material. For certain types of material and laser combinations the efficiency of etching is increased if the optical properties of the material to be etched are matched to the wavelength of the laser so as to enhance the amount of energy that is absorbed by the material for each laser etch pulse

Alternative methods of applying the mask film 10 include:

Liquid Coating Masking Film

As the size of the preferred pattern features is reduced so the preference to have a thinner sectioned film becomes preferred, particularly if high volume throughput using single pass patterning is wanted. Accordingly, the masking film/adhesive coating (or masking film alone if electrostatically bonded) may instead be a single deposited film or coating that serves the purpose of providing a laser ablatable masking layer that can be removed, preferably, as a whole area sheet using the mechanical peel-off methods of the present application. This process is particularly useful as not only does it seal the residual coating onto the masking film surface, but also relaxes the mechanical properties of the liquid produced coating such that emphasis can be given to coating process uniformity and optimised photoabsorbtivity for the laser ablation system type and wavelength selected for the patterning requirement.

Numerous methods exist for coating a surface (e.g. substrate 12) from a liquid source including:
Dip coating
Spray coating (including selectively switchable nozzles)
   Gas pressure assisted
   Electrostatic
   Piezoelectric
Flow coating
Spin coating
Capillary (laminar) flow coating
Roll coating
Printing
   Screen
   Digital ink jet
   Gravure
Chemical
   Sol-gel
Electrophoretic
Draw bar
Vapour coating
Plasma (including plasma polymerized)
Electron beam
Thermally evaporated
Sputtered

Such processes provide (1) wide control over surface wetting, (2) mask coating intimacy with the substrate surface and any structure associated with it, (3) wide control over mask coating thickness and (4) wide control over the mask coating properties

The above coating methods may be used to apply a range of controlled thickness liquid coatings on to a roll of material or to a discrete component such as a silicon wafer or a plate of glass, or even preprocessed substrates. By way of example the use of a whole area coating process such as thixotropic screen or sheet liquid dip processing (or other from the list above) produces a polymer sheet substrate with an integrated low-tack masking film as a single component that may be applied to a roll of film (for example a PET sheet film used as a substrate in macroelectronics and/or flexible electronics applications). This method is advantageous in that it overcomes interfacial contact issues due to the manner in which the film is applied to the polymer sheet substrate media (liquid spreading due to surface energy—surface tension—viscoelasticity effects). Further details with respect to applying a thin viscous or non-viscous liquid coating to a polymer sheet substrate in roll form are well known in the polymer film industry (i.e., processes of Intelicoat Technologies, Wrexham in the UK.

Powder Coating Masking Film

An extension to the liquid coating processes is the ability to use thermally fusible thermoplastic particles to produce a masking film which may be removed as a whole area sheet at room temperature or as a result of the application of heat at a temperature, substantially below that used to melt, flow, or fuse the particles together to form the continuous masking film in the first place. Processes that are of particular interest in this respect are Xerography (very high resolution, preferably up to about 5 microns) and off-set toner transfer printing.

Vapour Coating Masking Film

For feature patterning requirements at about the 1 to 2 micron level, vapour deposition becomes may be a practical alternative and opens up a whole range of possibilities, not just organic or nanocomposite, but purely inorganic oxides for example. This provides even greater LPM versatility it is possible to deposit a thin oxide film with essentially zero-stress onto, for example, a plate of glass which can be patterned using direct write laser ablation. This, provides means for producing high temperature thermal expansion matched masking films which can be used for high temperature thin film coating requirements, for example, removal of oxide mask from residual coating. Once again numerous suitable methods exist to produce a range of organic and inorganic or hybridised coatings including:
Atmospheric monomer deposition (for example thin film paraxylene [parylene] coating deposition for films greater than 0.5 microns)
Monomer vapour spraying (in vacuum process)
Thermal and electron beam evaporation
Magnetron sputtering
   High target utilisation (HiTUS from PQL)
   Multiple magnet high target usage
Ion-beam assisted deposition (IAD)
Ion-beam sputtering
Chemical vapour deposition (CVD)
Plasma-assisted chemical vapour deposition (PECVD)

Each processing method has its own specific benefits that include throughput and coating thickness control that provides a platform for cost-performance patterning—and/or increased processing versatility via Mix-n-Match process selection.

Molecular Masks

For very high feature resolution, at the few tens of nanometres and below, it is important to have a masking film that is defect-free and highly homogeneous at the molecular level. This is because the size of the feature being produced is of the same order as the material structure and so imperfections on this scale will have a considerable impact upon pattern quality and hence device/circuit operational yield. In order to achieve such homogeneity in ultra thin film form it is preferred to make use of a number of processes that include:
1. Molecular beam epitaxy (MBE)
2. Atomic layer deposition (ALD)
3. Langmuir-Blodgett technique
4. Adsorption and chemisorption
5. Self-assembled monolayer techniques

The deposition methods listed above are suitable for producing a photoabsorbtion-matched peelable patternable mask onto a large diameter silicon wafer that may then be selectively patterned with features in the range 10 to 50 nm using a whole area mask exposure, or step and repeat mask transfer process, based on, for example, a 193 nm excimer laser or similar high energy pulsed light source. The use of this patterning method in the processes of the present application makes for a very clean patterning method having very high resolution features—especially useful in an industry that seeks to process such wafers without any debris present because any debris at such feature sizes would render the associated device or circuit inoperable, and would thus reduce useful product yield.

The use of direct deposition methods, as outlined above, such as digital drop-on-demand ink jet printing means that the design of the dispensed liquid masking film source can be such as to provide a better intimate coating to the substrate, irrespective of whether the surface has 3-dimensional features pre-deposited on, or etched in it, so as to give a better coating coverage but using a material that only provides a low energy interfacial bond strength so that the film can be readily peeled-off after use.

As has been noted, the processes of the present inventions allow for very high resolution patterning at the sub-micron features scale. In the conventional process 193 nm ArF excimer laser technology may preferably be used to produce a pattern of order 45 nm (EUV plasma source patterning below 25 nm) in an ultra thin liquid coated photoresist, that after thin film coating is removed with the residual coating material using a liquid spray/immersion etch process. Inhomogeneity in the dried liquid coat can introduce pattern feature aberrations which may lead to device operation instability and optimum performance limitations. However the processes of the present inventions (especially using “Seal-n-peel”) provide for a cleaner, and it is believed more uniform, very high resolution patterns, as the low tack peelable masking film can be deposited in ultra pure thin film form using high quality, high uniformity vapour coating processes (such as Polymer laser ablation or Polymer vapour coating). The high quality material deposited in this way provides a means of producing nanometre thickness (and molecular scale) peelable films which may be laser ablated over a range of wavelengths to provide high quality patterns on, preferably highly polished planar substrates, such as silicon, gallium arsenide, indium phosphide, and zinc oxide crystal wafers.

The vapour phase deposition of ultra thin polymer masking films allows for the depositing of an intimate contact masking film of very low adhesive contact energy to a variety of amorphous and crystalline substrate types—including pre-processed substrates exhibiting devices and circuits at varying stages of manufacture. It is believed that the low contact adhesive strength is achieved because the polymer film deposition is a low deposition energy process which does not impart surface damage. Moreover, the deposited polymer film preferably has a chemical structure that provides for a fully terminated polymer surface that has no “dangling” bonds for higher strength ionic or covalent bond sharing.

The choice of polymer and coating method permits the deposition of very homogeneous high purity amorphous polymer films that possess tailored light absorption properties to match the specific EUV source wavelength spectral output thereby allowing for efficient laser ablation of very high quality nano scale features with excellent edge definition.

As noted above, the polymer masking film may be based on a range of polymer types including polyimide, polymethyl methacrylate (PMMA), and parylene (type N, C, or D) that may be deposited using conventional evaporation, laser ablation, or magnetron sputtering, as well as, gaseous monomer chemical vapour deposition (CVD) process with or with plasma or ion beam assistance.

Once the masking film has been deposited and laser (or focused ion beam) patterned, a subsequent thin film coating may be deposited. The residual coating material if removed without sealing could introduce debris as the methods of removing the mask and residual coating could result in fragments of the coating being spalled-off the masking film driven by localised stress. However, the use of the present masking film removal methods (“Seal-n-peel” especially) ensures no coating debris remains (is redeposited from the atmosphere) and no masking film is left behind on to the wafer/substrate surface. As the masking film is preferably of molecular thickness, the attachment of the removal film is purely 2-dimensional, with the thickness of the removal system providing mechanical support for the nm thick masking film as it is peeled off along with the residual coating material.

If desired, however, a large number of treatments are available to alter the physical properties of the masking film. For example, various nanoscale additives (including inorganic nanoparticles) and material blend, modification or mixture can affect the chemistry of the film. These changes affect the material properties such that the film may be hazy or optically clear, or have a particular tear resistance, or handleability. Handleability in this context means the ability to be able to mechanically apply and remove the ultra thin film without introducing creasing or buckling, or adhesion to itself. Subtle or major changes can be introduced to the masking film and flexible substrate media by such methods to optimise the physical properties of the peelable mask.

For example, adhesion promoters (such as polyvinyl alcohol, ethylene vinyl acetate co-polymer, and hexamethyldisilizane may be included with the polymer chemical source mix.

UV laser radiation is known to predominately break material bonds (bond scission) leading to rapid localised pressure build-up and explosive evaporation of material so irradiated. The thermal component of this energy pulse process is very low—typically 5% or so. Although the most industrially accepted UV laser technology for ablating patterns in plastic (and other materials) is Excimer (157 to 351 nm nanosecond pulsed), other technologies may be used for the micropatterning applications. Such laser technologies include:
Diode-pumped solid-state (i.e, YAG, etc.)—213 nm to 355 nm
Copper vapour—255 nm
Ultrafast (i.e., YAG, hybrid excimer, etc.)—266 nm to 390 nm

Ultrafast (picosecond to attosecond pulse duration) laser technology is of preferred importance in processing plastics because a key feature of the present processes is the provision of an auto etch stop on the deposition receiving substrate surface without introducing any surface damage may is deleterious to the product being manufactured.

Auto etch stop patterning resulting from the use of ultra violet laser technology is mainly important for mask patterning which takes place directly on the substrate surface (in-situ process), and from the point of view of defining a suitable processing method, the nature of the substrate material (polymeric and non-polymeric) is important.

For the non-polymeric substrates, such as Corning Eagle 2000 plate glass as used in flat panel display manufacture, the surface ablation threshold of glass (silicon oxide) is considerably higher than that associated with the masking film plastic sheet/adhesive system and as such adequate differential surface ablation threshold fluence exists to achieve a clean etch stop. This is not necessarily the case for polymeric substrates.

For polymeric substrates the material may be PET (polyester, Mylar, Melinex, etc.), or any of the other suitable materials described above or elsewhere in this application. For a PET masking film electrostatically bonded to a PET substrate sheet, the production of through mask processing windows (e.g. by deposition, etching, etc.) can produce auto-etch stop patternings on the substrate surface where the PET masking film has a lower surface (and bulk) ablation threshold fluence than that of the PET substrate film. It is known in the art that the surface ablation threshold fluence of amorphous and crystalline (i.e., Mylar-D) PET have similar values (for 248 nm KrF excimer laser it is 30 mJ cm⁻²—reference: Lazare and Tokarev 5^{th} International Symposium on Laser Precision Microfabrication, Proceedings of SPIE Vol. 5662, (2004), pp 221-231), and therefore it is preferable to modify the masking film so as to achieve a substantial reduction on this figure. It is believed that the surface ablation threshold fluence is independent of both the size and depth of the masking feature area being irradiated—unlike the situation which occurs with micro drilling high aspect ratio holes. The change in threshold may be achieved by using a suitable dopant that increases the absorption coefficient over clear (undoped) PET, so that greater energy coupling can be achieved. In doing so, it is preferable for the duration of the laser pulse to be reduced so as to make optimum use of the available pulse energy without an ablated material ejection plume, (or laser induced plasma), by, where appropriate, shielding a portion of the pulse energy which produces the plume/plasma. It is this latter factor that is of importance in respect of Ultrafast UV laser technology—particularly such laser technology that supports high-repetition frequency.

By way of example a broad spectrum absorber may be high purity surface-modified carbon black nanoparticles, nanorods, nanotubes, and nanoplatelets, introduced into the host polymer so as to form a nanocomposite material—where the photoabsorber size is less than 45 nm, preferably less than 25 nm. In order to take advantage of size-dependent temperature effects—that is for particles approaching a few nanometres, a substantial reduction in the melt temperature over that observed for bulk material may be achieved thereby assisting the expulsion of an inorganic material (of particular importance for photoabsorbing materials that do not readily form volatile species with oxygen, nitrogen, or hydrogen). Such absorbers are not generally used for UV stabilisation but for enhancing absorption. Organic UV absorbers, such as benzophenones and benzotriazoles promote increased absorption in polyester over the wavelength range 190 to 400 nm (primarily used in the range 290 nm to 400 nm).

Where a masking film uses a pressure-sensitive low tack adhesive (≦10 N cm⁻¹ and preferably ≦1 N cm⁻¹) to provide a peelable/repositionable attachment to the substrate surface, different conditions may be introduced for UV laser ablation etch stop processing compared with that described above for an electrostatically bonded masking film.

In such a case, a modifying agent may be combined with the adhesive layer compound, or a custom-designed adhesive polymer may be used, that enhances the photoabsorbing behaviour of the adhesive. Clearly, one such agent could be high purity surface-modified carbon black nanoparticles, nanorods, nanotubes, and nanoplatelets since such additives have been shown to introduce very high (>10⁵ cm⁻¹) absorption to a Latex adhesive over a wavelength range of about 190 nm to about 320 nm (see FIG. 57). A suitable adhesive may be designed to control the etch rate of the adhesive even to the point of a using a single laser pulse to cleanly remove the adhesive coating by using the approximate formula for the etch depth per pulse L_{f}:

L_{f}=(1/α) In (F/Fₒ)

Where, α is the UV absorption coefficient, Fₒ is the ablation threshold fluence, and F is the actual fluence above threshold used.

The adhesive coating thickness may be equated to the etch depth to determine the optimum number of pulses required to achieve auto etch stop even allowing for a degree of over-etch to cater for laser beam non-uniformity, and to ensure all adhesive is removed from the deposition window thereby leaving it clean and damage-free. If the masking film patterning process is to be used for producing a surface device or circuit, then the surface (and bulk) ablation threshold fluence is preferably substantially lower than that needed to ablate the substrate surface. If the masking film patterning process is to be used for producing an embedded device or circuit, then the optimum masking film system preferably requires use of a base film polymer and attachment adhesive that are thermally matched to the substrate plastic, and that exhibit equivalent laser ablation rates for all three materials—for example a typical system might be clear PET substrate/attachment adhesive/clear PET masking film where the attachment adhesive would be a co-extruded PET material or an acrylic-base with thermal expansion and photoabsorbtion properties closely matching the PET film. The use of a photoabsorbing PET masking film in this example allows a high throughput process to be achieved.

The above also provides a means for producing an excellent edge quality for features ablated into pre-coated substrates (such as transparent oxide coating of ITO on plastic or glass) where the features are etch stopped on the substrate surface, or extend in depth below the substrate surface with the masking film acting to pin the ablated coating edge to the substrate (preferably under laser pulse energy induced thermal expansion, including use of photochemical UV laser technology where it is understood that some energy conversion to heat takes place), and in some cases enhancing the edge ablation by concentrating the laser energy along the patterning exposed coating wall.

The nature of the peelable surface bond can make use of a large group of adhesives based on many polymers (acrylics, rubbers, polyurethanes), together with plasticisers and tackifying resins to form a permanently tacky (sticky) adhesive. Such adhesive layers can be deposited from solvents, water emulsions or hot melts as the active ingredient in pressure-sensitive tape adhesives where moderate pressure alone is sufficient to spread the viscous adhesive layer on to the surface and achieve useful adhesive strength. They do not solidify or chemically cure but even so are often able to withstand adverse environments. Such adhesive bonding layers can be applied to a variety of substrate (base) media such as cellulose, polyester or PVC. Generally, most pressure-sensitive tapes give high tack but fairly low strength. Some versions develop higher strength upon ageing but newer, higher strength products can be used in more rigorous applications.

The surface of the masking film may be treated so as to affect surface adhesion behaviour using treatments that induce surface effects/modifications in chemical bonding, surface charge state, and surface morphology at a scale of order 20 nm and above as produced by processing methods such as plasma or electric discharge exposure.

For most thin film deposition processes a masking film preferably provides an undercut, or recessed cross-section. This is particularly so for line-of-sight or substantially directional deposition processes such as electron-beam evaporation, magnetron sputtering and ion beam assisted (IAD also sometimes term IBAD) deposition.

A further embodiment for use in the processes of the present invention comprises a method of producing such an undercut feature (1000) using a pressure-sensitive masking film (1002) attachment adhesive (1004) that exhibits a negative thermal expansion (NTE) coefficient (also termed negative-CTE) in conjunction with a laser (1006) for ablating features into the masking base film and adhesive which provides a suitable source of heat energy to drive the adhesive coating shrinkage (1008) as shown in FIGS. 58 and 59.

A suitable adhesive is a co-extruded strained layer that upon local heat undergoes contraction—shape memory effect is associated with a large group of polymeric materials including homopolymers, co-polymers, polymer blends, filled polymer composites, and polymer gels. This approach can be applied to the masking film PET base media during the film forming process but it is not essential.

An alternative method is based around the use of organic-inorganic, and purely organic, nanocomposite materials that make use of polymeric resins (i.e., mercaptothiol), rubber compounds, and long folded molecular materials. It is known that rubber compounds may be used to prepare low-tack adhesives and that such compounds may be modified to provide a highly photoabsorbing (>100,000 cm⁻¹ coefficient) pressure-sensitive adhesive (PSA) that possess a thermally contracting nature. The NTE effect is due to internal entropy change driven by heat residing in the melt/HAZ (heat affected zone) region produced by the laser as it ablates for example, a PET base masking film and the associated PSA attachment coating. Controllable shrinkage as the adhesive coating is removed during laser patterning is a highly desirable property as it not only provides a source of heat for forming the undercut, but also acts as a heat source sink removing excess heat away from the substrate surface. The effect of shrinkage on the heated adhesive allows the adhesive to be pulled away from the weaker bond interface at the adhesive-substrate surface interface. It is the differential rate of shrinkage that determines the degree of undercut, and is a function of the:
Adhesive thickness
Heat energy rate and magnitude supplied
Adhesive-to-substrate surface interface bond energy
NTE nanoparticulate properties
NTE nanoparticle loading in the adhesive nanocomposite

It is known in the art that polyethylene, for example, undergoes negative expansion when formed as a high density, ultra-high-molecular weight (3-6 MDa) thermoplastic. It is also known that the introduction of even small quantities of nanometer-sized inorganic inclusions (see discussion above) that are uniformly dispersed into, and/or chemically/physically fixed to, an organic/polymeric matrix—forming a nanocomposite—which can produce material that possesses equivalent properties to the host polymer but with certain properties considerably enhanced including: size dependent temperature effects driven by surface tension interaction at the inorganic-organic particulate interfaces. Such effects provide considerable synergistic effects—carbon-polyimide composite (1 volume % addition of carbon nanoparticulate) coatings are known to exhibit a pronounced negative temperature coefficient of resistance (NTC) unlike conventional polymer-based composite films that show predominantly positive temperature coefficients of resistance (P Murugaraj et al 2006 J. Phys. D: Appl. Phys. 39 2072-2078). Additions of less than 10 weight % of a high purity carbon black nanoparticles promote a significant increase in thermal conductivity of the nanocomposite over a pure host polymer but also provide high absorption over the visible-infrared waveband (400 nm to 1,800 nm). Other NTE inorganic nanoparticle materials include the ZrMₓO_{y} (M=W, Mo, etc.) family such as ZrW₂O₈ and ZrMo₂O₈. Nanoparticles substantially less than 20 nm and preferably below 10 nm size promote greater temperature dependent effects and as such permit clean removal of the adhesive coating and any included inorganic nanoparticulate during the laser ablation process.

For use in the laser patternable peelable masking (LPM) processes of the present invention, the thickness of adhesive where an undercut feature might be required is in the range 1 to 10 microns with a pressure-sensitive peel-off adhesive strength on, for example, plastic sheet, glass, metal foil, and cardboard/paper in the range 0.1 to 5 N cm⁻¹.

The benefits of achieving a negative temperature coefficient of expansion (NTE) pressure-sensitive attachment adhesive include:
Easier removal for thin film coatings that are deposited by non-line-of-sight (partially conformal) processes; and
Excess heat removal from the melt zone created in the adhesive at the time of ablation removal to expose the substrate surface—minimisation of thermal damage to the substrate

The use of direct deposition methods, such as those described above, can be an alternative to introducing polymer sheet film contact interface surface treatments in order to enhance masking film-to-substrate media adhesion.

Masking Film Design

When considering use of a masking film for patterning, for example, PET-based substrate film, as is preferably used in large area macroelectronic circuit and flexible display manufacture, consideration should be given to thermal expansion differences between the substrate and masking film. With this in mind and given the fact that a preferred substrate material is polyester (PET) it is preferred to make the masking film out of such a material. Photoabsorbers may additionally be added to the masking film and pressure-sensitive securing adhesive in order to achieve an efficient laser ablation patterning process.

It will be appreciated that the PET masking film must be heated as to cause a localised melt pool, and it is the properties of the pool and associated melt therefrom that determines if the substrate surface will be damaged/changed as the masking film is locally ablated to reveal the substrate surface. The low tack (peelable) adhesive coating used to bond the masking film to the substrate surface must exhibit a melt temperature that is substantially lower than the melt temperature of the PET film—PET film melt temperature is dependent upon specific criteria (including heat stabilised, filled, and planarised electronic device grades) but is of the order of 260° C. Acrylic pressure sensitive adhesives generally have melt temperatures of the order of 130° C. (266 Fahrenheit). At this lower melting temperature it is expected that the PET substrate film will not be damaged, although some softening may occur due to the melt temperature of the acrylic being above the PET glass transition temperature of 75° C.—This however is dependent in large part on the specific properties of the laser-matter interaction.

It will also be understood that the melting point of a pure substance is always higher than the melting point of that substance when a small amount of impurity is present. The more impurity that is present, the lower the melting point, and a person of skill in the art can alter the melting point as appropriate. Eventually, a minimum melting point will be reached. In this regard, reduced melting temperature may also aid in ablating the PET masking film without damaging (although polymer softening might occur) the PET substrate film surface.

Broad Spectrum Photoabsorber

The use of a broad spectrum high efficiency energy absorber such as a high purity carbon black nanoparticle widens the scope of laser wavelength and type that can be evaluated for producing ablated patterns in the preferred PET-based masking film and integrated carbon black photoabsorbing low tack adhesive. The use of such particles are also described elsewhere in this application.

The suitability of carbon black nanoparticulate resides in the manner in which such particles are removed during the laser ablation process. Larger particles acquire heat by absorbing laser energy and the resulting heat radiates out to melt, and then vapourise the polymer host. As the polymer host melts the carbon particles move with the viscous melt. If the transition from solid to vapour is fast enough then the heat produced by the laser energy is rapidly removed with the expanding vapour and also ideally the hot carbon particle. If the heating process is slow then the carbon particles, as stated previously, move in the melt and because the vapour pressure is low the carbon particles are not efficiently removed leading to a concentration increase toward the masking film—substrate surface interface (the carbon particle concentration is most likely to initially occur at the masking film)—adhesive coating interface. Experimental data exists to support such a hypothesis—Ono et al (Ono, S. et al: Jpn. J. Appl. Phys. Vol. 36 (1997) L1387-L1389 Part 2, No. 10B, 15 Oct. 1997) who performed ablation experiments on composite materials consisting of elastomer and carbon black using a KrF excimer laser, and observed the development of visco-elastic cone-like microstructures that they ascribed to the aggregation of carbon particles leading to the formation of carbon-rich cones by repeated etching and melting upon further laser irradiation

The carbon nanoparticle size is also important in achieving a more uniform energy distribution, for a given carbon black concentration, as well as improving the removal efficiency of the carbon particles. This is due to either the carbon particle volatilizing in its own right (because of size dependent effects—surface initiated process—actually this relevant for other organic and inorganic nanoparticulates) or also due to the low mass particle being more easily removed by the expanding vapour. It will be understood that the carbon black nanoparticle size associated with the Cabot PLASBLAK PT4778 masterbatch is <26 nm (other sources of carbon black particles in masterbatch and ink forms are available from companies such as CHO YANG Corporation, A. Schulman, Inc., etc.).

Although high purity carbon black nanoparticles may be used to provide broad spectrum absorption, it is envisaged that specific applications or masking requirements for specific market sectors may be achieved using a wavelength specific organic photoabsorbing dye (or nanoparticle/quantum dot) for example Rhodamine 6G (R6G) absorbing around 590 nm. (Note care must be exercised in selecting a suitable dye due to lifetime, toxicity, handleability, and disposability issues). Inorganic pigments are known to reduce laser ablation threshold energy density in respect of PET film ablation but little is known about non-volatile residue—that is the removal of the photoabsorbing nanoparticles. Moreover, it is known that the use of pigments, including carbon black, may lead to dispersion and nanoparticle agglomeration.

Other suitable forms of photoabsorber include nano-tubes (and other geometries such as rods, coils, lamellae, etc.), frequency tuneable quantum dots and associated aqueous dispersions, and specifically engineered polymeric side-chain and dendrimer chemistry designs.

PET Film Absorption

As light passes through a film, for example, PET it will be absorbed (A) according to Beer-Lamberts law, I(z)=Iₒe^{-αz}, where I denotes the intensity of the light and α represents the absorption coefficient (α can depend upon the material; the light wavelength; the absorbing film temperature; other properties of the absorbing film).

The absorption coefficient for the reference clear PET film E47 was calculated to be 39.1 cm⁻¹ at a wavelength of 1,064 nm—note this is not a fully transparent medium at 1,064 nm wavelength but what is termed a volume absorber. Scattering is only found in volume absorbers and only under certain conditions. The absorption coefficient for the 1 weight % Cabot carbon black loaded PET film PET-CB1.0-2-01 was calculated to be 204.8 cm⁻¹ at a wavelength of 1,064 nm and for 2 weight % Cabot carbon black loaded PET film PET-CB2.0-2-01 was calculated to be 1,120.77 cm⁻¹. The latter sample has an absorption depth L, defined by 1/α of 8.92 microns (8.92×10⁻⁴ cm) that although is not a volume absorber, is not a surface absorber either because its absorption coefficient is less than 10,000 cm⁻¹.

Assuming a semi-infinite solid with temperature independent density p, specific heat c, thermal conductivity k, and thermal diffusivity D, the absorption depth L is the depth within which the incident radiation is absorbed.

If the masking film has a thickness d, of >8.92 microns then the laser pulse radiation will be absorbed within the film thickness to the depth defined by the absorption coefficient resulting in a specific temporal and spatial temperature profile that has a maximum temperature at the free surface.

Adhesive Coating Absorption

The absorption coefficient for the reference clear adhesive base film E959 was calculated to be 38.31 cm⁻¹ at a wavelength of 1,064 nm (volume absorber). The corresponding absorption coefficient for the 2.1 weight % Cabot carbon black ink jet ink loaded PET film 2.1Cabojet250-E595adhesive mix was calculated to be 922.43 cm⁻¹ at a wavelength of 1,064 nm—the 10 weight % loaded adhesive mix had a calculated absorption coefficient μ, of 3741.51 cm⁻¹, still not a true surface absorber. However, the absorption depth of order 3.7 microns is very close to the initial thickness of the adhesive coating to be used (typically in the range 1 to 5 micron).

Minimal HAZ

In order to minimise heat affect zone (HAZ) geometry it is preferred to minimise the temperature maximum, simply due to the fact that heat diffusion will occur outward from the source of the heat. Naturally, if the mechanism of polymer film removal is purely thermal in nature—that is the polymer must be heated to its melt temperature in order to liberate an associated vapour—it is essential that a thermal pool is achieved. HAZ minimization is a trade-off between melt temperature and rate of vapour loss if sufficient polymer is to be removed before the energy driving the melt temperature (energy accumulation from the laser pulse) is so dissipated as to be insufficient to heat the polymer resulting in a cool-down phase. HAZ minimisation also depends upon the thermal properties of the solid i.e. a strong absorber limits the accumulation of energy to a discrete volume which provides a means of reaching the melt temperature more efficiently, but at the same time any excess energy delivered by the laser pulse drives the temperature of the melt up. This melt temperature increase leads to greater vapour pressure and hence faster ablation of polymer, but also may cause increased material softening adjacent to the pool melt. If this polymer softening occurs at the substrate-mask interface (actually the substrate-adhesive surface) then potential damage to the substrate surface might ensue. It is such damage that is required to be minimised and preferably eliminated.

However, it will be appreciated that in some instances, controlled HAZ is both required and preferred—that is for embedded structures produced particularly in a polymer sheet substrate, such as PET, a controlled amount of heating might actually be a good thing. The reason is that if surface roughness is induced by the temporal and spatial nature of the laser beam ablation then it is possible to smooth this using a final heat pulse that has energy below the ablation threshold but high enough to promote surface melting/reflow leading to surface smoothing. Such a process may negate the necessity to apply a localized liquid planarising layer, but requires fine tuning of the laser ablation process. There is some evidence of this viscous melt flow for extreme UV excimer (KrF) laser ablation of PET as reported by Tokarev et al (Tokarev, V. N., Lazare, S., Belin, C., and Debarre, D.: “Viscous flow and ablation pressure phenomena in nanosecond UV laser irradiation of polymers”, Applied Physics A, September 2004, vol. 79, no. 4-6, pp. 717-720(4)).

PET Thermal Relaxation Time

In order to ensure that the HAZ length is kept to a minimum, it is preferable to use a laser pulse duration time that is shorter than the conductive thermal relaxation time. The thermal relaxation time is determined by equating the thermal relaxation diffusion length L=(4αt)^{0.5} to the optical penetration depth d, such that a pulse duration time of <τ=d²/4α should be used to ensure that heat diffusion will not penetrate beyond the optical penetration depth with a temperature sufficient to damage material beyond this point.

The thermal relaxation time for, for example, a polyester film is understood to be at least several tens of milliseconds—much longer than a typical laser pulse of duration 1 to 20 nanoseconds (usual pulse duration length for YAG laser technology) so accurate control over heat damage is below good. However much shorter duration laser pulses are possible—termed pico and femto second (see below).

One way of reducing the laser ablation threshold energy density, is to raise the temperature of the masking film and adhesive such that a reduced laser power would result in ablation. This should also remove the induction period observed under certain laser energy density pulses. It is believed that such elevated temperature would be both localised and transitory (specific pulse duration) in nature—this is to minimize temperature transfer to the substrate whilst heating up the masking film and to some degree the adhesive—and one way to achieve this is to use a dual pulse set-up with a known time-delay between the arrival of the pulse energy (as opposed to the creation and triggering of two separate pulses of energy). The time delay is defined on the basis of the thermal conductivity and thermal capacity properties of the masking film/adhesive coating and the substrate that the film has been attached to, and should be of a duration such that the masking film is brought up to peak temperature as the ablation pulse strikes the pre-heated element surface thereby introducing further energy to achieve ablation but at a lower threshold energy.

Spatial and Temporal Temperature Profile

Assuming that the penetration depth is much less than the diameter of the laser beam then the spatial and temporal profile of heat conduction can be solved in 1-dimension using:

∂T(z,t)/∂t=∂/∂z[(κ/Cₚρ)(∂T(z,t)/∂z)]+(α/Cₚρ)I(z,t)

where, T represents the temperature induced in the masking film, z is the position from the surface, t is the time, κ, Cp, ρ, and α denote thermal conductivity, heat capacity, mass density, and absorption coefficient of the masking film, respectively. Temperature profile for the PET masking film and the adhesive coating/layer are usually different but, it is this difference that is required to achieve the process control needed to produce a mask pattern which opens a deposition window onto the PET film substrate surface without damaging it.

Photoabsorbing PET Film Ablation Laser Selection

In preparing, for example, a PET-based masking film, it is possible to use several types of laser at differing wavelengths as presented in FIG. 56.

The adhesive coating has an even stronger absorbtivity as disclosed in FIG. 57 over the 175 nm to 1,800 nm waveband.

Most current infrared laser technology uses pulses of energy that have pulse durations in the range 1 nano second or longer. Using longer pulse times for the ablation of a material allows for reaching the material evaporation state before the pulse of energy has been experienced by the material. This is because the plume of material vapour thermally evaporating from the surface being ablated can act as a mask for the remainder of the incoming laser pulse thereby stopping such energy from assisting the ablation process. In effect this means that the efficiency of the ablation process is impaired by the degree of masking that occurs from the on-set of the material ablation (thermal expulsion).

Another embodiment of the LPM process that addresses the melt zone issue raised above is the use of a thin adhesive coating (as described in this specification) that is highly absorbing at the laser wavelength of interest. It is known that aqueous compatible infrared absorbing dyes, specifically absorbing at or close to 1,064 nm, exist that have absorption coefficients, α, of order 100,000 cm⁻¹. For a thermally insulating material such as the envisaged low tack adhesives of the present invention, the photon absorption depth, L, (L=1/α: α=the absorption coefficient) would be 100 nm into which all of the laser pulse energy would be absorbed. If the laser pulse duration was very short, typically a few nano seconds or less, then the rate of heating and subsequent thermal melt zone flow rate would permit the lower temperature adhesive material to vapourise without damaging the surface of the PET substrate underneath.

In addition, film forming polymers and/or a low tack adhesive coatings may be produced which absorb more efficiently in the infrared (also true for other wavelengths spanning the UV, visible, and near infrared).

Ultra Short Laser Pulse Technology

Since the objective of the present LPM processes for use with infrared lasers is to remove (ablate) material using a pulse of heat energy, it is important to understand the interplay between the masking film system (base film and adhesive or alternate system) absorption coefficient at the wavelength of the laser, overall masking system thickness, and the magnitude of the pulse energy and duration. In this regard the preferred use of several laser types/wavelengths is to maximise the versatility of the processes of the present inventions in respect of a wide range of substrate types, whether pre-processed or not, in order to increase the window for damage-free cleaning by varying the pulse duration, pulse energy, and laser wavelength. If a high absorption coefficient material is used for the masking film/adhesive then the infrared laser pulse energy rapidly heats up the absorbing volume with relatively little thermal conduction loss due to the low thermal conductivity of the polymer materials used in the masking system. It is with this in mind that pico second laser pulse technology may be applied to the present processes. The shorter duration pulse energy can be rapidly absorbed and converted into a very shallow melt front that volatilises the absorption volume, and as it evaporates it takes excess heat energy away with it, thereby minimizing the amount of heat that can contribute to the creation of a heat affected zone (HAZ). Such pico second infrared lasers, including mode-locked Neodymium YAG and 1,070 nm ytterbium-fibre amplified lasers, provide a very cost effective means of ablating materials at high speed and resolution.

It is also possible to use even shorter duration pulse lengths than pico second pulses—termed femto second pulses. Femto second laser excitation of materials involves several fundamental physical processes that differ from longer pulse laser-matter interaction including: energy deposition, melting, and ablation; that have well separated time windows with respect to the pulse duration being employed. Such ultra short pulse lengths may introduce near-threshold ablation anomalies that have potential in achieving auto etch stop ablation of the masking system on a substrate surface without, introducing damage to the substrate surface as the masking film is ablated cleanly from it.

Examples of a Femto second infrared laser include a titanium sapphire laser.

Pattern Creation

It will be appreciated that the processes of the present inventions may be used with a variety of patterning methods, dependent upon the application requirements with particular reference to feature resolution and deposit film thickness. In this regard the following processes are specifically highlighted:
Single or multiple laser systems (also termed laser scalpels, etc.)
Semiconductor laser wafer arrays (sometimes termed a laser linear bar or print bar) and physically-butted discrete solid state lasers on cooling bars
Rotary cutter (plotter or flat-bed based)

The Laser Etching Process

There are numerous solid-state and gas-based laser systems that can be used to produce, or assist in the production, of patterning features in the mask. It is desirable if they possess photon energy wavelength in the range several microns (IR) through the visible to <190 nm (deep UV). Such laser systems include: Excimer [in the range 308 nm to 157 nm]; Diode-pumped YAG [2,128 nm to 266 nm (Quadrupled)]; and electronically tuneable Ti: sapphire (189 nm to 1,064 nm—femtosecond pulse). Other possible laser technologies include, diode pumped solid state Nd:YVO4, semiconductor diode laser, Q-switched and flashlamp-pumped lasers such as Nd:YAG or Nd:YLF lamp-pumped Q-switched.

The pattern shown in FIG. 1 can be produced by a laser having the following specifications:
Diode pumped solid-state Nd:YVO_{4;}
Repetition rate 100 kHz;
Wavelength 355 nm;
Pulse width in range 10 to 30 ns;
Average power 2 W; and
Writing speed 2 m second⁻¹.

An alternative, equally suitable laser, would be an excimer laser having the following properties:

| | |
|---|---|
| Pulse repetition frequency | 250 to 1,000 Hz |
| Pulse width | 10 to 30 ns |
| Operating wavelength | 248 nm |
| Multimode, M² | >100 |
| | 35 |
| Energy density | >10 J cm⁻² |
| Feature resolution | 2 μm (minimum limit) |

An alternative, equally suitable laser, would be Diode-Pumped Solid-State YAG laser having the following properties:

| | |
|---|---|
| Output power | 400 Watts (measured at 10 kHz pulse |
| | repetition rate) |
| Pulse repetition frequency | 6 to 50 kHz |
| Pulse width | 20 to 200 ns |
| Operating wavelength | 1,064 nm |
| Multimode, M² | 20 to 70 |
| Energy density | >100 J cm⁻² |
| Feature resolution | 3 to 5 μm (minimum limit) |

Yet another alternative is the use of an infrared laser (1,064 nm DPSS YAG or 1,070 nm pico second ytterbium-doped fibre), which may preferably be used to ablate, for example, a PET-based masking film that is bonded to a substrate PET (polyethylene terephalate) film using a low tack (peelable) adhesive—where the ablation etching of the masking film-adhesive system is automatically terminated on the surface of the PET substrate without causing any damage to it. Since the chosen laser wavelength is in the infrared section of the electromagnetic spectrum the mechanism of ablation is understood to be purely thermal—that is the film used must be locally heated using the pulsed laser beam so as to induce a phase change from solid polymer to a liquid melt pool that provides a vapour source for polymer removal. This method may be used to achieve a required mask pattern.

The feature size produced by the laser patterning depends upon the specific application requirements. Feature size has a close relation to the performance of the materials used in the device build, they together enable a desired device performance being sought. By use of a peelable mask manufacturing process, materials that are difficult to etch using conventional processes can be used, making high performance devices possible at a wide variety of feature sizes. To produce laser etched feature sizes in the range 0.1 to 100 microns generally requires different laser systems to achieve features in the range 0.1. μm to 1. μm, 1. μm to 5 μm, and 5 μm to 100 μm. Such different systems may be used to form patterns on the same peelable mask layer to enhance flexibility and lower costs.

Alternative lasers which may be used in the processes of the present invention include:

Semiconductor Diode Lasers

Semiconductor laser types are sources of light energy in a focussed beam form. In this respect one source of such technology is the Intense Limited INSIam technology (see FIG. 60; which can provide an array of up to 1,000 individually addressable laser elements that may be placed side-by-side and that can operate over the wavelength range 0.65 μm to 1.67 μm. It is also possible to integrate micro-optic elements with the array to provide individual focussed or collective overlay focussed laser beam profiles, which may form discrete ablations or ablations resulting from exposure with a continuous line pattern.

The compactness of the laser linear array allows for the provision of a semiconductor wafer scale LPM patterning system based on:
1. High resolution LCD or similar addressable light aperture
2. X-axis linear laser array
3. Y-axis drive
4. Z-axis drive
5. PC system x-y-z control, processing, and wireless image transfer

Diode Laser Linear Array System

Diode laser linear array systems may be used to ablate material over small substrate widths (discrete samples or roll-to-roll substrate or masking [off-line patterning] media) using a static positioned electronically addressed individual laser element array, to direct write transfer an image into a masking film on a line-by-line basis. A (x-y) computer-aided design (CAD) pattern construction and transformed image transfer may be achieved by moving the substrate in the y-axis as the laser array is addressed in the linear array x-axis.

Preferably, the laser array may be position controlled in the z-axis in order to provide a means of using the individual laser element laser beam output geometry, or associated micro-optic element, to achieve (i) laser overlap for line ablation by increasing the height (z-axis) between the laser optic and the masking film; or (ii) to provide high resolution image transfer by decreasing the height between the laser optic and the masking film. As the height is adjusted so the PC controller readjusts the laser output power to compensate for exposure area change to maintain a constant average irradiance power or ablation energy density.

Pulse Duration Issues

Since the diode lasers discussed above have a wavelength range 0.65 μm to 1.67 μm, heat will be introduced during ablation, there is a preferred need to use short and even ultra short pulse durations to minimise the heat affected zone (HAZ). Some diode laser set-ups deliver tens of nanosecond pulses. It is also possible to use a light shutter array to control the red/infrared light energy by using a fast switching scattering medium—such as a suspended particle or liquid crystal display element—that when switched reflects the light energy. Such approach permits short pulse processing at high repetition rates.

The simple, one mask process described above can be used to produce a working transistor. From the structure shown in FIG. 1d, a single direct write laser etch is used that delineates the drain and source contacts. The associated gate length contact spacing is also delineated during this etch from a continuous area of transparent thin film conductor that covers the whole surface of the substrate 10. The single mask system makes use of a dual laser process in the following manner. A plastic sheet flexible or rigid substrate that has deposited on to it a series of parallel stripes of a transparent conductive oxide, such as Indium Tin Oxide (ITO), is presented to the direct write laser process without any masking film at this stage. The first laser process is applied to this stripe patterned substrate so as to convert the stripes into an array of square lands of ITO. The substrate with square lands of ITO is now covered with an ultra thin masking film and then presented to the next laser station for the second laser etch. This etch dissects the ITO land to form the thin film transistor drain and source contacts. The masked and laser etched substrate is now taken to the deposition station where the semiconductor, gate insulator, and gate contact are deposited in a single process after which the masking film is peeled away to cleanly remove the excess thin film deposit leaving an unconnected array of thin film transistors.

Typical Applications

Typical applications for diode laser linear array systems are the patterning of, for example, pre-processed silicon wafer surfaces (1020) (including the processes disclosed throughout the present application) to expose windows (1022) in the laser patternable peelable masking (LPM) film (1024) that provides access to contact pads on the silicon wafer (see FIG. 61). These contact pads may form part of a silicon device such as a signal integrator. The window in the masking film serves to pattern a suitable thin film such as a zinc oxide (ZnO) dielectric that acts as a gas sensing coating or as a piezoelectric transducer element on the pre-processed silicon circuitry. The windows in the masking film are preferably opened using the addressable semiconductor diode lasers (1026) where specific lasers are switched on to initiate the laser ablation of the masking film. The use of semiconductor lasers of a wavelength in the visible waveband (400 nm to 700 nm) means that standard optical alignments may be used to provide pattern overlay alignment. It is also possible to use a CCD μcamera (remote micro camera chip with integrated micro optic) to image a fiducial reference set of points on the pre-processed substrate wafer from which to align the laser array prior to ablating the required masking film window pattern.

An Embodiment of a Two-Mask Technique

The technique can be made more powerful, however, and more complex devices constructed, if two or more masks are used. FIGS. 2 to 4 show examples of structures formed at various stages in such processes, which use two peelable masks.

A first peelable mask 20 is laid down on a substrate 22 in a first manufacturing stage. A focussed laser beam 24 is used to dry etch through the mask 20 and also cut into the substrate 22 to form a trench therein, as shown in FIG. 2b. Two layers of material are then sputtered on to the substrate 22 and the mask 20, using, for example a closed-field unbalanced magnetron sputter ion plating (CFUMSIP) process. An environmental barrier layer 26, made of silicon dioxide, aluminium oxide, parylene (organic film)-silicon oxide multilayer, or inorganic transparent multilayers is deposited adjacent to the substrate 24, and a transparent contact layer 28 is deposited atop the environmental barrier layer.

The first peelable masking film is then removed, as outlined above. As shown in FIG. 2d, the transparent contact layer is aligned with the top of the trench 16 in the substrate, when the mask is removed.

A perspective view of structures formed during the course of this process is shown in FIG. 3.

A second peelable mask 30 is then laid down on the structure, as shown in FIG. 4a. The thinness of this layer gives it the ability to conform to the structure, even if perfect alignment of the deposited layers has not occurred. The mask is aligned to the first mask patterned features using fiduciary marks formed around the substrate media edges. The fiducial marks can be introduced during substrate manufacture or as part of the feature etching process along the periphery of the substrate or along one or both edges of a roll of material.

A further laser dry etching stage now takes place, a pattern being formed in the peelable mask. In addition, the transparent contact layer 28 is bisected to form drain 32 and source 34 electrodes having a gap (to become a transistor gate region conduction channel) 36 between them, as shown in FIG. 4b.

Another deposition step now takes place, with semiconductor 38, insulator 40, and gate electrode 42 layers being deposited as shown in FIG. 4c. The semiconductor layer 38 is deposited in a gap left between the drain 32 and source 34 electrodes, the top of the layer aligning with the top of the transparent contact layer 28. An ultra-thin bandgap alignment layer (not shown) is deposited on the semiconductor layer 38. The insulator layer 40 is deposited on the bandgap alignment layer (not shown) and the gate electrode layer 42 is deposited last. The gate electrode layer 42 and the insulator layer 40 are deposited in a trench 44 formed as part of the pattern etched into the peelable mask.

The second peelable mask is then removed, together with waste coating, to leave a complete isolated thin film transistor device, as shown in FIG. 4d.

The peelable masking film process therefore can provide a means of etching a proportion of the substrate material that has been covered by the masking film. This means that an etch feature such as a trench or well can be produced in the substrate that is aligned with the etched hole created in the masking film. The alignment is inherent, as both are produced in the same process, and greatly superior to conventional techniques.

Additionally, the etch region of the substrate material can be laser smoothed after etching to produce a highly smooth surface finish onto which to deposit a coating or conversely the etched substrate surface finish could be deliberately roughened so as to provide mechanically enhanced coating adhesion or an increased surface area for microfluidic surface chemistry reaction and/or catalysis.

Alternative Pattern Generation

Masks for use in the processes of the present invention may be patterned off-substrate and then transferred onto the substrate before processing. The mask, if it is in a coating form is produced on a siliconised surface energy controlled paper or plastic sheet film release liner and is further covered with a similar release liner or is coiled onto a drum where the rear surface of the single sheet release film is also so treated to provide a very low bond strength to the mask. The mask in coating form is produced on the release liner and then patterned using, for example, a laser such that the resulting patterned mask can further be transferred by pressure roller and lamination methods on to a substrate surface of choice thereby providing a patterned peelable mask onto a substrate without introducing damage to the substrate surface or coatings thereon due to the method used to pattern the mask. If one release liner is used, it is removed once the mask has been attached to the substrate. If a liner/substrate/liner sandwich is used, one liner is removed to expose the mask surface that will be use to attach to the substrate. In a further embodiment the release liner, or liners if the mask is sandwiched between two such materials, is transparent to the wavelength of laser to be used to ablation pattern the mask (mask coating) so that a pattern can be generated in the mask (mask coating) by directing the laser light onto the mask surface directly or by passing it through the transparent release liner.

Patterns for use in the processes of the present invention may also be formed off-line and then transferred onto the substrate to be patterned. As an example, a section of selected low tack (<1 N cm⁻¹) 3M type 5001A polyethylene protective tape was laminated onto a 125 micron thick piece of poly(ethylene-2,6-naphthalate) [PEN] plastic sheet, and a second piece of PEN sheet placed it on top of the masking film so as to form a sandwich. A mechanical punch was used to produce two holes through the sandwich so as to ensure clean hole-edges. It will be appreciated that it is possible to use a more cost-effective over-laminate film to protect the resulting features particularly for use with an array of mechanical punch and dye pattering pieces.

The top sheet of PEN was removed and the 3M 5001A masking film was peeled off the bottom PEN sheet and reapplied to a second cleaned piece of PEN sheet.

In this example for demonstrating the off-line principle, rapid dry Tipp-Ex white correction fluid was used because of its highly viscous nature and its fairly rapid drying time. The Tipp-Ex was applied with a wedge brush over the masking film adjacent to and including the punched holes. The masking film was again peeled off this surface.

Clear hole-patterns were formed on the PEN substrate reproducing the pattern produced in the masking film.

The corresponding peeled-off mask used to produce the two white circular features can be re-applied/reused/disposed of, as required.

It must be noted that the example disclosed makes use of a thixotropic fluid. When using such a process, consideration should be given to what was applied to the mask and subsequently given to optimised coating, drying, and masking film removal conditions. The above example provides a simple demonstration of the potential use for generation of patterns using the peelable masking process for processes by:

Micro stencilling where the pattern can be produced:
Mechanically
   step-and-repeat punch and die
   x-y addressable plotter rotary die or micro blade cutter
   High-speed water jet cutting
   Hot knife patterning
Digitally
   Pulsed laser (UV, visible, IR)
Liquid source patterned coating deposition based on
   Precision spraying
   Digital ink jet printing
   Screen printing
   Doctor blade fluid draw-down
Production of repositional microfluidic structures
   Liquid source thin film transistor manufacture
   Permanently bonded microfluidic channels
   Mural “Stick-n-Peel” patterning mask

Micro stencilling has potentially a wide appeal for direct production of peelable masks for subsequent thin film processing thixotropic pressure-sensitive adhesive (such as acrylic, urethane, silicone-based, etc) liquid is then forced through the micro stencil to produce a contiguous or non-contiguous peelable mask pattern at a resolution of greater than or equal to 800 dpi (less than or equal to 32 microns).

A complementary concept is to use a variant of the thermal print head technology to make a peelable adhesive material that produces a digital contiguous pattern. The key point in achieving the direct thermal printing of a peelable mask resides in the use of a mask material that either undergoes localised shrinkage when heated or that readily flows out of one surface to form a ridged-hole when locally heated. This means that the mask can be produced (1) on a release liner for transfer onto a substrate, or (2) directly on a substrate surface (taking due regard for thermal dissipation into the substrate) or (3) as an intermediate option of thermally patterning the peelable mask material just as it is released from the release liner but prior to it being attached to the substrate surface.

Deposition Processes

The provision of the etched feature in a substrate using a peelable mask means that a whole area process such as magnetron⁻sputtering or discrete area process such as digital ink jet printing could be used to deposit a thin or thick film into the etched substrate feature using the mask to ensure that any excess material is removed when the masking film is peeled-off the substrate. This provides a means of ensuring that several coatings could be deposited into the etched substrate feature that are vertically aligned to each other whilst being isolated from other devices because of the nature of the pattern formed in the peelable mask and that it removes excess material when peeled off. Such multiple coatings could be achieved using a mix of processing methods such as laser ablation, ion beam deposition, electron beam evaporation in several processing chambers and at atmosphere or under vacuum. Such multiple coatings could also be achieved with one process using several differing materials in one process such as a range of ink types from an array of digital ink jet printheads or through the use of a multiplicity of magnetron sputtering cathodes in a single chamber or cluster tool.

By way of example the use of a multiplicity of magnetron cathodes provides many important benefits to the production of a thin film transistor because using the peelable masking and laser etched deposition window described above it is possible to deposit the heart of the transistor—the semiconductor, gate insulator, and gate contact—and, in particular, the important semiconductor-substrate and semiconductor-gate insulator interfaces, in a single processing step in a single vacuum chamber under very clean and highly controlled conditions. This has considerable positive implications for thin film and associated interface quality as well as minimising processing and masking steps that impact product yield and cost.

However Closed field Magnetron Sputtering (CFM) as described above, is just one of many physical vapour processes that can be used to produce a transparent thin film transistor based, for example, on semiconducting ZnO. CFM is a process that provides a high ion current density and maintains the ion-to-neutral ratio at the film growth surface as the power to the magnetron cathode is changed thereby maintaining the quality of the ensuing film microstructure (more detail is provided in GB 2 258 343, U.S. Pat. No. 5,554,519, and EP 0 521 045). The incident ions arrive at the growth surface with low energy impaction or impingement (typically less than 50 eV but preferably less than 5 eV) and it is this low impact energy coupled with the high ionisation efficiency that provides for a low temperature growth environment, very smooth oxide surfaces, very low oxide absorption coefficients, k, and high density coatings which are necessary to produce a high quality device on a temperature sensitive substrate such as PET.

Alternate processes to closed-field magnetron sputtering include, but are not limited to: laser ablation; ion beam sputtering; ion beam assisted deposition; vacuum arc (or multiple arc); electron beam evaporation; atomic layer epitaxy; molecular beam epitaxy, chemical vapour deposition, electron cyclotron resonance chemical vapour deposition, plasma enhanced chemical vapour deposition or laser dry transfer printing.

The processes of the present inventions allow for widespread use of digital ink jet processing of finer features than hitherto thought feasible. For such free-surface direct write process the properties of the ejected droplet as it impacts and spreads on a surface, coupled with the nature of the surface (such as topography, cleanliness, chemistry, etc.), can lead to incidences of liquid bridging (and splashing) due to surface tension driven flow that can impair or destroy the performance of the circuit for which the printed pattern is being used. The use of the present processes provides a means of achieving very high resolution track and gap with a masking film that also serves to eliminate liquid bridging. Removal of the mask removes excess material and allows for high density circuitry at much higher yields than currently possible.

If the required pattern is non-contiguous in the x and y directions, then a single masking film may be used. This aspect of the laser patternable peelable masking (LPM) processes of the present inventions provides a very valuable extension to current digital printing technology.

Precision Spray Approach

Direct write methods may be used to pattern a wide range of materials and in this regard digital ink jet printing (D-IJP) a preferred process (as described above). However, the use of D-IJP has several limitations that were partly discussed above including:
High droplet volume
Limited range of fluids due to restrictions imposed by the practical ability to produce a monodispersed droplet stream (droplet ejection constraints that for some applications can be relaxed to include the controlled occurrence of smaller satellite droplet(s) with the main droplet
Complex printhead electronics needed to select a nozzle for droplet ejection
Multiple printhead technology required for very large area patterning—butted together to provide a higher resolution of print than available from a linear array nozzle spacing of a single printhead or to provide a wider fixed width print swathe so as to negate the need to use some form of printhead transport mechanism (shuttle head technology)
High resolution patterns—even using differential surface wetting behaviour—can still result in liquid bridging
Maintenance of printhead technology required—nozzle blockage and partial blockage are of considerable concern for device printing

Typical spray compositions have a range of droplet diameters centered on a specified mean—for example a droplet range d₁₀ to d₉₀ of 0.2 to 1.8 micron for a 1 micron mean. This provides much better droplet coalescence for film formation and also means that much less liquid is used to achieve a continuous filling of a mask pattern deposition window. This also means that for a given film thickness a solid content can be specified that requires minimal evaporative loss of the carrier solvent compared to that required for an equivalent film produced using digital ink jet printing. Typical spray coating processes is to use a linear or area array of nozzles that can be selectively switched on continually, or pulsed on for a pre-set pulse duration, to provide a low resolution means of coating areas of a laser patterned peelable masking film. This further minimizes the waste of expensive fluids such as a gold nanoparticulate ink for the printing of gold electrodes or contacts.

A particular feature of the present inventions is the fact that the various forms of precision spraying available (whether electrostatic field assisted or not) allow for a significantly much wider choice of liquid properties: from aqueous to solvent; very low viscosity to thixotropic; high to low solid containing; and even solid particulate (nano or other size). This in turn provides for a much more versatile, and lower cost, processes than normal digital ink jet processes particularly where the mask pattern can be produced off-line (non-contiguous designs in x-y space). The adhesive coating used to provide the low energy attachment of the masking film to the substrate surface may be formed from adhesives that are of themselves low energy surfaces—that is they are highly non-wetting. This feature means that the semi-dried liquid/ink feature does not make a high energy contact with the masking film adhesive thereby permitting easy removal of the film plus coating residue without lifting the required patterned solidified ink.

Other benefits of the present processes in conjunction with the generic technology of spray coating include:
Low fluid volume for a given area of coverage and film thickness compared to digital ink jet printing
Simpler and more versatile liquid delivery
   Large substrate areas
   Wide roll widths
   Multiple spray stations for multi-layer coatings of different materials
Wider liquid properties can be dispensed than available for digital ink jet
   Wider viscosity and surface tension range
   Wider solid content
Simple multiple coatings that are auto aligned
Surface feature curvature control through contact angle liquid-mask properties design—dependent upon the geometry of the required patterned feature
No liquid bridging between adjacent patterned features
Very high resolution “track and gap” patterning
2-layer masking process for creating integrated embedded structures

Application Examples

Transparent Conductor

A display panel requires an electrode layout that provides power and data to the switching transistor circuit adjacent to each of the display panel's picture elements. Such electrodes can be transparent (ITO, ATO, ZnO:Al. etc.) or opaque (Au; Ag; Cu, etc.) and generally require a print width of less than 20 microns. Such fine features place great demands on state-of-the-art digital ink jet systems particularly in respect of edge quality, film uniformity, and localised splatter resulting from misfiring nozzles or satellite droplets.

Using the present processes, a pressure-sensitive low attachment energy adhesive-backed masking film may be laminated to a surface to be patterned and a suitable laser (such as a 266 nm or 1,064 nm DPSS YAG) forms a pattern in the film that provides the necessary deposition window trenches and wells into which the digital ink jet printing ink may be dispensed. The masking film, being a bilayer structure, provides a versatile process for achieving a wide range of print solutions at high resolution. For example the use of the ink jet process for producing transparent conductors is partly limited by the performance of the film produced in this way but is also limited by the need to take more than one print pass to achieve the film thickness. Multiple pass prints whether liquid-on-liquid or liquid-on-solid invariably result in an electrode cross-section that is not uniform—leading to complex electrical current flow behaviour. Using the LPM processes in conjunction with a low surface energy (non-wetting adhesive), for example, silicone-based low tack adhesive of a thickness preferably somewhat greater than the required electrode thickness allows for contaminant of the liquid from the ink jet print process to be achieved such as where the liquid is dried (air or other atmosphere) or solidified (UV, visible, IR radiation; electron-beam exposure) wherein the viscosity change permits the masking film to be removed without impairing the quality of the required printed feature. Moreover, because the adhesive is essentially non-wetting to the printing ink/liquid the containment wall contact angle can be adjusted to achieve close to zero contact angle (printed feature surface edge is at 90° to the masking film wall face). This also imparts a degree of discontinuity between the printing ink flowing on the masking film surface and into the laser ablated trench/well that not only assists peel-off removal of the masking film and printing ink residue but also suppresses any liquid bridging between adjacent patterned tracks or other features.

A further embodiment of the invention is to use a conductive ink formulation that includes an ingredient (such as ZrM_{X}O_{Y} nano particles—such as the negative thermal expansion compound ZrW₂O₈) that promotes contraction of the printed feature nanocomposite coating thereby causing it to recede from the masking film, thereby further assisting masking film removal whilst enhancing the printed feature density (increasing) and feature size (track width—with some height reduction unless the contraction is directional).

An extension to the above, and yet another embodiment of this invention, is the use of a two-layer masking system (for example as disclosed above) (or more masking layers within the limit of being able to peel-off the uppermost layer (1030) without disturbing the layer(s) below (1032)) that has differential attachment adhesive strength between the two-layer mask-to-substrate and between the upper (1030)-to-lower (1032) masking films. This approach provides a means of achieving a patterned feature of one material that is embedded or surrounded in x-y space by another material—for example (1) an optical waveguide core (1034) surrounded by an optical cladding material (1036) of a greater refractive index than the core (see FIG. 62), or (2) a coloured material (1038) surrounded by a containing rib or structure (1040) that has a black, neutral, or contrasting colour as might be required in the production of the transmissive display colour filter (see FIG. 63).

In the case of the optical core cladding the permanent adhesive properties may be optically matched to the cladding film so as to ensure uniform optical confinement down in the z-axis direction the whole wall of the cladding structure.

Clearly, although the examples discussed above are directed at digital ink jet printing it is anticipated that precision spray deposition methods can be used to achieve equivalent patterned features.

Organic Semiconductor

To illustrate the point of using spray deposition to achieve features currently produced using known digital ink jet printing, reference is made to manufacture of an organic transistor based on, for example, a liquid phase semiconductor [regio-regular poly-3-hexylthiophene (rr-P3HT)] and an organic electrically active buffer contact layer {PEDOT-PSS [Poly(3,4-ethylenedioxythiophene)-poly(styrene sulfonate)]} to the transparent ITO electrode and an insulating nanocomposite for the gate dielectric [i.e., poly-4-vinylphenol and titanium dioxide nanoparticles (PVP-TiO₂—reference: Fang-Chung Chen et al, Applied Physics Letters, Vol. 85, No. 15, (2004) pp 3295-97)]. The specific transistor configuration shown in FIG. 64 is termed a top gate device because the drain and source electrodes (1042) are patterned and deposited first. A second masking film (1044) is then applied, in this instance using low resolution patterned spray coating, which is patterned using optically aligned laser ablation (1046) methods to produce the deposition windows in the masking film into which the tri-layer semiconductor—gate dielectric—gate contact coatings are spray deposited (1048) using a multi-station in-line assembly or roll-to-roll manufacturing process.

The 2^{nd} spray coated masking film with residual coating material is then removed to reveal a complete array of isolated organic thin film transistor (1050) (O-TFT or organic field-effect transistor O-FET).

Digitally Print the Peelable Masking oating

It is known that digital (drop-on-demand and continuous jet) ink jet printing may be used to direct write masks on to surfaces. However, the formation of such a mask has not been directed at the mask being whole area peelable whether laser ablation patterned or not. Moreover, laser trimming of the ink jet printed mask is also possible.

Once advantage to this process is the ability to produce moderate feature size patterns directly with digital ink jet printing along side areas that can be further laser ablation patterned to achieve very high resolution features (<5 microns) that cannot be achieved using previous digital printing methods (resolution even greater than off-set lithographic printing at 5 micron resolution). Integrated digital ink jet printing and laser direct write ablation processes may be used to produce medium and high resolution features in a whole area peel-off patterning mask.

However, not all of the potential deposition processes that may be used in peelable mask microelectronic device fabrication are what is termed line-of-sight. This means that consideration has to be given to the manner in which the masking film is coated during the device build. This is especially so at the mask-substrate interface that is exposed by the laser etching of the required deposition window pattern, for example, as shown in FIG. 2b.

Considerations Affecting Peel-Off—Solid Deposition Coatings

A highly desirable feature of the peelable mask fabrication process is achieving a clean peel-off for the masking film after the required film or films have been deposited. Those deposition processes that produce conformal coatings such as non-line-of-sight processes such as PECVD, ECR-CVD, CVD, plasma polymerisation, variants of magnetron sputtering, variants of spray coating, etc, pose the greatest challenge in this respect since they will provide a uniformly thick coating over the mask and substrate alike. Irrespective of the masking film wall, the “throwing power” of the film deposition process may provide a coating at the mask-substrate surface that might impair the peelability of the masking film.

The degree of impairment will depend on the overall thickness of the deposited film or films, and the mechanical strength of the film to resist forces during the peeling process. There is likely to be greater impairment where the deposition process coats the interface between the mask 20 and the substrate 22 in the laser etched trench 26. There is a risk that peeling the mask away will tear the deposited film or films from the substrate along with the masking film and so may introduce a degree of patterned film edge tearing/material removal.

By choosing the material properties of the mask, substrate, and deposited films, and the manner of adhering the mask to the substrate, carefully, the bulk of the required deposited film or films will be left substantially intact and adherent. It is anticipated that even for a conformal coating covering the masking film an adequately clean peel-off process can be obtained by ensuring that the contact cross-sectional area of the deposit at the peel-off interface (in the vertical plane of the masking film and substantially at normal incidence to the peel-off force direction) multiplied by the intrinsic bond strength of such a coating or multiple coating is less than, and preferably much less than the interfacial bond strength of the deposit to the substrate surface multiplied by the contact area of the deposit (essentially the etched window in the masking film).

FIG. 38 shows schematically a cross-section through a conformally coated substrate 600 covered by a mask 602. The coating comprises a barrier layer 604 and a TCO 606. These layers have coated an upper surface 608 of the mask 602, a side surface 610 of the mask 602 and a upper surface 608 of the substrate 600.

At the upper surface 608 of the substrate 600, a, the ease of peel off is represented by:

Thickness of TCO layer x contact area of TCO layer x interfacial bond strength by ^{SI}=d_{TCO}A_{TCO}φ_{S}

At the side wall 610 of the mask 602 the peelability is equal to =thickness of multilayer coating×cross-sectional area×intrinsic bond strength of layer on layer i.e.=D_{MC}A_{SCMC}ξ_{SB}

For ease of peel off without removing the required coating (TCO) in the well then: a >> than B i.e. D_{TCO}A_{TCO}φₛ>>D_{MC}A_{SMCM}ξ_{SB}

Assuming no overhang in the mask and that the coating around the mask is essentially conformal.

The degree to which such tearing will act to remove the whole or a significant proportion of the required patterned film or films depends upon the magnitude of the deposited film or films bond strength (adhesion) to the exposed substrate surface resulting from the laser etching of the required pattern deposition window. Poor adhesion will tend to favour complete removal of the required patterned film or films with the masking film. The converse is true for high bond strength deposits.

The use of sub-surface etching of the substrate tends to mitigate to some degree the effects of conformal coating because at the masking film-substrate surface edge line the planarity of the etched wall that comprises the masking film and substrate material will be inhomogeneous due to differential etching rates and localised laser induced chemical-assisted etching effects (i.e., enhanced polymer etching due to activated oxygen liberated from the polymer and substrate materials during etching). This inhomogeneity, although coated by the conformal process, will have a distributed coating weakness along the interface line that will act like a perforation cut as in a tear-off slip such as a cheque from the cheque book stub, rendering this region weaker thereby assisting the clean removal of the masking film and unwanted conformal coating film or films.

Other methods may be used to assist with the clean removal of the masking film and unwanted conformal coating film or films. Peeling may be enhanced by debonding methods such as thermal, electrostatic, air pressure, chemical etc. that are aimed at the peel interface junction to assist and/or accelerate the peeling process. For instance, an air-blade “knife” (air jet nozzle generated wedge aimed at the mask-substrate interface) that helps to separate the mask from the substrate, heat (used to weaken the thermoplastic mask mechanical bond to the surface), and/or anti-static to assist the peel-off.

The peel-off edge of the required film deposit does not need to be straight and/or parallel. Peel off at the vertically aligned semiconductor-to-gate contact stack is not as crucial as it may seem, since the semiconducting film is in intimate contact with the drain-source contacts and in ultra thin band-gap alignment film is in intimate contact with the semiconducting film surface along substantially its entire area such that minor disruption at the edge of the stack will not substantially impair the performance or operation of the thin film transistor. Nevertheless, it is of considerable benefit to ensure that the interfaces of the vertically stacked films possess excellent adhesion in order to ensure that a plane of weakness does not exist at such interfaces thereby rendering the device potentially inoperable if failure occurred at such an interface.

Considerations Affecting Peel Off—Laser Heating Effects

The peelable mask manufacturing process is designed to be simple but to have the stretch capability to achieve very high pattern resolutions, as required, and as such is based on the technique of laser etching/ablation so that a range of laser beam types and irradiation wavelengths can be employed. Both thermal and non-thermal laser etching can be used but preference is given to non-thermal processes that provide material lattice bond scission without, or at least with the minimum of, heat generation.

The primary reason for minimising/eliminating laser etch induced heating is the need to be able to peel-off the masking film at the end of a specified deposition process. Excess heat generated by the etching of a deposition window might affect the masking film edge bond state by virtue of localised welding or melting, irrespective of whether the masking film has been attached to the substrate surface using electrostatic or adhesive co-polymer or bond film methods. Preferably the masking sheet material is bonded to the polymer (or glass, paper/treated paper) substrate sheet material in a roll lamination process where the masking film is held in place by electrostatic attraction in order to keep the substrate-mask interface as clean as possible and as free as possible from any semi-permanent/temporary bonding adhesive.

Considerations Affecting Peel Off—Liquid Deposition Coatings

Consideration must also be given to the use of such peelable mask manufacture processing with liquid-based coatings. In this case it is to be expected that the liquid source, such as a semiconducting polymer (Polythiophene) or inorganic nanoparticle semiconductor (ZnO) ink, would coat the etched wall of the pattern feature. In this case consideration must be given to when to peel-off the masking film since if too early then smudging and smearing of the deposit will occur. Conversely, peeling off the mask when the ink has dried would lead to problems of mask removal or device degradation or failure. It is, therefore, advantageous to use a manufacturing method that makes use of a liquid (ink) reservoir that has integrated into it a fluid flow restriction device that controls the rate of liquid flow into a device defining micro channel. It is the termination geometry of this device defining structure that affects the manner in which the masking material can be peeled away from a substrate surface. This is because the initial liquid flow provides a specific thickness of liquid-solid (ink constituents) as no loss of carrier solvent (assuming not 100% solid ink) has occurred such that this ink thickness reduces as the solvent is evaporated off and the liquid contact line retracts off a suitably non-wetting surface to terminate when fully dry in a thin coating edge that is readily broken as the masking film is removed. This provides the necessary flow restriction from the reservoir into the microfluidic channel that defines the device active region which in the case of the transparent thin film transistor is the channel length.

It is possible to consider defining such ink reservoir and device structures using micro and sub-micron UV embossing techniques to define structures of specific surface energy to modify the flow properties of the ink channels leading to, and contained in, the device under manufacture. Such embossing is of considerable interest in components and devices where the microfluidic channels and ink reservoirs are a permanent feature of the design—that is where the patterning method is not a peel-off system. It is also anticipated that such microembossed reservoirs and related microfluidic channels could be processed off-line, for example on a polymer sheet that could then be used as a peelable masking film. This enables a separate process where the resulting microembossed plastic sheet is laminated to the substrate in approximate registration with surface features, such as transparent conductor contacts, and a laser etching system is then used to define in-situ alignment of the piece parts used to make the devices to ensure the correct flow of the selected inks/fluids. Such a microembossed plastic sheet (or microembossed peelable masking film) may have features that project through the whole thickness of the masking film so as to provide a direct transport path for a liquid to flow easily through the mask into a reservoir or microfluidic channel (i.e., to permit filling of a reservoir).

In one embodiment it is possible to use this peelable mask manufacturing method to produce high resolution tracks of transparent as well as opaque materials by making the surface of the masking film substantially non-wetting. Such a surface causes any liquid coating to de-wet thereon as the liquid is drawn into micro channels formed by the laser etching process in the masking material and in the substrate material directly beneath the masking layer etch window. As the walls of the etched channels are substantially more wetting than the upper (outer) surface, the liquid is pulled under surface tension into the micro channels. The liquid fills the etched substrate channels and partially or completely fills the masking channels. After a specific time period has elapsed the masking film is removed, to leave a set of high resolution tracks. Thus, such high resolution tracks may be produced by a process combining peelable masking and ink jet printing or spray processing at low cost.

FIG. 5a shows schematically a perspective view of a transistor formed by the process shown in FIG. 4, which has a vertically aligned semiconductor-to-gate contact stack 50. By contrast, FIG. 5b shows schematically a perspective view of a transistor where the second peelable mask was not aligned to the first peelable mask, and a gate electrode 52 overlaps drain electrode 54 and source electrode 56.

Contact overlap is not desired as it causes leakage current and parasitic capacitance effects.

If the gate and drain or source contacts overlap this must imply either that they are in direct contact which means that they form an electrical short circuit or that they are overlaid with one or more materials sandwiched between the electrodes. Dependent upon the nature and properties of the sandwich filling including film thickness, microstructure, chemistry, and number of individual layers, the resulting electrical path between the gate and drain or source contacts may be more or less conducting (dependent using other factory upon the magnitude of the voltage difference between the electrodes) and of greater or lesser capacitance dependent upon the dielectric nature of the material or materials that are interposed between the gate and drain or source contacts. This latter effect is also dependent upon film thickness and film thickness ratio in a multilayer stack. The leakage and parasitic capacitance directly affect the thin film transistor performance and degrades the operational characteristic of a switching circuit that makes use of such a transistor.

As peelable mask manufacturing means that a plurality of layers of material can be laid down in a trench, providing as to-alignment, it enables structures that depend on accurate alignment to be developed, and manufactured cost-effectively.

FIG. 6 shows schematically a further embodiment of a process using a peelable mask. Drain electrode 58 and source electrode 60 are produced by an off-set lithographic printing process. Alternatively one or both may be produced by laser etching or by off-set, stamped or ink jet printing processes. For applications where cost is the overriding factor, the thin film transistor performance, including the need to eliminate/minimise parasitic capacitance and leakage current, does not need to be ideal or optimised providing that it adequately serves the purpose for which it is intended. For such applications tolerances in the manufacturing process, for example a small offset from ideal alignment for the gate/insulate/semiconductor stack in the dissected drain-source contact, are not problematic as there is a concomitant reduction in manufacturing cost

FIG. 7 shows schematically a structure formed from a similar process as that shown by FIG. 6, having slightly different scaling. In the embodiment shown in FIG. 7, a top surface of a semiconductor layer 62 lies below the top surfaces of drain electrode 64 and source electrode 66. The drain and source electrodes are approximately 50 nm thick and the semiconductor layer is approximately 40 nm thick. A gate insulator layer 68 is approximately 50 nm thick and a gate electrode layer 70 is approximately 50 nm thick.

FIGS. 8a and 8b show two further different embodiments of transistors, illustrating flexibility of positioning. When using laser etching to bisect a single conductive layer into a drain electrode 74 and a source electrode 76, the accuracy of a laser etching system determines the accuracy to which a position of a gate channel can be determined. The materials used in the device, and its structure, (i.e. its top gate thin film transistor configuration) mean that there is a large tolerance on where the gate channel may be laid down, and so less accurate and more inexpensive etching systems may be used. Compared with transistors constructed anywhere on the drain-source contact pad after dissection these inexpensive systems have equivalent high performance. Either structure shown in FIG. 8 could produce a working transistor. A gain of a factor of ten in tolerance means a factor of ten or so in terms of machine cost.

One of the problems with such direct laser etching of electrode layers in the past has been the tendency of the film to degrade or curl up at its edges in response to the heat generated in the etching process. This is particularly problematic if the film curls to the extent that it bends back on itself. The curling depends on the following process parameters including: material of the film from transparent conductive oxide or transparent conductive polymer or equivalents which are more susceptible to materials such as carbon nanotubes and sheets of unfolded carbon nanotubes which are less susceptible; laser wavelength and energy density; substrate material on which the film has been deposited; and quality of the optics used to generate the etching laser beam.

Such degradation manifests itself, in the most severe cases, as an up curled feature that forms a reverse “C” shape. It is understood that the cause of this degradation is thermal in nature and occurs even for the first pulse in a multiple pulse single site etch process.

Embodiments provide a number of ways to reduce the extent of the curling, so as to enable the use of a suitable material, preferably a transparent conductor such as an inorganic oxide indium tin oxide, ITO film, with a direct laser etch. The first of these is film capping, which involves covering an ITO film with another permanent or sacrificial film such as a peelable resist. Alternatively, an ITO film may be deposited on a thermal dissipating thin film to sink heat away from the ITO etch edge so as to dissipate the heat from the laser pulse in a time period of femto (10⁻¹⁵), pico (10⁻¹²), to nano seconds (10⁻⁹) so as to substantially reduce the thermal load at the edges of the laser beam etch zone prior to, and during, the etching process. Alternatively, a suitable structure of ITO film is chosen depending on the properties of a substrate. For example, amorphous ITO film is more suitable for a glass substrate and crystalline ITO for a plastic substrate. Materials may be paired and/or processing parameters altered to have a series of grain boundaries whose interfaces are so weak as to cause the film to tear or break along such grain boundaries when the transparent conductor is laser etched. In this regard a nano/micro/polycrystalline coating can be deposited, by varying suitable processing conditions, on both glass and plastic substrates. Alternatively, the film can be formed as a series of vertically stacked ultra thin films, known as a superlattice or multilayer stacked contact. Alternatively ion-beam assisted ITO deposition may be used. This involves high energy ion bombardment to enhance surface adhesion through an atomic stitching process whereby the ITO-substrate contact interface is made diffuse through the irradiation process (induced “radiation-enhanced diffusion”) thus leading to increased adhesion of film to substrate media.

Severe “curling”, features that bend upwards and partially back on themselves, and those that have a bend and/or lift dimension greater than about 150 nm are potentially troublesome. If such curl does occur, the vertical stack make-up and dimensions can be re-defined so that the curl height is covered by a thick enough insulating layer such that leakage between the drain and source to gate contacts is minimised and preferably suppressed. However, in doing this it is inevitable that the peelability of the masking film will be severely impaired due to the fact that the whole area deposition will coat the up turned edge of the masking film and base contact.

In general there are many potential effects of laser interaction with masking film bonded to plastic, treated paper, or glass substrates that include: polymer sheet bond scission; thermal reflow; trapped air/gaseous bubble rupture and mask lift-up; thermal edge melting and substrate surface bonding of exposed etched mask edge; vertical walled etched features such as ribbing; non-vertical walled etched features such inverted or re-entrant trenches and wells; and sub-surface aligned mask edge etching and production of “perforation-like” peel-off edge for masking

There are many permeations of processing parameters that can be used to overcome such effects, as set out below.

| | |
|---|---|
| 1. Mask thickness | 0.5 to 25 μm |
| 2. Mask etch profile | Vertical, inverse, re-entrant |
| 3. Mask material | PET, PP, PI, other |
| 4. Substrate type | Glass, plastic, treated paper, metal foil, other |

Three primary methods are:

Firstly adhesive bond line selective area removal. A peelable reflective surface is used on the base of the substrate to control reflection angle and hence etch length. A schematic diagram of this process is shown in FIG. 39.

FIG. 38 shows schematically a substrate 620 having a mask 622 adhered thereto via adhesive layer 624. A further, UV reflective layer 626 is laminated to the underside of the substrate 620. The UV reflecting layer is preferably a reusable peelable film. A laser beam 628 is used to etch the mask 622. The primary etch is in the direction of the laser beam as indicated by arrows towards the centre of the laser beam, but the secondary etch occurs as the laser is reflected from the ultraviolet reflecting surface 626. The UV reflecting surface is patterned to cause reflected energy to reflect at a set angle. Various geometries and material types can be used for such patterning. Reflected light is shown by arrows 630 in FIG. 38 and this reflective light having less energy than the forward beam etches only the adhesive layer 624.

A typical surface for the UV reflecting layer is shown in FIG. 39. As seen schematically in this figure a normal laser beam hits an edge of the triangular cross-section structure 626 and is reflected by an angle α.

The etch back length which is the distance that the adhesive layer is etched such that the mask 622 overhangs the adhesive layer 624 is equal to the width of the substrate+the width of the adhesive layer x tan α. If we assume the width of the substrate+width of the adhesive layer is around 100 μm and the desired etch back length is around 2 μm the necessary angle is around 2°.

The “reflection” constitutes a mix of reflection, refraction and scuttering. The type of material that can be used for the UV reflecting surface includes gold and various multiplayer stacks, the actual materials in the multi-layer stacks depending on the wavelength of light used which in turn depends upon the bond strength of the adhesive. The bonding in the adhesive may be such that a different laser beam is used for the adhesive etch back length than the primary beam.

Alternatively, a method of breaking the bond strength of the adhesive is simply to irradiate the entire structure with ultraviolet light to which the other structures (mask substrate etc) are transparent.

A second method of improving the peelability of the masking film is to laser etch an inverse taper in the peelable masking film. This can be done before or after the peelable masking film has been laid down.

As shown in FIGS. 40 and 41 and 42 it is also possible to use variable angle bombardment process which would produce a frustro-conical bi-layer having either an inverse taper (FIG. 41) or a standard taper (FIG. 42). In the standard taper the area above the drain and source electrode is air filled so there is negligible leakage current and/or parasitic capacitance.

The third method of increasing the peelability is via an embedded well, as shown in FIGS. 43 and 44. In such a well the film coating deposited into the well does not fill the well and so there is inevitably a finite gap between subsequent masking films base and the deposited films in the well.

A variable angle line of sight deposition coating process may be used. This ensures that there is minimal contact overlap at corners of the film.

FIGS. 43 and 44 shows schematically a substrate 650 covered by a capping film 652. A first laser beam (not shown) etches a well 654 into the substrate in which a barrier film 656 and an ITO film 658 are deposited. The upper surface of the ITO film 658 is well below the capping film/substrate interface at the upper level of the substrate 660. Therefore when the capping film is laid down it overhangs the well as indicated at 662. A further laser beam 664 may be used to etch drain and source electrode and variable angle line of sight deposition coating used to lay down a tri-layer stack. The coating process used is such that only a very small overlap 666 is produced. The top surface of the tri-layer stack is still below the mask/capping film interface 660 leaving a gap between the capping film 652 and any deposited layers. This means the capping film is relatively easy to peel off.

FIG. 9 shows schematically an example of a drain offset thin film transistor that can be manufactured using a peelable mask process. A substrate 78 is laser etched and source 80 and drain 82 contacts deposited. A first peelable mask (not shown) is placed over the contacts and etched together with the substrate. A semiconductor layer 84 and an insulator layer 86 are deposited and the peelable mask removed. A top surface of the insulator layer is aligned with a top surface of the substrate 78. A second peelable mask 85 is then laid down and etched, forming a trench offset from the drain electrode 82. Gate electrode 87 material is then deposited in the trench.

In this manner a drain offset thin film transistor, preferably a transparent thin film transistor, may be formed. The second peelable mask can be precisely aligned with the first peelable mask by fiduciary marks as described further below.

This is a dual pattern process combining embedded and integrated processing. It is possible to use independent ink feed reservoirs for the drain source and gate contacts. This example also demonstrates the fact that the disclosed process may comprise a combination of liquid and dry processing.

FIG. 10 shows schematically an example of a source-gated thin film transistor manufactured using a dual peelable mask process. A triple pattern process is used with dual back-to-back peel-off masking. First a substrate 88 is laser etched and a source contact 90 and a semiconductor layer 92 deposited. A dual masking layer comprising first peelable mask 94 and second peelable mask 96 is then laid onto the substrate. This mask may be pre-patterned on its reverse side (adjacent to the substrate) or may be etched in-situ. An ink reservoir feeder channel is hidden in a portion 98 of the second peelable mask. This feeder channel is accessed to deposit a drain contact 100. An insulator layer 102 and a gate contact layer 104 are then laid down using standard deposition techniques. The technique thus combines ink jet printing deposition and vacuum deposition. The second vacuum deposition does cover the drain contact other than in the region that defines the entrance to the drain contact microfluidic channel feed reservoir, which will be removed upon completion of the device structure.

A reverse laser etched alignment mark not shown may be provided on the masks to ensure that higher resolution alignment can be achieved optically by through alignment on optically opaque substrates or for applications that require tighter processing tolerance.

A transistor such as that shown in FIG. 10 has many advantages, including a lower operating voltage, lower power dissipation, larger gains and a higher operating speed.

FIG. 11 shows schematically an example of an auto-aligned bottom gate thin film transistor, manufactured using a peelable mask process. This device can conveniently be formed using peelable mask technique. A peelable mask 108 is laminated to a substrate 110. A parallel-sided trench 112 is laser etched into the mask, as outlined above. A gate contact layer 114, an insulating layer 116 and a semiconductor layer 118 are then deposited, in that order, so that the gate contact layer is adjacent to the substrate 110.

The peelable mask is then dry laser etched for a second time. Optically split (single beam) or dual laser beams are used that constructively interfere at a depth below the peelable masking film outer surface, to generate a frustro-conically sided trench 120 having a spur 122 of peelable mask material at a mid-point of the trench. A further small amount of semiconductor material is deposited until walls 124 of the spur are lined and two separate trenches have been formed. ITO film is then deposited in these two trenches to form a drain contact 126 that is separated from a source contact 128.

The mask is then peeled off. The spur may be peeled off with the rest of the mask, as it is continuous with other portions of the mask.

Low cost electronics, whether based on amorphous silicon, organic (plastic), hybrid organic-inorganic, or alternate thin film transistor technology require high performance to enable the widest range of applications. Conventional photolithographic patterning is too expensive, whilst current direct write processing, as exemplified by digital drop-on-demand ink jet printing has poor feature resolution and droplet positioning coupled with limitations in available materials. This is a significant limitation to the realisation of optimised Cost-Performance microelectronic products, particularly high performance transistor switching circuits processed on flexible substrates that are required to support high drive currents and voltages for long operating periods.

Further Mask Removal Techniques

It is of course preferable that the removal processes used leave no residue, and this may be achieved using mechanical means at room temperature without recourse to a pre-defined release layer on the substrate surface.

The following may be used with other aspects of the present inventions for removing a patterned masking film-multiple layer coating stack-unwanted etching and/or deposition debris structure that may pertain to fabrication of a device, circuit, and/or structure over a large surface area (planar or complex [curved; corrugated; etc]). The method comprises:
Laminating a sealing film on to the uppermost coating, and preferably into the spaces formed by the patterned masking film (roller pressure defines controlled depth of controlled thickness of adhesive to achieve 3-dimensional bonding) that has previously been attached (preferably using a low tack adhesive) to the substrate surface to be pattern coated, using a permanent strong adhesive;
Mechanically peeling off the sealing film, patterned masking film, multiple layer vertical coating stack and adjacent unwanted etching and deposition debris as a whole structure—termed the Patterning Sandwich (or “Peal-n-Seal”);
Peeling off the Patterning Sandwich in a single roll-up whole area removal process at a controlled pull-off angle and force commensurate with the application specific materials and the speed of removal required; and optionally
Sealing the Patterning Sandwich in a disposal cylinder, tube, carton, or bag (plastic, metal, glass, card/paper) for ease of handling and to minimise environmental exposure.

In applying the idea of a whole area polymer sheet film sealing-removal process to large area patterning of thin and thick film structures several important features have not hitherto been described in the prior art including:
1. The removal film acts to seal all the coatings deposited onto the patterned masking film so as to ensure that all residual materials and localised debris is sealed within the sandwich structure—this ensures that all unwanted material is removed in a single process over large area as opposed to relying upon sticking to a tacky adhesive surface whose properties are generally not compatible with a wide range of materials—this is of particular importance in respect of waste handling and disposal which are becoming increasingly environmentally important.
2. The sealing film adhesive thickness allows for 3-dimensional wrap around the patterned features, without contacting the required patterned film structures, so as to mitigate against the weak bond plane in the multilayer device fabrication vertical stack which is weaker than the sacrificial surface bond energy structure thereby causing the tape removal process to prematurely fracture at this plane and leave some of the debris/residual material behind—The added adhesive thickness acts to protect the device during sealing-removal film lamination as well as catering for wide variation in surface topography as experienced with an unused polymer sheet film or glass plate substrate versus substrate media that possess pre-defined device and circuit structures;
3. The, peel-off removal of the masking film-coating stack-sealing film system (Patterning Sandwich) occurs at the masking film-substrate surface interface and is a low temperature application/lamination process (essentially room temperature);

4. The peel-off removal of the masking film-coating stack-sealing film system occurs at the masking film-substrate surface interface and is defined by the strength of the adhesive coating used to attach the masking film to this surface—The low-tack adhesive coating strength being selectable in relation to the nature of the substrate surface to be attached to;
5. The peel-off removal of the masking film-coating stack-sealing film system occurs at the masking film-substrate surface interface and leaves no residue. Consequently no liquid, vapour, plasma, or laser release layer removal is required;
6. The sealing film provides the mechanical properties of the Patterning Sandwich thereby permitting the use of very thin sheet and ultra thin liquid or vapour films for very high resolution (sub-micron; nanometre scale) patterning;

7. The sealing film provides the mechanical properties of the Patterning Sandwich thereby permitting large area patterning of thin and thick film structures; and
8. The sealing film can be applied just after the final device/circuit/structural thin film deposition (in-line sealing) or after the removal from the deposition environment (off-line sealing).

FIG. 92 illustrates schematically the “Seal-n-Peel” removal system. In this illustration the “Seal-n-Peel” removal film (2000) is a polymer sheet film that is thicker than the mask and with higher tear resistance and stiffness. It has a thin high tack permanent adhesive coating (2010). This has been applied to the processed mask (2020), sealing in thin film coating residue (2030) on top of the mask. Clean removal (2040), e.g. peel-off, of the patterning sandwich (2000+2010+2020+2030) from the substrate (2050), which has been previously processed with a patterned functional thin film coating (2060), leaves the required patterned functional thin film coating (2070) from this sequence.

The “Seal-n-Peel” removal method provides mechanical stability to the processed mask to assist mask removal and allows the mask material to be removed regardless of whether the mask is in sheet film or thin/thick coating form, and provides a means of removing patterned masks that may or may not be continuously connected. Further, the “Seal-n-Peel” removal method provides a means of trapping in residual deposition coatings for reclamation purposes and to eliminate coating debris during mask removal.

It also provides a means of trapping in process environment induced debris to eliminate this as a source of contamination for subsequent processing of the patterned substrate.

In conventional prior art processes, there are a number of critical limitations:
1. A low surface energy release layer must first be grown or deposited onto the substrate of interest—this is a costly step especially when dealing with substrate used in macroelectronic applications that can measure in excess of 2 metres wide and even larger length; and
2. Secondly the removal of this release layer after patterning and mask/residue lift-off is also an added process cost and also introduces waste handling and disposability issues that are particularly difficult for acids such as Hydrogen Fluoride (HF).

In a method of removing a patterned masking film-multiple layer coating stack-unwanted etching and deposition debris structure according to the present method a patterned masking film and thin film coating is provided (see FIGS. 65 to 72). FIG. 65 shows an untreated substrate (1102) that may be a rigid (i.e., glass plate) or flexible (i.e., polyethylene terephalate sheet film in roll or other form) in form. On to this is attached (i.e., laminated; coated; etc.) a masking film (1104) (FIG. 66). The masking film (1104) may be attached to the substrate surface using electrostatic bonding or an adhesive coating (generally termed the masking film system to cater for all variant). In either method of attachment the masking film (1104) has photoabsorbing properties that are either broad spectrum in nature, as would be the case for the use of high purity carbon black nanoparticles, or wavelength specific, as would be the case for the use of water soluble infrared dye when the laser ablation is being achieved for example using a 1,064 nm DPSS Nd-YAG laser of an aqueous photoabsorbing adhesive.

A projection image or focused laser beam (pulsed or continuous) (1106) (FIG. 67) that is substantially matched to the photoabsorbing properties of the masking film system ablates a feature into and through the thickness of the masking film—termed the pattern—such that in one preferred embodiment the ablation automatically stops at the substrate surface leaving a clean debris free surface as shown in FIG. 68.

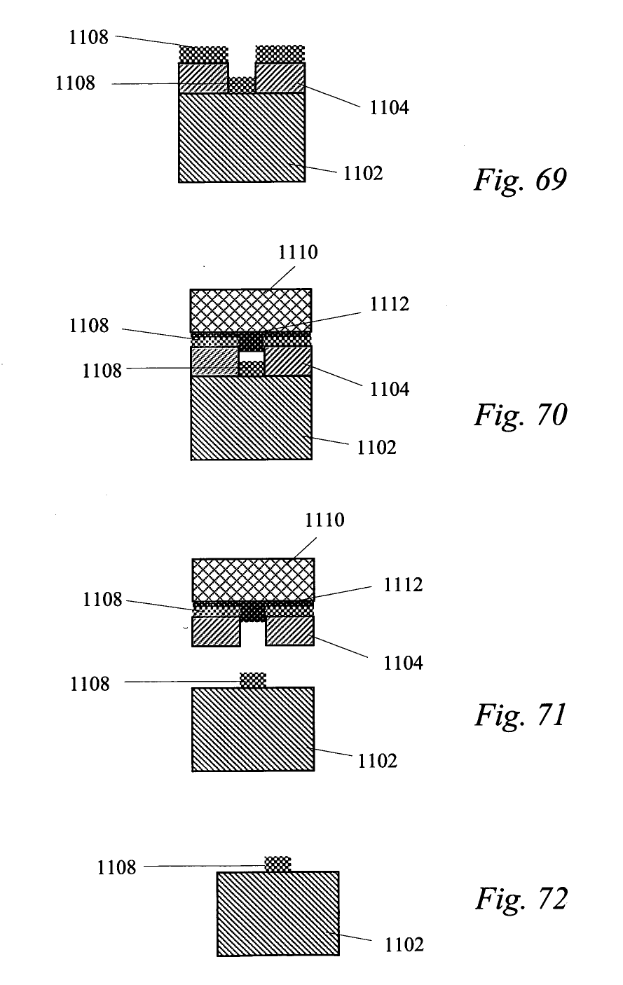

A thin film coating (1108) is selectively or whole area deposited over the masking film (FIG. 69) that includes providing a coating (1108) onto the substrate surface exposed by the laser ablation etching of the deposition pattern window into the masking film.

A sealing-removal system (Seal-n-Peel) comprising a PET or similar plastic base film (1110) and a high strength permanent adhesive (1112) is laminated over the coated substrate surface (FIG. 70). The laminated sealing-removal film provides mechanical integrity to the coated masking film whilst ensuring that all of the coating is trapped in the sandwich formed between the masking film (or coating) and the sealing-removal film. This aspect of the process as described herein is important because in one modification of the embodiment it is possible to simplify the masking film from a binary structure or binary (or multilayered) structure of a base film and adhesive to a single layer structure that is a solid film pressure-sensitive adhesive (PSA). This is because the properties of the compliant solid film adhesive are not as stringent when the sealing-removal film is employed to remove the “Patterning Sandwich”. This important feature allows a broad scope of masking film type and methods of application because it does not of itself have to have the mechanical properties to be applied (laminated) or removed (whole area peel-off) as a sheet of film because the former can be a continuous film forming coating whilst the latter is achieved through the lamination (or alternate method of putting down) of the sealing-removal structure.

Also of importance is the fact that the density of the LPM pattern, using the sealing-removal method described here, is not dependent upon the tear strength of the masking film because of the mechanical strength imparted to it by the sealing-removal film. The sealing-removal adhesive properties are such that dependent upon the lamination temperature and pressure the contact to the coated masking film can be 2-dimensional (contacting the upper coated masking film surface only) or 3-dimensional (contacting the upper coated masking film surface and the coated sidewalls of the ablated masking film) to a controlled adhesive penetration depth. The adhesive penetration forms a 3-dimensional connected network of adhesive that means that the lifting force is not just in the direction normal to the coating surface but is also acting in a range of angles including parallel to the coating dependent upon the etched pattern geometry.

The adhesive network provides a solution that can tolerate the occurrence of a coating that has weak or non-uniform bond strength to the masking film or coating already present’ thereon. The 3-dimensional aspect of the sealing film process is based on the use of a controlled thickness compliant adhesive (coating or co-extrusion or other as described herein) that under controlled lamination pressure is forced into the gaps defined by the patterning method. The controlled adhesive thickness is preferably based on the thickness of the masking film system which in turn may be partially based on the resolution of the feature required to support the application. The free end of the sealing-removal masking film is attached to a take-up roll that is designed to be used in controlled disposal of the residue materials in that once the take-up roll process has finished the roll of residual materials can be easily transferred into a containment tube or bag ready for environmentally friendly controlled disposal.

The attached sealing-removal film is now wound onto the residue take-up roll at a controlled speed and pull-off angle such that the sealing-removal film+coating+masking film sandwich are cleanly removed as a continuous whole area process leaving no low tack adhesive residue on the substrate surface (FIG. 71). The process ensures that no debris is created by removing the coated mask in an unprotected manner—that is if the coated mask was removed without use of the sealing-removal film (or coating) then if the coating material was brittle and granular then small fragments of the coating could break away from the coating and ultimately contribute to unwanted debris on the patterned substrate surface. In one embodiment, the upper surface can be so treated or pre-coated as to ensure excellent bonding between the required deposit material and the masking film. It is preferable that the coating not have a weak cohesive energy, as when deposited as a multiple faceted columnar grained film, the film can break away from the grain closest to the treated mask surface and would remain bonded to this surface. This illustrates a benefit of the sealing-removal film. FIG. 72 shows the required deposited coating (1108), left on the substrate surface (1102) in the shape of the laser ablated pattern defined in the masking film, after the masking film removal.

As has been described elsewhere in this description, suitable methods for forming the masking film or adhesive film or sealing-removal film (and which preferably may be used in the present embodiment) include:
Air knife coating
Contactless thin film web coating
Curtain coating
Digital inkjet printing
Electrostatic particle thermal reflow coating
Electrostatic spray coating
Gap Coating
Gravure coating
Hot Melt coating
Immersion (dip) coating
Laser induced forward transfer printing (including Direct Write—MAPLE process)
Magnetron sputter deposition (atmospheric and under vacuum)
Metering rod (Meyer bar) coating
Polymer laser ablation (atmospheric and under vacuum)
Polymer sheet casting (stenter and bubble processes)
Polymer vapour coating (atmospheric and under vacuum; liquid or solid monomer)
Pressure nebuliser nozzle spray coating
Reverse Roll coating
Rotary screen
Slot Die (Slot, Extrusion) coating
Ultrasonic spray coating

Laser ablation mask patterning debris may be removed by the use of multiple layers of materials, including a release liner coated with a transferable mask (mask coating), the non-mask material (including the release liner or liners if the mask is sandwiched between two such materials) is transparent to the wavelength of laser to be used to ablation pattern the mask. For example in the case of the release liner coated with a transferable mask coating the release liner is transparent to the laser wavelength so that pattern can be generated in the mask by directing the laser light onto the mask surface directly or by passing it through the transparent release liner. In one important embodiment the release liner is left in place over the transferable mask coating that has been attached to a substrate surface. Before the release liner is removed the laser is imaged onto the mask coating through this liner and the resulting ablation plume/evaporated/explosive vapour is collected on the released liner and is subsequently cleanly removed when the release liner is removed thereby providing for a very clean laser mask coating patterning process and negating the need for a subsequent cleaning step. The resulting laser ablation debris is efficiently collected and securely housed in the rolled-up release liner film thereby providing an excellent method of clean disposal.

FIG. 91 shows a schematic of a release liner system. The layers include a release liner 1000, a photothermal absorbing porous coating (1002) with a nano scale siliconised low energy surface (1003) and the mask coating (1004) which is attached to the substrate 1006. The release liner (1000) and absorbing porous coating (1002) are transparent to the laser beam (1008) allowing ablation of the mask coating. The locally laser ablated section of mask coating is absorbed (1010) into the treated surface of, and removed with the peel-off of the release liner film.

Hybrid Manufacturing

The peelable manufacturing approach provides for such high performance devices based on a highly flexible production strategy that permits a wide selection of dry and wet processes to be “mixed-and-matched” in the manufacture of a specific device type and performance-cost specification—“Cost and Performance Selective Manufacturing (CPSM)” using simple position-tolerant feature patterning. The peelable mask manufacturing is at the heart of the Selectable Interconnect Array Integrated Circuit (SIA^{IC}) production, based on this CPSM strategy, and as such has the capability of providing for high resolution patterns using a high tolerance pattern alignment process. This is best illustrated by the production of a transparent thin film transistor (TTFT) or more specifically a transparent thin film field-effect transistor.

Transparent Thin Film Transistor (TTFT) Production

A particularly high performance TTFT configuration may be produced by such techniques. A staggered structure having a gate contact being on top of the device is used. The structure is the result of a vertically aligned upward build of a 7 layer (4 materials) deposition sequence starting on an exposed laser etched feature surface in the substrate, as follows: Environmental barrier/Base Contact/Growth control/Semiconductor/Bandgap alignment/Gate insulator/Top gate contact SiO₂/ITO/SiO₂/ZnO/SiO₂/HfO₂/ITO.

FIG. 12 shows schematically a flow diagram of an embodiment of a method of manufacture which may be used as part of a peelable mask manufacturing process. More specifically, this method of manufacture is particularly suitable for the manufacture of thin film transistors such as those described hereinabove. FIGS. 13 and 14 illustrate various stages in manufacturing embodiment of this process. FIG. 13 gives an overview of manufacture of the array, whilst FIG. 14 shows the manufacture of an individual transistor.

In a first phase of the process, starting with an initial stage 130, a first peel-on masking film 147 is applied to a substrate 148. The substrate may be a rigid piece of glass or a section of transparent polymer sheet (made of, for example, PET), as required for the eventual application where the polymer sheet may in itself be rigid or flexible (conformable).

In a stage 132 a deposition window is formed in the first film and 147 the substrate 148 by laser etching. This substrate feature etch and deposition window provides a laser etched feature into the substrate material that isolates the TTFT from adjacent devices and provides for the environmental barrier and device growth stable platform film and base contact transparent conducting oxide bi-layer to be located below or substantially in-line with the substrate surface so as to afford greater mechanical adhesion particularly for substrates that are flexed or deformed during operation.

An inorganic glassy oxide barrier is then deposited in a further stage 134. A drain-source TCO contact made of an ITO film is then deposited in a further stage 136. A plurality of isolated islands 150 are deposited. In a further stage 138 the masking film is peeled off.

As an alternative to this first phase, if a simpler process is desirable, ITO TCO islands may be sputtered onto a substrate using a contact mask.

In between the phases, the substrate may be rolled into a mask and stored or transported, as described further below.

In a second phase of the process, as shown in FIG. 13c, a second peel-on masking film 152 is applied to the structure at a stage 140. The film 152 has a peel-off tab 154 which extends over the edge of the substrate 148. The tab may be pulled to peel-off the second film 152 making removal easier.

In a further stage 142, shown in FIGS. 13d and 14c, drain-source contact/gate channel laser etching occurs. A channel 156 is etched through the second peelable mask and through the deposited drain-source TCO contact. A drain electrode 158 and a source electrode 160 are thereby formed. The gate channel is auto-aligned with a masking trench for further deposited layers by this process.

As an alternative, offset lithographic printing can be used to define the drain-source contact land. If offset lithographic printing is used, then individual drain and source electrodes with a gate length as small as about 5 μm can be achieved. There is no need to laser etch a gate channel. If desired, offset printing may be used to deposit a base layer into which a gate channel is etched for those applications where vertically alignment is essential or where the resolution of the offset process (about 5 to 10 microns) does not meet the device application specification requirement (i.e., say a 3 micron gate length which is within the tolerance of a YAG laser system).

The second peelable masking film therefore provides a means of defining a laser etched trench in the base contact transparent conducting oxide film (ITO) so as to form two contacts from a single ITO film defined by the first peelable mask deposition/substrate etch window dimensions. The gap produced by the laser as it dissects the ITO base contact is the transistor gate channel and is an important dimension of the transistor. In order for the laser to be able to dissect the base ITO contact it must also etch a window into the masking film. This masking film window is aligned to the laser etched gate channel and provides a means of being able to deposit a vertical stack of films that are automatically aligned to the gate channel.

More specifically this patterning method provides a means of aligning the gate contact edges with the inside edges of the drain and source contacts so as to eliminate contact overlap thereby minimising parasitic capacitance and electronic leakage effects. This is a key element of the device processing approach since it provides a means of self-aligned patterning that is introduced at the time that the substrate media has been set-up ready for processing. This means that ambient temperature and processing configuration induced strain (i.e., reel uptake stress/strain in roll-to-roll manufacturing) can be catered for in the mask patterning of a flexible polymer sheet, such as PET, making the precision of the masking that much more uniform across the complete sheet area even for large area requirements.

A tri-layer stack 161 comprising a semiconductor layer 162, preferably of zinc oxide, an insulator layer 164, conveniently of hafnium oxide, or aluminium oxide or titanium oxide, and a gate contact layer 166 is then deposited in a further stage 144, using CFUBMSD. The masking film protects all other regions of the substrate. The tri-layer stack actually comprises four layers, having an ultra-thin bandgap alignment layer (not shown) positioned between the insulator layer and the gate contact layer. All deposited materials are transparent (even though the generic processing method is also applicable to translucent and opaque devices and microstructures).

The second masking film 152 and excess deposited materials are peeled off in a final stage 146.

The pattern of laser etching is chosen so that the process results in an array of isolated devices. Connections between the devices in the array may be made at a later stage, as appropriate to whatever application is desired.

Further details of this process will now be described.

The equation for a transparent thin film Transistor is:

I_{D}=(μ)(εᵣε₀/d)(W/L)(V_{G}−V_{D}/2)(V_{D})

where:

I_{D} is the output current, the larger the better;

μ is the semi conductor layer property;

ε represents gate dielectric layer properties;

W/L represents the patterning resolution;

and V_{G} and V_{D} are application device control voltages.

The semiconductor layer of the TTFT has a high mobility or μ. This leads to a high output current, from the equation above, and also a high device frequency (f_{MAX}=μV/L²). The semiconductor layer also has a low bulk conductivity σ. The bulk conductivity determines output current on/off switching ratio, (σ_{Semic}=neμ). Layer purity and the defect nature of the semiconductor layer are also important.

The TTFT also features high semicondudtor mobility, including intraparticle (nanorod) conduction across the gate channel. The nanorods, wires, tubes, or string cages may be CUED CVD grown or grown by tectronics plasma spray or generated in a liquid process or chemical solution process. The structure may be single crystal like or a coated nanowire or similar structure that is itself single crystal in its grown form.

The TTFT has a high gate dielectric with low operating voltages. The TTFT has low semiconductor-gate insulator interfacial trap density, with a low threshold voltage and low sub threshold slope.

Many of these advantages are as a result of the use of zinc oxide which has excellent properties but has not been widely used previously due to difficulty in etching it and growing and depositing high (device) quality material.

Benefits of the TTFT, dependent upon the specifics of the method of manufacture, include:
1. Self-aligned structure;
2. Simple build;
3. Fault tolerant processing;
4. High precision device from low precision processing;
5. Isolate high-K gate dielectric;
6. Embedded structure;
7. Low-K contact isolation;
8. Selectable drain-source contact-semiconductor interface metalisation;
9. Simple access to the drain-source-gate contacts for inter-device connectivity;
10. Minimum number of processing steps and patterning stages;
11. Shaped ink containment microfluidic feeder reservoirs;
12. Built-in layer thickness control reservoir flow structure;
13. Easy source contact off-set;
14. Selectable hybrid manufacturing to suit cost-performance criteria;
15. Processing methods (such as SPS design and manufacturing methods) provides a means of integrating P and N type semiconductor based TTFT's into a single circuit;
16. P-N junction formation (a peelable mask process for a single charge device is also compatible with the use of more than one material in a multilayer structure to achieve p-n and p-i-n structures hence equivalence to CMOS technology);
17. CMOS equivalent technology;
18. Energy efficient logic processing circuits.

The important features of the peelable mask manufactured TTFT design include:
1. Top gate, staggered, thin film transistor configuration (a peelable mask process as described in this application can also be used to produce bottom gate inverse staggered and co-planar thin film transistor structures)
2. Self-aligned vertical structure;
3. Simple build using wide variety of processes and a generic patterning platform
4. Low temperature processing;
5. Fault tolerant processing;
6. High precision device from low precision processing;
7. Bandgap aligned high-k gate insulator;
8. Substrate semi-embedded structure; and a
9. Minimum number of processing steps and peelable masks.

In the search for a low cost low temperature (<100° C.) processing method that can produce a high performance transparent thin film transistor (TTFT) several factors must be resolved including:
1. Vertically aligned gate contact edges to drain-source contact inner edges;
2. Control of transparent semiconductor and gate insulator wide bandgap alignment;
3. Low interfacial defect density;
4. Low bulk defect density;
5. Lowest number of masking steps possible;
6. Manufacturing method compatible with a wide range of deposition processes; and
7. Device design compatible with a wide variety of build materials (thin film layers).

The transparent thin film transistor design proposed herein provides a device that addresses all of the above factors and establishes a cost effective manufacturing method that produces a high performance TTFT. Preferred features are as follows.
1. Auto-aligned peelable mask deposition window with drain-source contact spacing (contact edge alignment);
2. Serially located very wide bandgap ultra thin insulator acting a bandgap alignment adjustment layer;
3. High quality ultra smooth, ultra thin oxide growth surface (Controlled growth surface—minimum damage);
4. High quality ultra smooth, ultra thin oxide growth surface (Controlled growth orientation and optimised lattice matching for minimising stress-strain effects); such layers are used on both sides of the semiconductor to ensure that back and front conduction channels and associated interfaces are of the highest quality possible whilst also providing a controlled growth surface for the high-k gate insulator;
5. Peelable self-aligned masking method means TTFT requires 2 masks;
6. Peelable masking method is compatible with a wide range of liquid, vapour, and solid particle processes;
7. Wide range of liquid, vapour, and solid particle processes provides a very wide range of materials that permits the construction of all-inorganic, all-organic, or hybridised inorganic-organic devices even mixing liquid, vapour, and solid particle processes in one device manufacturing sequence.

There are many manufacturing alternatives which may be used with peelable mask technology. Some of these are outlined below:

Laser Patterning, Multiple Ink Jet Printed Layers

In this process laser etching is used to define microfluid flow channels that may be used with the regions of the TTFT. Device fluids from DoD-IJP are conveyed into placement tolerant reservoirs. Ink reservoirs provide droplet volume tolerant processing. The TTFT may, thereby, be essentially completely ink jet printed.

Off-Set-Laser Patterning-Sputtering-Inkjet

In this process off-set printing is used to provide pre-patterned drain-source contacts to a resolution of the order of 5 μm. The laser patterning is also used for masked windowed delineation in situ. CFUBMSD is then used to deposit a semiconductor-insulator by layer. DoD-IJP is used to deposit isolation, insulation and conductive links to the X-Y addressing bus lines, if manufacturing a display.

Ink Jet-Laser Patterning-Sputtering-Inkjet.

DoD-IJP used to perform a continuous land of transparent contact metalisation which provides drain-source contact. Laser etching of this drain-source contact pattern and of a mask window is used. CFUBMSD is used to deposit a bi-layer semiconductor-gate insulator. DoD-IJP is then used to provide isolation and conductor pattern via a direct write printing process.

Inkjet-Laser Patterning-Dry Transfer Deposition-Inkjet

DoD-IJP is used to print drain-source contact lands. Laser etching is then performed to provide drain-source contact patterns and mask windows. Dry transfer printing (i.e. laser direct write forward transfer ablation) is then used to provide a self-aligned semiconductor-gate insulator stack. DoD-IJP direct write printing is used to provide isolation and conductor patterning.

Inkjet-Laser Patterning-Xerographic Deposition-Inkjet

DoD-IJP is used for drain-source contact land printing. Laser etching of drain-source contact pattern and mask windows is then carried out. Xerographic print deposition (i.e. dry transfer printing) of a self-aligned semiconductor-gate insulator stack then takes place. Finally DoD-IJP isolation is used for direct write printing of isolation and conductor patterns.

FIG. 15a shows a TTFT structure with TCO interconnects deposited. TCO drain-source electrodes 168 are 100 nm thick, a semiconductor layer 170 and a gate insulator layer 172 are 30 to 50 nm thick, and a TCO gate electrode 174 is 100 nm thick. An optional barrier coating (shown in FIGS. 25 and 26, FIG. 25 shows schematically a cross-section through a transistor having an environmental barrier; and FIG. 26 shows schematically a cross-section through a transistor having a sub-surface deposited environmental barrier) is 100 nm thick, and TCO interconnections 176 are 100 nm thick, also. In the embodiment shown FIG. 15a the gate electrode has been laid down separately from the semiconductor-gate insulator auto aligned bi-layer. If a bi-layer structure is used, the gate TCO metal may be printed onto the partially complete transistors, conveniently at the same time as interconnections are formed between them.

FIG. 15b shows a similar structure having a semiconductor-gate insulator-gate electrode aligned tri-layer. The semiconductor comprises an inner film, the gate insulator a middle film and the gate electrode an outer film.

FIG. 15c shows schematically how a tri-layer 177 may be shaped as a frustro-cone in cross section. As the narrower end of this shape is between the drain and source electrodes (which are connected to the drain and source layers). This shape minimises electrode overlap leakage, and leaves the wider end of the tri-layer available for inter-connect.

The tapered geometry deposition provides a means of achieving minimal leakage current and parasitic capacitance due to control overlap whilst providing a wider end section for ease of contact with a direct write interconnect.

FIG. 16a shows schematically a view of FIG. 14c with indication of alignment tolerances. The length of the structure, l1, is in the region of 500 μm, the length of the wider portions of the source and drain, l2 being in the region of 50 μm. the width of the gate structure, w, is less than 10 μm. The gate electrode, which is nominally in the middle of this structure, could be misaligned by ±25 μm whilst still allowing transistor action. It is advantageous to ensure that the drain source probing is defined so that the gate electrode is on the side that exhibits the lowest leakage field.

FIG. 16b shows schematically a transistor comprising a drain electrode probing pad 179, a gate electrode probing pad 181 and a source electrode probing pad 183. In combination with FIG. 16c it shows how voltage and current inter-relate across the transistor. Such a transistor will have field effect mobility in the region of >0.5 cm²V−¹s−¹, a threshold voltage in the region of <3V, a pre-threshold swing of in the region of <1.5 volts per decade and a switching on/off ratio of in the region of 10⁵ to 10⁶. The chain dotted line A shown in FIG. 16c represents the maximum loci of the saturation drain current drive voltage, the solid line B represents the gate-source voltage.

FIG. 17 shows schematically a view of a peelable mask having alignment markings also called fiduciary marks. These markings can be used to align two masks being used in the same process with each other. The marks comprise two generally parallel rows of squares, each row being adjacent an opposite edge of the peelable mask. They enable two masks to be aligned to better than ±20 μm in two perpendicular directions (X and Y axes). Alternatively or additionally, the alignment marks can be high tolerance sprocket holes for use in a roll-to-roll process that employs a drum feed that uses sprocket gear to both align and transport the plastic sheet

Manipulation of a Section or Edge of a Peelable Mask

FIG. 18 shows schematically a cross-section through a peelable mask, the peelable mask 185 having a straight edge 187, and, in contrast FIG. 19 shows schematically a cross section through a peelable mask 189 during a fabrication process, the peelable mask having an undercut edge 191. Deposition processes may cause a coating layer 193 to build up on the straight edge 187.

Since most deposition processes are not truly line-of-sight—that is they have a finite “throwing power” that can quite literally coat blind surfaces—it is preferable to alleviate such effects by producing a peelable mask that has a section that is to all intents and purposes screened from the deposit thereby permitting easier peel-off masking film removal. It is envisaged that such a structure can be achieved with a semi-permanent adhesive bond coated masking film that has also laminated onto it a removal UV reflecting structured plastic film as previously described. The adhesive bond may be etched away to increase the peelability of the film as previously described.

The UV reflecting structure acts to reflect laser beam energy at a controlled reflection angle so as to cause the exposed adhesive (glue) bond to be etched from the opposite side to which the laser is etching a deposition window into the masking film. The reverse-side masking film (actually the temporary adhesive bond coating) etching is achieved by making use of the regular array of UV reflecting structures on the reverse surface of the plastic (or glass) carrier film surface to direct the angle at which the reflected UV energy is returned toward the rear side of the masking film based on the thickness of the carrier film so that a known etch distance from the etched wall edge is achieved. The etched adhesive material is ejected into the etched channel (or well or trench) feature (lateral ejection occurs, without causing the masking film to lift) and is removed using powerful localised suction methods. If any of the etched adhesive bond material is re-deposited on the etched feature base then a subsequent clean-up pulse or pulses can be applied to remove such debris.

Although directional (line-of-sight) deposition processes are preferred it is still possible that small angular deviations in the substrate orientation, particularly so of flexible substrate media, might provide a means for the depositing film to coat the sidewall and mask-substrate etched interface whilst also not properly coating the drain-source electrode edges as exposed when the base contact land of material was dissected by the laser to produce the drain and source contacts and the gate channel, due to the set-up geometry of the deposition process and the masked substrate.

For a high performance device it is anticipated that the laser etched gate channel and vertically aligned stack mask will have a length dimension (gate length) of 1 μm. If one assumes that the mask thickness is also 1 μm this creates a 1:1 masking ratio (etched feature width to height ratio). In this case a small change in deposition direction can cause the drain-source spacing to not be fully coated leading to degraded thin film transistor operation. However, in the case of most of the preferred deposition methods such as magnetron sputtering the source is not a single point but a finite area and as such the coating is due to a finite range of angles as seen by the masked substrate and dependent upon the geometry of the deposition process set-up. This implies that there will be some coating of the masking film etched wall even for a highly directional process. This will be true to some degree for shaped etched walls that have been engineered to provide a form of undercut (such as that shown in FIG. 19) (base of the mask etched window is larger than its top) due to the partial resputtering of material by the energetic bombarding ions, although the magnitude of the resultant secondary coating will be substantially lower than that observed on the surface to be coated or than with a straight-sided wall.

Fully re-entrant (concave) etched features are also possible. These preferably use special processing or a customised masking film that comprises at least two co-polymers or laminated films that etch at different rates in the etching laser beam, with the fastest etching material being closest to the substrate surface. If the masking film comprises a base layer and a bonding adhesive layer then it is possible to deliberately etch/chemically attack the adhesive at the etching exposed interface so as to cause the bond line to be etched back under the base film, thereby creating a suitable peel-off undercut masking feature. It is possible to consider the production of a masking film that has a thin oxide or polymer overcoat or hard coat that etches at a slower rate to the bulk polymer onto which it has been deposited. Once again this would provide a means of creating a concave undercut.

Alternatively, dual wavelength single laser or dual laser processing could be used (co-incident beams aligned to better than 1 μm positional accuracy) to create a differential etching environment leading to concave etched wall features. Alternatively, a process that uses two aligned laser beam processes (or overlaid holographic patterns) could be used where the beams are present to the front and rear of the masking-substrate composite structure so as to receive additional benefit from the rear surface laser exposure even though this surface is not etched. A first laser, Laser A, is introduced from the front surface and a second laser Laser B, is introduced from the rear surface. Laser B is of a lower intensity such that it does not in itself etch but when it constructively interferes with Laser A at some specific point then the combined energy density introduces a controlled increase in the localised etching rate in the interference zone only. This method is of particular interest in producing aligned device features that require connecting via holes that pass from the front to the rear surfaces of the substrate material. It is also possible to use multiple frequency laser systems to create shaped microfeatures and via holes through the substrate and peelable masking film as required

It is further possible to consider using the same etching process but at different etching pressures (with or without the introduction of supporting etch gases such as oxygen) to effect a concave undercut wall etched feature or specific shaping of the etched feature profile.

The shaping of the masking film etched feature wall is dependent upon a number of factors including: laser energy; laser wavelength; ambient environment chemistry; ambient pressure; masking film material type, chemistry, and laser wavelength absorption behaviour; masking film thickness; and laser beam shaping and focussing optics.

Laser Etching Effects

The reflective nature of the material directly below the coating to be etched, in respect of the wavelength of the laser light that is to be used to etch the masking film and underlying coating has an effect on the removal efficiency and resulting etch exposed surface quality. This is important for the transparent thin film transistor because for this microelectronic device an important surface is that which is left exposed after the ITO land has been etched (dissected) to form the drain and source electrodes. This exposed surface is where the growth control film must be deposited prior to the deposition of the ZnO semiconductor film. It is this semiconductor-growth control surface interface that is important as it needs to be smooth, clean, and defect-free if high quality devices are to be produced.

Cleaner and more abrupt etched film interfaces and etch exposed surfaces result from achieving good reflectivity at the etched film interface with the surface that is not etched (in effect the etch stop surface). With respect to (transparent) thin film transistor manufacture this means getting good reflectivity of the laser light (e.g. YAG 1,064 nm) at the adhesion (barrier) film—ITO (transparent) conducting oxide film interface. This coating specific wavelength reflective interface located underneath the transparent conducting oxide film (film to be etched) is desired in order to achieve a clean abrupt interface and can be achieved by:
Depositing an adhesion promoter/barrier/semiconductor growth control multilayer/quantum layer stack where the optical properties of the stack affect the laser wavelength/energy reflectivity behaviour; and/or
Controlling specific chemical composition of adhesion/barrier layer so as to provide a means of enhancing the optical reflective nature of this film at the adhesion/barrier film—ITO transparent conducting oxide film interface, via introducing optical reflectivity and refractive index changes.

Laser Beam Profile Effects

The specific nature of the YAG laser beam profile introduces a variation in the shape of the etched feature. FIGS. 45a to d show some examples of different profiles that can be achieved with different lasers and laser profiles.

FIG. 45a shows a tri-layer comprising a mask 700, a TCO layer 702 and a barrier layer 704. The trench etched into the mask and TCO layer by the laser has straight vertical walls being a “top hat” laser beam. Such a laser beam has high quality optics and homogenised laser beam cross-section. This type of trench provides excellent alignment but minimal contact area for semi-conductor-to-contacts. The semi-conductor layer will be laid down in the trench.

FIG. 45b shows a “V” shape device which provides high current and speed performance. The device again comprises a tri-layer of the mask 700 a TCO layer 702 and a barrier layer 704 as shown by dotted lines 706. This “V” shape gives better coating coverage but only a slightly larger compact area. The average gate length is smaller than the mask opening. The width height of the V can be varied.

FIG. 45c shows a “U” shape in a tri-layer structure comprising a mask 700 a TCO layer 702 and a barrier layer 704. Such a shape has excellent alignment characteristics. It provides a base region to control growth of the semi-conductor layer and force the back conduction channel further away from the active device zone. Also the channel length may be longer to provide “off-state” conduction. This shape may have a thicker barrier layer to cater for etched depth into it. This gives control of actual length, extension of the back conduction channel even with the growth layer in place.

FIG. 45d shows a variable profile shape as does FIG. 45e. The curved shape is etched into a mask layer 700, a TCO layer 702 and a barrier layer 704. Different profiles are shown in dotted lines. This off-set inverted “S” shape gives a profile which is easier to achieve using a typical laser. It is also easier to coat and gives a slightly larger contact area. The profile may be changed to affect a lower average gate length. For example using one of the dotted lines shown at 706 and 708 the profile could include breaking into the barrier coating below the TCO contact land. Further achievable profiles are shown in FIG. 45e. Profile 710 and 712 demonstrate that greater or lesser mask etch back can be achieved with this profile as can a variable TCO contact layer for any deposited semi-conductor layer. The barrier layer may have a variable thickness in order to provide the facility to etch into it. This may be used to do without a bandgap engineering layer because the thickness of the barrier layer can be used to control quality of the semi-conductor layer.

So, the etched well that is the gap (or transistor conduction channel gate length) between the dissected ITO transparent conductor land (leading to the formation of the transistor drain and source electrodes) that under certain conditions can be used to advantage namely:
Electrode exposed surface shaping to achieve larger semiconductor-to-electrode contact area in a confined space
“V” shaped device that promotes higher current and speed performance
“U” shaped device that provides a larger conduction path for the back conduction channel (reduce leakage current and off-state conduction behaviour) whilst achieving a short conduction path for the front conduction channel.

FIG. 20 shows schematically a test pad for optical transmission analysis, which is particularly important for the manufacture of transparent transistors. Large scale deposits of different materials under test are made. The optical properties of different materials, different combinations of materials, and different thicknesses can be tested thereby. Materials shown in FIG. 20 include a CV-TFT (CV here means Optically Clear View or See-Through) test transistor 195, a single layer of zinc oxide semiconductor 197, a single layer of silicon or hafnium or titanium dioxide gate insulator 199, a single layer of ITO drain-source electrode material 201, a single layer of ITO gate electrode material 203l, and a multi-layer test pad 205. The multi-layer test pad provides optical transmission analysis for a layering structure equivalent to a complete device. The materials are laid down on a clear plastic or glass substrate 207.

Selectable Interconnect Array Integrated Circuit

In order to achieve low cost, high performance integrated circuits that exhibit stable operation at high speed, high voltage, and high current it is necessary to produce a core thin film transistor device using high quality materials and processing methods. The materials and processing methodology affect the overall performance and to some extent the cost of the finished integrated circuit.

An approach which reduces manufacturing cost is to produce a non-assigned and non-connected standalone set of transistors and support components such as diodes, resistors, and capacitors in a repeat array such that application-specific integrated circuits (ASIC's) can be produced by selecting the interconnection pattern (2-D in-plane and/or 3-D multiplane build) and method of producing the interconnect such as with digital ink jet printing or laser dry transfer printing. This method of integrated circuit construction is hereinafter termed “Selectable Interconnect Array” (SIA) Technology with the device being termed a “Selectable Interconnect Array Integrated Circuit” (SIA^{IC}).

The objectives behind producing standalone devices using this peelable mask manufacturing approach include:
1. Facilitating peel-off with a continuously connected masking film. Since the devices are not interconnected there is no section of the masking film that is left as non-connected islands of material or is potentially weakened to the point that islands of masking film might be left behind as the masking film is peeled-off in a continuous sheet format;
2. Producing an array of equivalent devices and/or circuit building components, such as transistors, diodes, resistors, capacitors, etc., this means that a high volume throughput of a standard product can be produced invoking economy of scale considerations. Individual circuit designs are catered for by introducing a repeat array of selectable device and component designs that permit device redundancy and flexible 2-D and 3-D circuit manufacture because the individual devices and components can be interconnected using low cost direct write methods such as digital ink jet and laser dry transfer printing to achieve 2-D and 3-D device interconnectivity. The choice of direct write or alternate interconnect method depends upon the resolution of the circuit required to support the application but would include:
   Digital ink jet >15 microns
   Forward transfer laser >5 microns
   Offset lithographic printing >5 microns
3. Have a laser etching process that has a large placement error tolerance brought about because of the top gate thin film transistor design. This means that processing errors can be much reduced leading to higher tolerance devices in large area array formats.

FIG. 21 shows schematically an embodiment of an array 200 of semiconductor devices 202. Each semiconductor device is a transistor comprising a gate, a source, and a drain. Each device 202 is electrically and physically isolated, there being no interconnections formed on a substrate 204 on which the devices are disposed. The array 200 is a regular array formed of equally spaced rows and columns. It is programmable, in that if the devices are interconnected in different ways, the two initially identical arrays will perform very different functions, and be suitable for different applications.

FIG. 22 shows schematically an embodiment of an integrated circuit comprising the array of FIG. 21. Interconnections 206 are directly written, at multiple levels within the structure, between different devices in the array. Insulation pads (that can also be written in a selectable manner) 208 are used to connect to a tri-layer stack 210 (as hereinabove described) to lessen the risk of a stack short-circuit.

The specifics of the device-to-device inter connections, and, of the devices themselves, define the circuit function. Examples of circuits which may be manufactured in this manner include radio-frequency identification devices (RFID), or digital (low or high frequency and analogue circuits also possible) logic circuits. Conveniently the semiconductor devices in the array are staggered top gate transparent thin film transistors (but could also be inverse staggered or co-planar configurations).

Such transistors are of use in one preferred application, a display. FIG. 23 shows schematically views of a further example of an integrated circuit comprising the array of FIG. 16, and making up a display; FIG. 23a shows schematically an overview of the array; and FIG. 23b shows schematically a single pixel.

Each single pixel 210 comprises a transparent thin film transistor 211 and associated drive circuitry. A high capacity storage capacitor 212 and a large contact pad for display media 214 are connected by device interconnects 216. The device interconnections extend to other layers in the structure through vias 218. Such an array can form an active matrix display in which the array comprises a transparent backplane or Frontplane (and includes the capability to have dual back- and front-planes that can be interconnected so as to provide for the construction of more complex circuitry.

Possible structures for such transistors are shown in FIGS. 24 to 28, FIG. 24 shows schematically a cross-section through a transistor having an environmental barrier 213, and FIG. 25 shows schematically a cross-section through a transistor having a sub-surface deposited environmental barrier 215. Either would be suitable for use in a display. The barriers 213, 215 are typically made of a glassy oxide. They are laid down adjacent to a substrate.

The transistor shown in FIG. 24 comprises an auto-aligned bi-layer stack 217 and an autoaligned tri-layer stack 219. The bi-layer stack comprises the environmental barrier layer and a drain-source electrode layer. The tri-layer stack is as described hereinabove.

The transistor shown in FIG. 25 comprises a sub-surface deposited environmental barrier 215, drain-source contacts 221 and a gate channel 223. There is no gate to drain-source contact overlap thereby minimising leakage current and parasitic capacitance effects. The environmental barrier 215 limits: thermal expansion mismatch and associated micro and nano cracking; and bending stress induced strain in the TTFT device. The barrier 215 also gives better adhesion control. Having embedded barrier and drain-source and semiconductor layers provides greater mechanical protection during flexing of a plastic sheet substrate.

A high density glassy oxide environmental barrier is also preferred because it acts as gate channel laser etch stop (when suitably designed to give the required laser light reflectivity behaviour) and as protection against ingress of moisture and oxygen. Such a layer provides a stable surface to deposit TTFT on to and can beneficially influence crystallography of device layers (this is due to surface energy control of the depositing adatom transport on the growth surface—the surface energy control is achieved by surface relief and smoothing effects, including nanoscale planarisation and surface defect repair or decoration, brought about by the laser interaction on the barrier growth during the transparent conductor land dissection. Such a barrier may have a number of different structures: it can be based on quantum or superlattice multilayer structure to enhance barrier performance; can be nanoparticle-dispersed polymer+inorganic coating multiple layer stack; and can be a thermally isolating or dissipating or spreading material.

FIG. 26 shows schematically a cross-section through an addressable transistor which could be used in a display, having a printed gate line 220 and a printed data bus line 218. The gate bus line 220 and data bus line 218 are disposed generally orthogonally on a flexible substrate 222. The transistor comprises a sub-surface deposited environmental barrier 224 and subsurface drain-source contacts 226, 228 and gate channel in which a tri-layer stack 230 has been deposited.

FIG. 27 shows schematically a cross-section through a transistor which comprises a single pixel element of a display, and has large cross-section TCO data lines 232 and gate lines 234. These lines are sub-surface deposited. They provide low resistance long length transparent conductors. An environmental barrier layer 236 provides isolation at the transistor. The boundary line of the single pixel is outlined in a chain dotted style.

FIG. 28 shows schematically a cross-section through an alternative transistor 238 which comprises a single pixel element of a display. In this structure a data bus 240 and gate bus 242 are separated from the transistor 238 by a substantially thickness of flexible substrate 244. This deep isolation minimises electrical cross-talk via bus lines. Connection between the bus lines and the drain or source or gate is provided by bus bar access vias 246. These are laser etched and printable conductive links. Both laser etch then direct write processing, such as ink jet printing, can be used, preferably together to in-fill the resulting via hole to provide a conductive column. Such links extend through the substrate 244 and any environmental barrier layer 248. A further isolation layer 249 provides isolation between the data bus and the gate bus.

FIG. 29 shows schematically views of a further structure which includes a pixel element 250 of a display, defined by address lines 252 and data line 254. The lines comprise offset lithographic printed bus bars. They are in the region of 5 μm to 10 μm wide. FIG. 29a shows schematically a top view; and FIG. 29b shows schematically an electrical diagram. An integrated liquid crystal capacitor 256 is incorporated into the layers structure of the device. This comprises a layer of insulator, a layer of ITO film, a layer of liquid crystal, and a further layer of ITO film. The capacitor may be formed at the same time the process of fabricating the transistor. A peelable mask manufacturing process is suitable for the fabrication of either or both.

FIG. 30 shows schematically views of a structure during the process of manufacturing a display. The process comprises a combination of printing and vacuum deposition and uses peelable mask technology. FIG. 30a shows schematically a substrate 300 comprising a single active matrix pixel display area 302 of 300 micrometers by 400 micrometers. Structures of many different scales can be created by the process described in this application, form very small (microns) to very large (cm) scale, for example display pixels and microelectronic, opto-electronic, and photonic devices and structures.

FIG. 30b shows schematically a top view of substrate with deposited electrodes and bus lines. A gate bus line 304 and a storage capacitor line 306 are deposited as generally parallel lines at opposite sides of the pixel display area. The lines are generally parallel to the limits of the display area.

FIG. 30c shows schematically addition of interlayer isolation. Isolation pads 308 provide isolation between the gate bus line 304 and data bus lines 310. FIG. 30d shows schematically addition of data bus lines 310.

FIG. 30e shows schematically deposition of contact pads. A drain-source contact land 312 is deposited, a capacitor base contact pad 314 is deposited and a display element base contact pad 316 is deposited.

FIG. 30f shows schematically deposition of a masking film 318. The laminated peelable masking film 318 has a very thin cross section and bonds to the substrate 302 electrostatically. A laser etching process is used to create drain-source contact spacing definition 320 and to open masking film deposition windows 322.

FIG. 30g shows schematically deposition of a tri-layer 324 comprising a semiconductor, a gate insulator and a gate metal. The masking film is removed following deposition using a peel-off action onto a take-off roller.

FIG. 31h shows schematically deposition of printed edge insulation land 326. This assists in elimination of edge short circuits when link connections are printed.

FIG. 31i shows schematically printing of a gate bus line connector 328 and a storage capacitor line connector 330. There are top electrode link connectors and use an on-gate method of connection.

FIG. 31j shows schematically printing of interlayer insulation 332. This is laid down between the transistor/capacitor and the display material base electrode.

Preferably the electrodes are formed using direct write methods such as ink-jet printing. The electrodes may comprise a thin film portion and an ink-jet printed portion which may be termed a flexible conductive link or FlexCLink, the ink jet printed portion being laid down when the interconnections are made. A number of interspersed thin film portions and ink jet printed portions may make up the electrode. The provision of ink jet printed portions means that the electrode is far more flexible than conventional electrodes, which is important in applications such as digital paper.

FIG. 31 shows schematically views of a further structure in a further application, being an inverter circuit. FIG. 31a shows schematically a top view; and FIG. 31b shows schematically an electrical diagram. A drain resistor 334 is connected between a supply voltage electrode 336 and an output voltage electrode 338. An input voltage electrode 340 is connected to a gate, and a ground electrode 342 is connected to a source.

Optional reticulation trench 366 may be provided to either side or indeed on any or all sides of the transistor as shown in FIG. 32c. This trench is laser etched, generally parallel to the electrode trenches. The trenches assist substrate deformation. Such trenches are particularly useful if the substrate is flexible. The trenches can be optionally filled with a damping material such as a compliant polymer (silicone or semi-hard clear polyurethane or similar) to assist flexural stability during operation without reintroducing significant mechanical stiffness.

FIG. 32 shows views of an embodiment of co-planar in-line structures produced by a fabrication process: FIG. 32a shows schematically a top view of a structure during the process. The structure shown in FIG. 32a is a transparent thin film transistor 350. The transistor comprises a drain 352, a source electrode 354, a environmental barrier/insulator layer 356, a semi-conductor layer 358 and a gate electrode 360 the substrate in which the transistor is formed is preferably made of PET, or PEN or thin glass. The substrate material may be in rigid or flexible (conformable) formats. The width of the semi conductor channel is indicator by CW on the figure and the channel length CL. This transistor may be made using a peelable mask process substantially as previously described.

As shown in FIG. 32b three generally parallel trenches 362 are laser etched into a substrate 364. Drain source and gate electrodes are deposited in the trenches the semi conductor-conductor layer 358 is deposited on top of the gate contact 360, and the environmental barrier layer is deposited such that it covers all three electrodes.

FIG. 32d shows schematically a dual gate-drain transparent transistor. An increased width-2-length ratio may be obtained using command gate and drain electrodes, as shown. FIG. 32e shows schematically a cross-section through FIG. 32d as may be seen from these figures, this transistor comprises two gate electrodes 368 and two drain electrodes 370 and a single source electrode 372 which is positioned generally centrally. All electrodes are generally parallel. By spacing drain electrodes 370 each side of gate electrode 368 and gate electrode 368 each side of the source electrode 372 the channel width is, effectively, quadrupled, whilst the channel length is only doubled.

FIGS. 32f and 32g show respectively a cross-section through and a top view of a dual gate-drain transistor having an alternate design. The gate electrode 374 has its fill reservoir end at the same end of the transistor as the drain electrode, and the connection pad for the source electrode is at the opposite end of the transistor as shown in FIG. 32g.

This transistor operates as a coplanar thin film transistor the device configuration shown. This configuration makes use of the fact that all the electrodes are on the same side of the semiconducting film and as such manipulation of the individual connections to such a layer make for a wide range of device behaviour including high voltage by virtue of modifying the spacing between the gate to source electrode trenches

FIG. 33 shows schematically a different type of transistor design, in which there is only one gate electrode that is positioned at the bottom of the common gate channel trench and into which each of the 3 reservoirs flows. This means that for the 3 layer stack of gate electrode, gate insulator, and semiconductor may be precisely vertically aligned thereby minimising/eliminating gate-to-drain/source electrode leakage current and parasitic capacitance. To manufacture such a transistor a ITO train/source conductive film 380 is first laid down on a substrate 302 a trench is then laser etched through the film, through a peelable mask and through the substrate. A vertically aligned tri-layer comprising a gate electrode 384, a gate insulator layer 386 and a semi-conductor layer 388 is then laid down in the trench. The semi-conductor layer can be confined to the trench at a height equivalent to the drain source electrodes or can be deliberately permitted to flow over both drain and source contacts. An optional protective film 390 may overlay the structure.

FIG. 33c shows schematically depths of the tri-layer trench. A step etched structure is used with depths to suit the required film thickness. A feed-in channel is also shown 392. This device operates in the same manner as a bottom gate thin film transistor the only difference is the method used to produce it. In this case it can be produced using liquids or inks based on low viscosity fluids (typically less than 100 mPa·s).

FIG. 33d shows schematically how a tri-layer stack may be built up from a simple cross over structure. A gate layer 394, a insulator layer 396 and a semi-conductor layer 398, all being generally rectangular, are laid down at an angle on a substrate such that they cross over at a square shaped central point 400.

This structure is advantageous because it permits the correct sequencing of the gate electrode, gate insulator, and semiconductor materials into a single trench so as to provide a low cost all printing or liquid processing manufacturing method of a thin film transistor with low leakage current and parasitic capacitance

An in-line structure such as that shown in these figures provides self-levelling embedded contacts. Laser etched cavities shown in these drawings can be produced as smoothly varying structures as in a corrugated roof. A transparent thin film transistor can be manufactured in this way.

This embodiment outlines a method of manufacturing a transparent thin film transistor (TTFT) that makes use of laser etched or embossed microfluidic structures that are defined in a peelable masking film. One such device is shown in FIG. 46. The device 750 is a bottom gate inverse staggered thin film transistor that makes use of two fluid reservoirs to control the flow of fluid dispensed into them by an ink jet printhead. One reservoir is embedded in the substrate, the other is introduced in the peelable mask and is removed when the peelable mask is removed. The embedded reservoir contains the gate contact material and is left in place to act as a gate contact pad. The other reservoir contains semiconductor and insulator material. The reservoirs are so displaced in position and depth that a sequencing of the fluids is achieved that permits the construction of a self-aligned thin film transistor in both opaque and fully transparent forms.

FIG. 33a shows a similar device having three independent reservoirs 384 386 and 388. Each reservoir may be a different depth if necessary.

The method of producing the device 750 comprises laser etching stripes of a transparent conductive oxide (TCO), such as Indium Tin Oxide (ITO), to form discrete pads 752, 754 of transparent contact material pre-deposited on to a sheet of glass or plastic (the glass or plastic being either rigid or conformable in nature).

During the delineation of the contact lands of ITO the “Embedded gate contact” ink reservoir 756 and contact pad 758 is also etched. An optional facility during this first etching step is the introduction (laser direct write etching) of an embedded ink reservoir 760 that is produced adjacent to both the drain and source contacts so as to provide a proximity alignment for the inaccurately placed ink jet printhead droplets to ensure an efficient connection between the interconnection tracks between adjacent isolated device contacts and the device contacts to be connected therein. This contact related containment well 760 also serves the purpose of providing a liquid containing structure (reservoir) for a barrier height adjustment material/coating so that normally inefficient or poorly electronic barrier height aligned materials, that are better in other respects (i.e., electronic conductivity or electro-optic transconductivity in a specific waveband), can be used separately for the device contacts and the device-to-device or device-to-component interconnection bus bars or connecting links. A masking film 762 as shown in FIG. 47 is now applied to the upper surface of the substrate material into which has been etched the embedded gate contact/land reservoir and on which is contained the bisected ITO land (drain and source contacts in the finished thin film transistor). This masking film 762 is applied over the whole of the substrate upper surface using electrostatic or semi-permanent interfacial bonding methods. The laser etching system provides a means of mask patterning that can easily register onto the ITO contact land covered by the masking film. Into this masking film and through the ITO land below is etched a trench that bisects the ITO contact to form two individual electrodes (the drain and source contacts). This trench is extended in one direction into the previously etched gate contact reservoir 768, embedded into the substrate media, using variable height and etch rate (number of pulses) to control the geometries of the interconnecting duct. This trench is also extended in the other direction into a newly etched semiconductor layer reservoir 764 (completely contained within the masking material) once again using variable height and etch rate (number of pulses) to control the geometrics of the interconnecting duct. This interconnecting duct geometry influences the amount of liquid that is transferred from the reservoir into the microfluidic gate channel and hence directly affects the thickness of the resulting device film (selected device build layer) once the liquid has dried/solidified.

The location of the device trench break through into the gate contact and semiconductor containment well reservoirs is not critical since the liquid will still flow, via the connecting duct, into the main device microfluidic channel (gate channel) to provide the necessary uniform coating.

FIG. 47 shows a variable shaped interconnection duct 766 between a gate contact reservoir 768 and a gate channel region where an aligned gate electrode bottom contact is disposed. The figure also shows a variable depth reservoir containment well 768 with a corresponding laser etched access window 770 in the masking film. The access window can be appreciably smaller than that shown and still provide adequate access to fit within the reservoir even allowing for the tolerances and variable accuracy of procedures such as digital ink jet printing. A variable depth semi-conductor reservoir 764 is laser etched into the masking film 762 only.

A direct write processing method such as digital drop-on-demand ink jet printing can be used to apply one or more droplets of ink into the appropriate reservoirs to produce the required gate contact—gate insulator—semiconductor vertically aligned stack. Where the embedded gate contact reservoir, etched into the substrate, remains in place and serves the secondary purpose of providing a device-to-device or device-to-component or external connection contact pad once the remaining liquid has dried/solidified.

It is envisaged that in using digital or continuous selectable drop-on-demand ink jet printing technology that a monodispersed droplet stream (jet) comprising individual droplet volume in the range 0.001 picolitre to 100 picolitres will be used in relation to the filling of the laser etched reservoirs. This means that droplets of mean diameter 1.24 microns (0.001 picolitre) to 57.6 microns (100 picolitres) will interact with the etched reservoirs and will provide a feed liquid for the construction of the required thin film transistor.

For the purpose of illustrating how a transparent transistor can be produced using digital ink jet printing (includes multiple level greyscale printhead technology) a 10 picolitre (26.7 micro metre diameter) droplet will be used. Since the transistor to be constructed is transparent it is possible to consider building a very different scale of device when compared with conventional opaque structures. In order to illustrate this we will take as our representation demonstration product an approximately 1 metre wide by 0.56 metre (16:9 length: height ratio) high flexibility (conformable plastic substrate media such as Melinex [polyethylene terephalate, PET]) colour display active matrix backplane where the display media is liquid crystal technology (including transmissive, reflective, or transreflective) that requires a switching circuit comprising a single thin film transistor and associated storage capacitor. Each display pixel comprises three individual colour pixels for red (R), green (G), and blue (B). Since this display panel is for large viewing distance (of order 2 metres or more) applications, such as colour video playback posters for upcoming film and product sales advertisement in cinemas or Blockbuster stores, etc., it is possible to use a large area tri-colour pixel of order 1 mm square. The large pixel actually comprises 3 individual pixels (for RGB colours) of geometry 1 mm in length by 0.33 mm in width (including isolation spacing between pixels).

For clarity we will continue our manufacturing illustration by looking at a single colour pixel of overall size 1 mm by 0.33 mm. Since the switching circuit is completely transparent in the optical waveband range of wavelengths it is possible to use large and complex geometry structures in the circuit manufacture irrespective of whether the manufacturing process is of lowest cost or not. This means that fluid reservoir/contact pad containment well structures can be used as part of the transistor fabrication scheme and that such features can be large in comparison to conventional opaque transistor technology.

The active matrix switch—transparent thin film transistor—shown in FIG. 48 is a three terminal highly non-linear switching device that possesses a steep threshold characteristic. Such a pixel is shown in insert G and is defined by eight lines 782 and a data line 784 the pixel also comprises a transparent thin film resistor 786 an LC element 788 a capacitor CST and, inevitably, parasitic compacitents CGS. It is possible for a transistor with a field-effect mobility of only 0.1 cm² V⁻¹s⁻¹ to switch an LC display pixel. The transistor switch must supply a voltage V_{LC} to completely switch on the pixel where the LC pixel behaves as a capacitor with a capacitance, C_{LC}. To cater for not overcharging the LC pixel capacitor during the refresh time (T) of a large array (N rows by M columns) display the row duty cycle (T/N) switching requires an optimum current drive level—the transistor On current, l_{ON}—that is given by l_{ON}=6 C_{LC} V_{CL} (N/T).

There are a number of dynamic characteristics of an LC pixel in an active matrix liquid crystal display (AMLCD) that are important including:
1. Storage time of the signal potential that drives the switching of the LC element
2. Switching time to transfer the signal voltage into the load capacitor via the on-state TTFT
3. Shift in potential that appears just after the gate voltage changes from the on-state to the off-state bias condition as a result of the parasitic capacitance between the gate and source electrodes, C_{gs l}
4. Delay and distortion of the gate pulse voltage or the gate delay

If the resistances of the LC element and the thin film transistor are sufficiently high then a storage capacitor is not needed. However, to achieve adequate levels of storage time, τₛₜ, a storage capacitor is usually employed in the pixel switching circuit.

### EXAMPLE

FIG. 51 shows a single pixel circuit 790 that can be used to switch a high (for this illustration 60 volts but in principle even very high voltages exceeding 200 volts can be supported) voltage liquid crystal display element. The device shown in this illustration is able to switch a high voltage without degrading the transistor performance. Since the transistor switching circuit is transparent it is possible to provide a solution that makes use of a number of thin film transistors that are switched in unison (all at once), using a common connected gate 792 and interlinked drain 794 and source 796 electrodes are shown in FIG. 49.

An alternative device is shown in FIG. 50. FIG. 50a shows a device 800 before removal of the mask; and FIG. 50b shows the device 800 after the removal of the mask. The device comprises a drain and source contact wells 802, 804 a plurality of interdigitated interlinked gate electrodes 806. the electrodes 806 are interdigitated with an insulator and semi-conductor stack 808. The microfluidic channel filling for gate contact pads 810 and a removable reservoir in a peelable mask containing the insulating semi-conductor materials 812 are both removed when the peelable mask is removed.

Alternatively, the device presented here, and also shown as a circuit schematic in FIG. 51 may provide that a high voltage to be switched can be distributed between a series of transistor devices that are produced as a single device in a single processing sequence.

An alternate design provides for a removable gate contact reservoir.

FIG. 51 comprises a plurality of gate lines 820 and a data line 822. The device comprises a switch 824 comprising 4 transparent thin film resistors 826, a LC element 828 and CST 830 and parasitic capacitance 832 as previously described.

It is envisaged that, in this embodiment, the transistor output current, for the display size and pixel density of interest, will be of order several μA to several mA since the transistor circuit is switching a capacitive liquid crystal pixel. One possible design geometry for the switching transistor, for a large pixel size (say 1 mm square comprising one or more pixels dependent upon whether the display was monochrome, colour, or a hybrid of pixel technologies) commensurate with large area displays, such as electronic and video playback posters, would be a 4 gate structure with a gate length of <50 μm, a channel width of >5 μm, and a semiconductor mobility of >0.1 cm² V⁻¹s⁻¹, which for a suitable selection of gate insulator and drive voltage would provide a suitable transistor output current.

From the design parameters of the transparent thin film transistor as outlined above it is possible to define the geometry of the containment well reservoirs for the multiple gate contacts and the insulator-semiconductor bilayers. Using typical transistor film thicknesses the required gate contact pad and conductive ink reservoir geometry would, for a rectangular shaped (other shapes are possible) reservoir, be a length of say 120 μm, a width of say 100 μm, and a depth of say 2 μm. This provides a total fluid volume capacity of order 24×10⁻¹⁵ m⁻³ (or 24 picolitres sufficient to hold 2-off 10 picolitre drop even with a drop volume variation of ±10%). The 20 picolitre total drop volume would have a static liquid height, assuming no solvent loss, of 1.67 μm. Since the collective volume needed to provide the necessary gate contacts in the multiple contact structure is of order 20×10⁻¹⁵ m⁻³, assuming a solid loading of only 5%, the access window that allows the fluid to flow from the reservoir into the microfluidic channels can be limited to depth of order 2 μm from the substrate surface (essentially in-line with the depth of the reservoir). This would allow uniform in-filling of the gate contact microfluidic trenches and the reservoir that after drying/solidification of the conductor containing fluid would produce a suitably distributed gate contact and interconnect contact pad. The contact pad/reservoir being substantially empty after the fluid has dried/solidified provides a catchment/containment well for suitably printed (i.e., digital ink jet) device-to-device and external connection (i.e., to gate bus line, etc.).

A similar argument exists for the removable reservoir that provides the necessary liquid source material for both the insulator and semiconductor layers. In this instance the layer thickness is generally less than the gate contact and as such a single 10 picolitre droplet, for each layer, should be adequate to provide the distributed bilayers being proposed. The insulator—semiconductor fluid reservoir being substantially empty after the fluid has dried/solidified from the first filling, the gate insulating layer, provides a catchment/containment well for the second fluid to provide the semiconducting layer in an aligned structure.

Such a geometry is shown in FIG. 52. FIG. 52a shows schematically a cross-sectional view of a substrate 900 having a gate bottom contact 902 a gate insulator 904 drain source contacts 906 a gate reservoir 908 and a semi-conductor reservoir 910. A laser etched peelable mask 912 provides access to the gate reservoir and houses the semi-conductor reservoir.

FIG. 52b shows schematically a cross-section across the transparent thin film resistor along the line AA showing embedded ink containment wells 914 and an embedded gate contact interconnection pad 916.

Another important electrical characteristic of liquid crystal (LC) display technology is switching speed. The LC takes time to react to the application or removal of the switching voltage resulting in small delay times associated with the onset of rise and decay. LC's exhibit an exponential increase in viscosity as the operation temperature is reduced resulting in increases in delay times. Such delay times can be reduced by decreasing the LC viscosity or display pixel thickness but for optimum behaviour it would be useful to control the temperature of each LC pixel. Using the method manufacture outlined above in conjunction with a transparent resistor, based on a controlled resistivity of a transparent conducting oxide such as Aluminium-doped ZnO or Indium Tin Oxide (ITO), it would be possible to build a localised heater in each pixel that could be used to control the pixel temperature to a specific operating range.

Applicability

The above outlined manufacturing method for the production of a thin film transistor and related micro- and opto-electronic devices and components, whether opaque, translucent, or transparent in nature, can be achieved using the following material types:
1. Polymers
2. Polymers combined with nanoparticle powder
3. Nanoparticles, rods, wires, flakes, belts, or tubes
4. Direct chemical converting liquids

Features of the Processes and Structures Include:
1. The use of a laser etched peelable mask to define the semiconductor film where the liquid containment reservoir is completely contained in the masking film and is removed, along all remaining contents, when the masking film is peeled away from the substrate
2. The use of a laser etched embedded gate contact reservoir that is a permanent feature of the device and serves the secondary purpose of provide a gate contact connection pad
3. The use of laser etching to dissect the ITO land and form the microfluidic channel and the embedded gate electrode
4. The use of a vertically self-aligned thin film transistor structure
5. The use of the dissection of an ITO land of material covered in a masking film with concomitant etched trench in the masking film that aligns directly with the gap etched in the ITO film due to the dissection process
6. The use of multiple gates in a single device build using a common trench fill reservoir (whether reservoir is a permanent or temporary feature of the transistor structure)

Bandgap Alignment

FIG. 34 shows schematically a cross-section through deposited elements of a thin film transistor, showing a bandgap alignment layer 402. A bandgap alignment layer allows a relatively high-k (dielectric constant) insulator for a film to be used with a low-k semi-conductor 406 even though the electron band energies of the semi conductor and insulator are such that, without an alignment layer, leakage might occur.

The bandgap alignment layer is preferably made from a material such as silicon dioxide which has a very high bandgap and is an excellent insulator.

We have realised that the basic bandgap selection issue relates to the use of a pair of vertically stacked insulators that form a pair of capacitors in series. This means that the important issue is the (dielectric constant)(thickness) product such that the band gap alignment layer (dielectric constant)(thickness) product is of order 100 times lower in value than the required wide band gap insulating film in order to not influence the overall charge transfer properties of the higher-k material in the bilayer insulating stack. This is as a direct result of the key equation for two capacitors in series, namely:

C_{Equivalent}=(εₒε_{SiO}_{₂}A)(ε_{HfO}_{₂}/{ε_{SiO}_{₂}d_{SiO}_{₂}}+{ε_{HfO}_{₂}d_{HfO}_{₂}}) [F m⁻¹]

For example, a hafnium oxide (HfO₂) thin film has a dielectric constant of order 20 and thickness of 50 nm to give a (dielectric constant)×(thickness) product of 1,000 so in order to achieve a 100:1 ratio the (dielectric constant)×(thickness) product of the much wider bandgap silicon dioxide (SiO₂) film must be 1,000 divided by 100. In mathematical terms:

ε_{SiO}_{₂}d_{SiO}_{₂}≦10 [nm]

d_{SiO}_{₂}≦10/ε_{SiO}_{₂} [nm]

d_{SiO}_{₂}≦10/3.4 [nm]

d_{SiO}_{₂}≦2.94 [nm]

Such a thickness of ultra thin film is readily achievable using any one of the proposed manufacturing methods whilst still providing adequate direct tunnelling leakage current protection due to the drive voltages that might be required to operate this design, particularly when used as a transparent thin film transistor.

The use of a bandgap alignment layer permits a much wider range of gate insulators to be used.

The peelable mask manufacturing method also enables the use of various novel types of apparatus and techniques.

From the above considerations it is possible to use an ultra thin film of a much wider band gap transparent dielectric (such as silicon dioxide with a 9 eV band gap and ε_{SiO}_{₂} of 3.4), even though it has a low-k value, to protect against leakage effects from non-centralised (non-symmetric) charge neutrality level (CNL) alignment thereby permitting a much wider choice of high-k dielectric (such as strontium titanate with a 4 eV band gap and ε_{SrTiO3} of 100 or more) without recourse to considering conduction and valance band overlap induced leakage in the TTFT design. For strontium titanate a bandgap alignment silicon dioxide film thickness d_{SiO}_{₂}≦14.7 nm would be required to fulfil the 100:1 ratio.

One of the benefits of the peelable masking manufacturing method is the fact that it is compatible with a multiple layer device build where the layers are vertically aligned and where the layers can be deposited with whole area, selective area, or direct write processing methods using a single mask. This means that the introduction of the bandgap alignment and conduction channel and bulk film growth control insulating layers can be achieved without having to introduce any further masking. This is, therefore, an improvement over a standard build that does not introduce the symmetrically aligned controlling layers and thus provides for a more flexible TTFT manufacturing method that has the potential to produce a much higher quality device at lower cost than conventional TFT manufacture.

FIGS. 35 to 37 shows schematically an embodiment of apparatus for roll-to-roll processing; and embodiments of apparatus for removing a mask.

Cassette-to-Cassette Manufacturing

There is a conceptual method of manufacturing for “Selectable Interconnect Array Integrated Circuits” (SIA^{IC}) production that makes use of cassette-to-cassette processing. The idea is to use a cassette transport system for the roll of substrate material such that the cassette is inserted into a lamination machine. The lamination contains a second roll of masking film and a mechanism that pulls the substrate material out of the inserted cassette and mates with the masking film on to a temporary support take-up roller. The laminated substrate-masking film bilayer is then rewound off the temporary take-up roller back into the cassette casing and on to the take-up roller housed therein.

The cassette is now removed from the lamination system and is then coupled into apparatus such as that shown in FIG. 35. This apparatus includes a processing machine, which may be a multi-cathode magnetron sputtering system 500. A feed cassette 502 stores a bi-layer material comprising a peelable mask and a substrate. This cheap material may be pulled from the cassette passed through secondary rollers 504 and introduced into the sputtering system 500. The masked substrate sheet material is then coated. The coated bilayer material is subsequently dissected as shown in FIG. 31 or FIG. 37. The masking film is peeled away from the substrate sheet material so as to remove the unwanted coating whilst leaving the required coating pattern (in this case peel-off occurs as the roll of coated materials is rewound back onto the carrier roller located in the cassette housing). As shown in FIG. 36, masking film 510 is laminated to a substrate 512 the masking film is wound onto a tape-up roller 514, a secondary roller 516 being used to provide a continuous tension on the film, as the substrate is pulled rightwards as shown in the figure.

FIG. 37 shows a system suitable for peeling a double sided masking film 520, 522 from a substrate 524. Each of the masking films is taken up onto take off rollers 526, 528 tension being maintain by secondary rollers 530 islands of deposited material 532 are left on the substrate 524 as it moves toward the right of the figure. The substrate is then wound onto an output roller 540. This coating patterned substrate sheet film is then rewound off the temporary take-up roller back into the cassette casing and on to the take-up roller housed therein.

Laser processing creates debris as a by-product of the etching process. This can be removed by a close proximity micro vacuum system (not shown) that effectively provides continuous suction at the laser processing point or along a distributed etching area or that is removed using a secondary laser beam or equivalent or differing laser wavelength, pulse rate, and pulse energy density.

Other methods may also used to remove the debris. Such methods could be, for instance, air transfer and blowing or liquid spray cleaning.

A further example of equipment suitable for peeling off the peelable mask in a roller-to-roller system is shown in FIG. 53. The apparatus comprises a collection roller 950 for the mask a treated subject roller 952 for the treated substrate, a tensioned roller 954 to tension the substrate as it is wound onto the treated substrate roller and a plurality of rollers 956 which together comprises a tension and force peel of angle control roller. These rollers may be varied in position to control the take up angle of the peelable film and may be varied in relation to each other to determine the force of peelability.

The roller shown can operate in a forward or reverse direction.

Continual Loop System

For manufacture (e.g. circuits) that requires a repeat pattern that is not contiguous in design layout, a single sheet of the laser patternable peelable masking may be patterned off-line, and then mounted in a deposition apparatus so as to form a continuous loop (1200) (see FIG. 73). This continuous loop may be provided as an oscillating (single flatbed or assembly line of discrete panels) or a continuously moving mask (assembly line of discrete panels or roll-to-roll manufacturing) that is in soft contact (low tack pressure-sensitive adhesive (1212)) with the substrate to be patterned. The minimal adhesive contact (which could also be an electrostatic bond) ensures line registration and synchronised transport with the substrate surface and/or ensures that vapour deposits do not penetrate underneath the mask causing feature broadening or loss of edge definition. The system may also be used in liquid-based coating deposition processes such as precision spray coating, digital ink jet, and screen printing. It is envisaged that the loop mask would be used for a given time, such as a single shift of processing time, before being disposed of by rolling up the mask and disposing of it (preferably using national regulations of disposal).

FIG. 73 shows a single magnetron source (1202), but it is anticipated that several different sources may be accommodated between the mask and the substrate (1204) to be coated, so as to provide a means of depositing more than one thin film coating using the same mask pattern.

Optical encoders and piezoelectric positioning device (actuators) may also be used, and it would be possible to have a continuous loop of a series of mask patterns that are sequentially aligned (step-and-repeat) in the same position (very high registration accuracy) so as to provide a means of building up a circuit based on an all additive process. This allows for continuous single pattern or multi-pattern step-and-repeat processing in the same unit.

The continuous loop process as outlined above may also be used for a continuous pattern of a viscous liquid material—similar to that used in screen printing—and also in a more efficient set-up that caters for multiple patterns and materials. High throughput manufacture can be achieved with this production concept.

Example of the use of this technique is the ability to deposit an array of elements such as circuit elements used for automobile windscreen heaters/demisters/antennas and loop antennas for RFID tag stick-on transponders.

The above process is a very efficient means of producing a large number of repeat patterns onto a continuous roll of material (plastic, metal foil, metal, textiles, cardboard, or other) over a range of feature sizes using a masking system compatible with liquid, vapour, and solid particle coatings.

Step-and-Repeat Disposable Masking System

For circuit manufacture that requires a fixed mask design repeated onto a large number of substrates, it is also possible to use the laser patternable peelable masking process to produce a non-contiguous pattern in a disposable frame of masking film that is positioned in the step-and-repeat unit (as described above) and used for a fixed number of depositions before the mask is replaced. (See FIG. 74). The process may be carried out using an assembly line (1210).

The step-and-repeat unit may comprise one or more of the following features:
Processing vacuum contained in the step-and-repeat unit (1214) with the adhesive seal ensuring good process environment control of the vapour process
The magnetron source may be a multiple target design such as a cube or hexagon that can be rotated to select a given material in a given sequence thereby permitting the deposition of a thin film stack or quantum structure
May incorporate a magazine of adhesive peel-n-seal masks that permit very accurate overlay alignment (high precision and repeatability) of several layers in a circuit build that can be achieved in sequence before stepping on to the next substrate piece or area of substrate
May cater for very wide rolls of plastic film (i.e., PET, PEN, etc.)—widths in excess of 2 metres
Multiple step-and-repeat units may be modularly aligned to one another and indexed in predefined sequence to achieve complex circuit manufacture over large area

Flat Bed Process p FIGS. 54 and 55 show schematically apparatus suitable for manufacturing the peelable mask technology on a flatbed process. The apparatus comprises a flatbed processing system base 960 and a mask edge support frame 962. This frame can be integrated onto a demountable substrate holder plate. The apparatus further comprises a peelable masking film edge-supporting frame 966 disposed on top of the mask edge support frame 962.

The rigid substrate is placed into a frame work that includes a lifting bar with a supporting clamp 962 to ensure that the peelable edge of the masking film is included in the masking film lamination process.

A securing edge is supplied over the peelable film lift off edge after the solid film has been laminated or the liquid film has dried to ensure that the peelable edge is removed uniformly and cleanly from the substrate after processing.

The securing edge and a peelable edge locator can be moved with the demount or substrate holder for use on other processing equipment such as whole area spay or digital ink jet printing press.

FIG. 55 shows apparatus for control of a peel off process. An integrated peel off frame 968 is attached to the peelable masking film edge supporting frame 966 and a lateral force causes the peelable mask film etch supporting frame to lift, lifting the peelable film with it, as the peelable film is clamped between the peelable mask frame 966 and the masking edge support frame 962 as hereinbefore described.

The height of the peel off frame 968 in relation to the position of the peelable mask may be altered and appropriate angle height and force or peel off rate set as part of the apparatus control system.

Liquid Mask Manufacturing—Cassette Manufacturing Approach Given the possibility of only requiring a very thin film for the peelable masking and that such a film could be produced using a precision sprayable or jettable (i.e., digital drop-on-demand ink jet printing) liquid source a method of roll-to-roll manufacture of a wide range of devices and circuits comes to mind based on the use of a transportable universal cassette. This cassette is used with a range of equipment such as the masking film laser etching patterning system and the subsequent thin film deposition multiple target sputter deposition system used to deposit the barrier and transparent conducting oxide bilayer of the transparent thin film transistor that forms one of the inventions of this patent application. This means that the retained roll of material housed in the cassette can be precision aligned with any number of processes that are compatible with the cassette attachment mechanism/system, with such system attachment being used time and time again and having easy transfer/swapping of the contained roller/film assembly.

The concept is based on the fact that upon connection of the cassette to a processing system, such as the masking film laser etching patterning tool, a mechanism located within this system (masking film laser etching patterning tool) exposes the roll of film that is protected by an environment plate/flap/cover and attaches to the roll of polymer film contained in the cassette and begins to pull it out to prepare it for expose to the laser. As it does so the embedded digital drop-on-demand ink jet printhead array, housed in the cassette assembly, dispenses a thin continuous film of the peelable masking material that dries (air dried or via exposure to integrated IR lamp/LED assembly) as the sheet polymer is pulled further from the roll and prior to being exposed to the laser patterning system. This process continues until the processable area of the roll of material has been coated and laser pattern treated whereupon the digital ink jet printing and IR heating system is switched off and the processed roll including the laser etch patterned masking film are reverse transferred back on to the roller contained within the cassette ready for transfer to another processing station. Once the complete length of processed material is return to the cassette roller a sealing plate/flap/cover is introduced to protect the processed roll of material as it is transported between processing sites.

Liquid Mask Manufacturing—Batch Processing Approach

The liquid precision spray or droplet jetting process can also be used to provide a peelable masking film on to a batch processing substrate surface such as a glass substrate. Even for very large sheets of glass such as 2 metre by 1.5 metre the digital precision droplet dispensing method provides a highly efficient means of producing the masking film. This batch process also opens up the ability to integrate a re-useable peel-off initiation (start) mechanism into the substrate holding frame/base that allows the liquid coating process to include this peel-off feature during the mask deposition thereby ensuring that the masking film peel-off process can be easily, quickly, and accurately achieved during the masking film manufacture.

It is envisaged that for this manufacturing sub-system/system the masking film deposition process, such as digital drop-on-demand ink jet printing, will be integrated directly into the flat-bed laser etching patterning system.

It will be understood that the present invention has been described above purely by way of example, and modifications of detail can be made within the scope of the invention.

Each feature disclosed in the description, and (where appropriate) the claims and drawings may be provided independently or in any appropriate combination.

Seal-n-Peel Removal System

FIG. 93 shows schematically apparatus suitable for removing processed materials, i.e. the Seal-n-Peel film together with any of a patterned masking film, multiple layer vertical coating stack and/or adjacent unwanted etching and deposition debris as a whole structure 2110, in a single roll-up whole area removal process. The apparatus comprises a flatbed processing system base 2100. The apparatus further comprises a take-up roller 2120 for the composite removal of the patterning sandwich. The apparatus also comprises a removal sheet film pressure transfer roller 2130 and a transfer film protective release liner sheet film take-up roller 2140. Removal of the composite patterning sandwich from the substrate 2150 results in a patterned coating 2160 on the substrate.

Flexible Displays

The processes of the present inventions allow large area flexible displays to be manufactured on a deformable substrate material such as polyester (PET). A range of display medias including liquid crystal (LC), electrostatic balls (E-Ink; Gyricon), OLED (Universal Display Corporation), PLED (CDT), may be used. In all cases it is necessary to be able to deposit a conductive track that spans the display width and height such that when the display is folded or rolled-up the electrode does not undergo micro cracking as a result of the localised stress-strain effects that are induced by the substrate deformation.

The processes disclosed in this application facilitate production of a very large area compatible micro patterning process based on the use, preferably, of a polyethylene terephalate (PET) sheet film and laminated masking film. The method of producing features in the masking film—i.e. the required conductor pattern—is based on use of laser technology that permits both surface and embedded features to be produced.

Macro Scale Straight Line Electrodes (Mandrel Process)

For large features sizes of order several hundred microns and above it is possible to configure a simple low tack pressure-sensitive adhesive tape process that is compatible, for example, with vacuum deposition methods such as magnetron sputtering and ion-beam assisted evaporation, and that may be applied to a rigid or flexible substrate (1306) (possibly from a supply roll (1308)) for the purpose of producing one or more straight electrodes of fixed track and gap. The track and gap may be defined by machining the required geometry into a whole area adhesive tape spool that has been located on a processing mandrel (1300). High precision rotary slitting knife, laser scribing or other suitable tools may be used to define the track and gap required by virtue of removing the tape (1302) from the mandrel spool where it is not required. FIG. 75 shows such a tape array on a processing mandrel where the track and gap are equally spaced. The tape geometry may also be achieved by locating individual rolls of tape on the mandrel using, for example, solid ring spacers (1304) to define the track width whilst the tape width defines the gap. A wide variety of tapes can be used in this context including polyester (PET, Mylar, P-ETE), Polyimide (PI), polyethylene (PE), and polytetrafluoroethylene (PTFE) to name but a few examples. (See various disclosures of masking materials disclosed above).

Similarly a range of low tack pressure-sensitive adhesive (1312) (see FIG. 76) may be used, including silicone, acrylic, and latex to name but a few examples, and applied using hot or cold roller (1310) technology—with or without added roller pressure—in air ambient or a selected gas or a soft/hard vacuum environment. It is also possible to use this approach with electrostatically bonded tape.

FIG. 77 shows a typical illustration of a set of parallel conductors (1314) produced using the mandrel method which may be applied with equal benefit to both rigid (large area glass panels) and flexible (roll-to-roll manufacturing) substrate media.

The above described process is a very low cost method of forming a long length of conductive electrode(s) that is based on the basic material structure used in patternable peelable masking (LPM) processes—preferably the low tack peelable tape.

Although the patterns are contiguous, they are so only in one plane, and as there are no lines of overlap there is no possibility of islands of masking material being left behind as he masking tape is peeled from the substrate.

Even for this application it would be possible to use a “Seal-n-Peel” process to remove the coated masking film, although for some applications such a refinement of the peel-off removal process is not required.

Other applications for this technology include straight-line and interdigitated electrodes for photovoltaic cells and solar panels and ribbons.

Micro Scale Straight Line Electrodes

For higher resolution long length electrodes the “Mandrel” tape process may again be used, but the mandrel spool of adhesive tape (1312) is modified to be photoabsorbing such that very fine features can be produced in the continuous tape as it is pulled from the mandrel, and prior to it being attached to the substrate (equivalent to off-line patterning).

Given that the mechanical integrity of the laser scribed adhesive tape mask might be impaired by the fine features produced in this manner, it is preferred to use the “Seal-n-Peel” process to ensure a clean whole area peel-off of the coated masking tape.

Although the “Mandrel” adhesive tape process is highly beneficial for producing electrodes in straight lines along one axis—say the x-axis—it is also anticipated that an orthogonally defined system (1316) could be set-up to define patterns such as isolated square or rectangular contact pads or electrodes as shown in FIGS. 78 to 80.

The Y-axis tape is preferably applied in a cut-and-attach manner as required by the width of the substrate to be patterned and would apply equally to rigid large area plates as well as rolls of flexible material (plastic, paper, foil, card, etc.).

Non-Continuous Macro and Micro Electrodes and Device Contacts

The mandrel process outlined above may also be used to produce very low, as well as, very high resolution non-contiguous features by providing the laser patterning is undertaken with the masking film in contact with the substrate surface. Otherwise the island features, for example the central portion of an mask defining a circular annulus, will fall out of the masking film before it can be applied to the substrate surface.

The sequence of processing steps undertaken after the masking tape/film (1402) has been attached to the substrate (optically transparent) surface (1400) is depicted in FIG. 81. The sequence shows the laser ablating (1404) a trench (1406) in the masking film thereby opening a deposition window through the masking film onto the substrate surface. After thin film metal deposition (gold coating) (1408) a “Seal-n-Peel” film (1410) is attached using a permanent adhesive (1412) onto the coated masking tape/film, and removed (1414) at the substrate surface resulting in the remaining patterned metal track (1416).

The conductive track may be inorganic or organic, and may be opaque or transparent or any hybridized state in between.

Further Applications

A number of approaches are being pursued in the race to produce both rigid and flexible large area display panels, for signage, games monitors, and high definition television (HDTV), which will have off-panel electronics integrated directly on to the display panel. In this regard, it will be appreciated that the processes disclosed herein can be applied to:
Active matrix switching backplane technology
On-panel pixel switching control and display functionality electronics
Intelligent screen interaction/access electronics
All-transparent display panels (rigid and flexible substrate types)

Other applications include display panel switching backplanes, intelligent touchscreens, large area sensor arrays, bioelectronic sensors, opto-electronic and optical waveguides, radio-frequency identification circuits, MEMS devices, MOEMS devices, fluidic actuators, digital print heads, integrated ferroelectrics, microelectronic ceramic packaging

The core technologies being employed in respect of achieving manufacture of the above products are the laser patternable peelable masking (LPM) process and the transparent thin film transistor (TTFT) and associated circuit devices (all disclosed in detail herein). In order to highlight some of the features being disclosed in this invention a preferred embodiment of an all-transparent large area flexible substrate display panel (as shown in FIG. 89) is described below. This is just one of a wide range of potential products that could be produced using 3T's core technologies.

The description of the array of surface or embedded thin film transistors that can be interconnected after manufacture as an isolated array of devices means that this manufacturing platform can be used to construct an addressable active matrix switching array circuit that can be applied to, for example, the following applications:
Flat panel displays
   Monitors, HDTV, signage
   Interactive screen
Large area scanners
   Whole body detectors—medical (x-ray, gamma, etc.)
   Terahertz whole body scanner (with integrated conformally mapped transparent imager)
Large area imagers
   Operating theatre transparent image overlay system to assist surgeons during operations
   1-to-1 pattern overlay pattern recognition in assembly lines, etc.
Large area distributed/interconnected integrated circuit clusters
Large area distributed sensor arrays
   Integrated processing, memory, and wireless communications and power
Large area distributed transducer arrays for smart and intelligent applications
   Whole area airplane wing skin adjustment and telemetric status updating in real-time

Display Media Picture Element

Such displays usually comprise one or more of the following:
AR Coatings (1800);
Sealing Films (1802);
ZnO:Al TCO Coatings (1804);
Retained IPM Layer Isolation Wells (1806);
Permanent Adhesive Coatings (1808);
On-Panel Electronic Circuit Isolation Coating/Adhesives (1810);
Multiple TTFT Pixel Switching Circuits (1812);
Flexible Substrate Media (i.e. PET, PEN, etc.) (1814);
Single Pixel Cross-section Boundary (1818);
Multi-layer Barrier and Inorganic Growth Surfaces (1820);
On-Panel Control Electronics i.e., Shift Register, etc. (1822);
On-Panel InterPlane Connector Links (1824);
FlexCPlane Stress Relief Ablated Structures (1826);
ZnO:Al TCO Mag. Sput. Coated Laser Ablated Micro Via.; (1828); and
ZnS.Mn I-EL Display Media (1830)

Such a display element could, for example, be a navigation aid integrated into, or laminated onto, an automobile windscreen where the displayed feature might be a right turn indicator that is observable inside the vehicle as well as providing turn indication outside the vehicle where/when required or requested.

Key inventive features disclosed in the present application, which are associated with the manufacture of a flexible (or rigid) display are:
1. The production of embedded device circuitry (switching backplane/frontplane and on-panel circuitry such as shift registers and logic memory) on both sides of a substrate media simultaneously
2. Differential attachment of adhesive energy bilayer forms to produce embedded device circuitry (i.e., display pixel media on to a substrate surface (whether embedded/non-embedded or on a pre-existing circuit feature or device) where the isolation material (material surrounding and confining the display pixel media material) is the lower layer of the laser patternable peelable masking (LPM) system that is in first contact with the substrate surface and that is attached using a permanent bond adhesive
3. The use of FlexCPlane (i.e. flexible) structures for localised stress/strain relief ablated in one or more surface of the pieces parts used to form the overall laminated display
4. The use of FlexCLink structures for localised conductive link deformation adjacent to the ablated FlexCPlane structures to optimise controlled deformability of large area flexible displays
5. The use of localised laser (1906) ablated trenches/wells (1908) (in substrates (1904) having a mask (1902)) that are filled with liquid/vapour planarising polymer and inorganic multi-layer environmental barrier and growth surface (all 1910) that are precisely aligned (1912) to the trench/well wall by the auto-aligned LPM mask(see FIG. 90).
6. Laser ablated micro structures produced as part of the LPM patterning process that are coated with a conductive film using dual side sputtering to ensure good internal coverage leading to low interplane conductive link with integrated contact pads on both surfaces of the substrate film

The use of on-panel electronics to provide drive and switching electronics for a dual set of display pixels on both sides of the substrate allows for simultaneously viewing with the correct image being portrayed—that is written text may be displayed reading from right-to-left on both surfaces at the same time. This concept can be applied to rigid media and paper media display panels.

Having regard to the various disclosures in the present application, it will be appreciated that the processes may be applied to:
Unprocessed substrates with no previous surface features or deliberately defined surface topography (such as a curbed surface or a facetted surface comprising multiple device elements or circuits) to which a mask pattern must be aligned; and or
Pre-processed silicon wafers or glass or flexible plastic sheet film comprising existing partially or fully functional device/circuits with a range of 3-dimensional topography.

The processes of the present inventions allow alignment of one level of patterning with another pre-existing or subsequent pattern. In its simplest form a suitable pattern may be defined using the LPM process in an off-line manner—that is the masking film is patterned free-standing as a roll-to-roll process for subsequent lamination to a selected substrate. Since the selected substrate has not previously been processed, the alignment of the mask is anticipated to be non-critical.

An off-line patterned masking film may be laminated to, for example, a rigid panel of glass, as in the case of a flat panel for use in display manufacture, and the glass will have been cut to precise dimensions and will have a safe handling zone along the edges within which the pattern must not be placed. This means that reasonable care must be exercised to position the masking film on the glass plate—possibly permitting edge-to-edge alignment between the plate and the mask depending upon the precision with which both are produced. Since the masking films of the present inventions possess a low-tack pressure-sensitive adhesive that can be removed cleanly and repositioned many times, it is possible for the roll of masking film to be suspended over the glass plate and the free end of the roll—that is the starting edge of the required mask pattern—brought into contact with the glass plate in order to set-up the required positional alignment (includes electrostatic attachment means also). This may be achieved manually or through the use of high precision robot technology (robotic arms, piezoelectric transducer roller positioning, etc.). Once alignment is achieved and confirmed preferably optically by integrated CCD camera technology, the rest of the mask may be unrolled (controlled rate and height to the substrate surface) and laminated (cold or hot—with or without additional roll pressure) on to the rest of the glass plate surface. Once the whole mask and peel-off tab are in place, a slitting knife or disc cutter or ablation dicing/slitting laser (excimer, diode, or YAG, etc.) may be used to separate the mask from the patterned roll ready for laminating the same, or a different, mask from the same patterned film roll on to another glass or flexible plastic substrate (fixed area or also as a roll of material).

The repositioning ability of the LPM mask provides a manufacturing solution that is both highly versatile and cost effective (particularly so for high resolution disposable screen printing mask applications where identification can be achieved along with much thinner coatings having finer scale features than can normally be achieved using conventional rotary or rigid micro and macro screen technology). Once deposition has been completed, any residual coating material is cleanly removed with the masking film as it is rolled-up and placed in a disposal tube or carton.

At this stage the large glass plate now has on its surface a pattern of a thin film coating that, for example, might be a conductor layout for a circuit—such as data line bus bars for a liquid crystal display (LCD). Developing this later application further opens up a next level of patterning—pattern overlay. For some designs of LCD displays it is necessary to have a transistor switch and storage capacitor associated with each display pixel (picture element) where one end of the capacitor must be connected to the data line bus bar—actually onto a pre-existing contact pad that was deposited with the first mask deposition. Given that this contact pad exists, it is only natural to want to place a second mask on to the glass plate surface that aligns (is in registration with) the contact pad. Once again the low-tack repositioning ability of the masking film permits accurate alignment with the contact pad in a similar manner to that described above. One method of achieving this is based on the use of “through mask etched window alignment”—that is the masking film free edge, as taken from the masking film roll, is approximately positioned in close proximity to, but not contacting initially, the glass plate surface adjacent to alignment marks (fiducial marks) that were deposited using the first mask (and at the same time as the bus bars and contact pads). When used, the CCD camera imaging system controls a robotic arm or electronic film applicator so as to align the edges of the through mask etch windows to the metal deposit alignment marks. Alignment is in the x and y axes, and with the masking film under a specific tension off the roll so as to ensure the straightness of film application once alignment has been achieved. Once proximity alignment has been achieved the masking film may be laminated, but preferably only over a short length of film/substrate. This is so that the CCD camera imaging system can re-evaluate the alignment precision now that mask is in intimate contact with the substrate—any out of tolerance location can be corrected be clean removal of the low tack masking film and repeating the alignment cycle until alignment is achieved at lamination with the defined tolerance. At this stage the second mask may be applied to the glass plate substrate, and slit to length using the ablation laser (or other suitable method). The second deposition may be a single or multiple coating process that provides a patterned dielectric only for the storage capacitor, or might be a dual layer of the dielectric and auto-aligned top contact that forms a complete capacitor with the top contact. For this illustration devices has been deliberately left unassigned electrically thereby allowing other methods of contacting the electrode, such as ink jet printing and laser induced forward transfer printing, to be used to achieve such electrical connectivity as defined by a circuit layout CAD file. Once again clean whole area removal of residual coating material and the masking film leaves a clean fully patterned glass plate. The substrate is now ready to receive yet another masking film (if appropriate) that would be aligned to the previous patterns in a similar accurate manner. This demonstrates a highly tolerant method of patterning a thin film coating using a variety of deposition methods such as physical and chemical vapour deposition, screen printing, inkjet printing, spray coating, and others discussed within the specification.

Other patterning requirements may be dealt with in a similar manner. Take for example the need to deposit a pattern on a dielectric material such as a ZnO as a gas sensing element, or to an existing contact pad of a silicon wafer device. This device will have associated with it a series of marks, possibly deliberate fiducial marks, which may be used for optical alignment. Knowing the device manufacturing circuit/component layout patterning means that the deposition windows being processed off-line—one mode of operating the processes of the present inventions—can be produced along with the required “through mask etched window alignment” structures that are used to achieve precise alignment to the device contact pads. As detailed above a CCD camera imaging system may be used to align the through mask etched windows to the selected substrate surface alignment marks or fiducials, and would repeat the proximity and intimate masking film contact alignment precision test before permitting the whole mask to be laminated. Once again precision alignment is achieved easily and quickly thereby increasing manufacturing yield and device/circuit operational performance uniformity and reproducibility.

Yet another method of accurately patterning a thin film coating on a surface may be achieved by ablating the required deposition window pattern into an unpatterned masking film that has been pre-laminated to a substrate of interest, for example a ZnO gas sensing element on the silicon wafer device. In this instance the requirement is to laminate an untreated masking film onto the surface of a pre-processed silicon wafer that has associated with it a series of contact pads onto which it is required be deposited the ZnO sensing coating. This in effect provides whole area coverage of the wafer with an integrated peel-off tab, but at this stage no deposition windows have been ablated into the masking film. Since the masking film (including the photoabsorbing attachment low-tack adhesive) may be partially or completely optically transparent or in other forms optically opaque (i.e., such as the carbon black photoabsorber loaded film type as disclosed above) it is necessary to have a method of substrate surface feature identification that does not rely solely upon optical waveband visual means. This may be achieved using a number of alternate methods that include infrared imaging and ultrasonic imaging. For an optically transparent masking film system, a CCD imaging set-up, as described above, images a set of alignment features on the pre-processed substrate surface through the masking film and is continuously adjusting the (0,0) reference start position of the laser or laser array. Once registration is confirmed by the optical system, the masking film may be patterned. For other masking film types, the use of infrared or ultrasonic imaging methods take on a similar registration approach as outlined above, but using a different method of imaging the buried alignment mark/feature.

Yet a further method of masking film-to-substrate alignment is the use of high precision sprocket holes produced in the masking film and the flexible plastic sheet substrate material. Alignment of the mask pattern to a specified fiducial or other reference position/structure would take place using, for example, the CCD imaging method described above or a laser position alignment method that scans the sprocket holes of each and aligns them by independently nano-stepping both mask and substrate media roll drives to achieve optimum positioning.

For either method (or alternate approaches) once registration has been achieved, the sprocket holes of both substrate and mask would be locked together thereby maintaining a constant registration that remains even at higher temperatures due to the thermal properties of the substrate material and the base film used in the masking system being equivalent—both being made of polyester for example.

Flexible Substrate and Circuits

As noted in this application, the processes disclosed are suitable for application in the manufacture of very large area distributed electronics (macroelectronics) and display panels (including monitors and HDTV) on flexible plastic substrates.

By definition a mechanically flexible display is required to be deformable—that is folded, crumpled, or rolled-up—and as such the complete electronic system, such as a display panel or electronic circuit, must deform in a manner which does not impart damage to, or degradation of, the panel in storage or operation. An important consideration in this regard is associated with the power and data bus bar electrodes that span the length and breadth of the display—for example the means of providing power and switching data to an array of switching transistors commonly found on the backplane of all thin film transistor active matrix display panels. Conventional materials used for such bus bars, such as indium tin oxide (ITO)—a transparent conducting oxide—undergoes microcracking (and to some degree nanocracking) when the display panel is deformed (or even deflected beyond a critical strain limit) leading to degradation, if not complete failure, of the bus bar electrode. The mechanical failure of the electrode structure is compounded by the fact that the substrate deformation does not occur in a controlled manner, and where it does occur, invariably introduces stress/strain on devices and circuit elements adjacent to the stress/strain site that leads to device/element degradation resulting in a lowering of circuit performance and again even complete failure. Moreover, yet a further issue with flexible substrate circuit manufacture is the permeability of the substrate material—primarily oxygen and water vapour ingress (considerably enhanced in the presence of an electric field)—that once present in a device severely degrades performance and in the limit causes catastrophic failure. This is notwithstanding, the fact that various barrier coatings and multilayer coating stacks are usually used to minimise such condensed liquid and vapour ingress, and which are whole area applied, add to the substrate stiffness thereby exacerbating the problem of substrate flexibility. Reducing the substrate thickness merely modifies the barrier coating requirement (makes it more stringent) such that substrate handling issues are still a serious challenge.

The processes and features described herein allow for the production of flexible substrate displays and electronic circuits (including macroelectronic, organic electronic, and polytronics systems) to provide a solution to the flexible circuit and display deformation and handling difficulties described above, and includes:
Sectionalised electrodes and conductors
FlexCLink flexible conductive links
FlexCPlane micro hinge mechanisms
Localised inorganic barrier and device growth platform

Although it is preferred for one or more of the above to be used together it will be appreciated that they can each be used independently, dependent upon application requirements. In addition, they may also be applied collectively or independently to rigid substrates as for example in the manufacture of display panels on glass sheets.

Sectionalised Electrodes and Conductors

It is preferred to use bus bar electrodes (1500) or long length conductors which comprise a series of tracks (1502) and gaps (1504) along their length: i.e. a dashed design electrode or in other words—bus bar electrodes made up of sections of electrode with a gap between adjacent sections (See FIG. 82A). Since the stress/strain in an electrode is distributed across its length it is not surprising that small deformations of a flexible circuit containing a long length electrode will cause damage somewhere along its length, dependent upon the properties of the electrode thin film, the adhesion of the electrode to the substrate, the extent of the deformation, and the orientation of the deformation. The use of short lengths of electrode reduces the incidence of microcracking and other forms of failure, whilst permitting greater deformation freedom due to the presence of the gaps between the electrodes, which afford some degree of stress/strain relief in the substrate at such locations. Even relatively weaker film-to-substrate adhesion may be supported over shorter lengths for a given deformation strain.

In order to illustrate this point further a section of a display is shown in FIG. 82B that depicts a section of the x and y axis addressable bus bar electrodes (1506) that select which pixel (1508) (display picture element) is to be switched or off. This diagram shows that the conventionally continuous electrodes may be sectioned along the length and breadth of the display pixel. This sectioning location can in fact be anywhere along the electrodes length but as will be discussed later, the location adjacent to each pixel provides advantages that will be dealt with later under the FlexCPlane heading.

The sectioned electrode elements may be achieved in a number of ways including:
Laser patternable peelable masking (LPM) process
Direct write laser ablation
Direct write digital ink jet printing
Micro stamping
Offset printing (Gravure, etc.)

The method chosen will of course relate to the nature of the application, choice of conducting material, required electrode width size, and whether surface or embedded structures are required.

It will be appreciated that sectionalising a continuous electrode is in itself useful for assisting flexible circuit deformation (roll-up of folding, etc.) but in this specific instance, only if some means of electrically bridging such conductive elements is available. This is where the flexible conductive link (FlexCLink) feature is particularly useful.

FlexCLink—the Flexible Conductive Link

In order to produce a continuous long length electrode using the sectionalisation feature described above, it is necessary to have the gaps between the section linked together in the x- and/or the y-axes (i.e. to form a mesh connected in both x and y axes as might be used for manufacturing a flexible substrate solar panel) using a flexible conductive link (FlexCLink) that can accommodate the stress/strain introduced during substrate deformation (i.e., roll-up, folding, etc.).

The concept of using a flexible conductive link is feasible as the actual resistance of such a link is small, and large contact overlap minimises/eliminates contact resistance effects. Preferably, such conductive links are produced at the end of the circuit manufacture—using direct write techniques such as laser forward transfer and digital ink jet printing—and therefore cross-sectional area benefits may be applied by making the link substantially thicker than the original electrode section material (whether in thin or thick film form). Accordingly, it is possible to make use a wide range of transparent and opaque lower conductivity polymer and organic-inorganic nanocomposite materials (such as those described herein) that possess excellent mechanical and flexural properties FIG. 83 shows a typical flexible conductive link (1510) applied to connect two sections (1512) of an x-axis electrode. The placement accuracy of this link may be low and the contact overlap large to accommodate ease of manufacture with built-in fault tolerance and addressing contact resistance issues. In addition, the conductive link may not require post-treatment such as rapid thermal or laser annealing/sintering, but such processes may be used if required.

Since long length electrodes likely by necessity have to cross one another a suitable isolation (1514) (insulating film—see FIG. 84) will likely need to be applied over the 1^{st} level conductive link in order to electrically separate it from the 2^{nd} level electrode link (1516). Once again techniques such as direct write techniques for example laser forward transfer and digital ink jet printing may be used to deposit this insulating land/feature. Completion of an x-y addressable long length conductor layout requires the 2nd flexible link (y-axis) to be deposited over the isolation pad that is covering the 1^{st} conductive link (x-axis) (see FIG. 85) so to provide electrical contact between the y-axis sections of electrode, but without introducing a direct short between the x and y axes electrodes (see also FIG. 86)

Typical materials for use in producing the flexible conductive links include:
PEDOT-PSS(i.e., Baytron)
Nanoparticle conductive ink (Cabot Ag, etc.)
High purity carbon nanoparticle loaded conductive polymer nanocomposites
Carbon nano tubes and rods in polymer nanocomposite form
Transparent conducting nanoparticles in nanocomposite form

Typical materials for use in producing the flexible insulating pad include:
Polyimides (including UV curing forms)
Polyurethanes
Silica nanoparticle loaded polymer nanocomposites
Porous Silicon low K (SILK)
Dielectric resins

Typical conventional opaque and transparent conductors and contacts based on for example aluminium and indium tin oxide (ITO) respectively, have film thickness in the range 0.02 to 1 micron. Preferably, the flexible conductive link thickness will be in the range 0.5 to 5 micron and the corresponding insulating pad thickness will be 0.1 to 2 micron. A typical flexible conductive link cross-section is shown in FIG. 86.

Compatible base materials for nanocomposite coatings may preferably be used to ensure excellent adhesion between the layers comprising the FlexCLink.

In extending the sectioned electrode and FlexCLink idea further to achieve better substrate deformation it is preferable to want to make use of the electrode gap in a manner that allows for controls of the way in which the substrate behaves on a local, as well as, on a macro scale when the substrate is folded or rolled-up—this where the feature termed FlexCPlanes is preferred.

FlexCPlane—(Micro Hinge-like Mechanisms)

FlexCPlane is a feature—that is micro hinge-like or bellows-like—formed into a plastic substrate which provides a controlled compliance weak link along which stress/strain can be channelled, as would be necessary in the case of rolling up or folding a large area flexible display or interactive map that is required to fit into a coat pocket but fold out to a size of order A3 or larger. The mechanical micro hinges (1600) may be positioned at each corner of a key device or circuit element (1602) such as the four corners of a square or rectangular display pixel (see FIG. 87A)

Depending upon the specific properties of the flexible substrate, and the application for which it is being considered, the depth and length (see FIG. 87(1)) of the ablated (or physically impressed) FlexCPlane structure may be adjusted so as to offer the best fold/roll behaviour without compromising issues such as tear resistance and moisture/oxygen ingress. The FlexCPlane structure may have a multiplicity of smooth- or corrugated-edged hinge- or bellow-like structures in the form of trenches that cross-over one another to form a 2-dimensional multi-pointed star that has a finite controlled depth. Each point on the star is associated with a specific trench that forms the flexure plane (hence the term FlexCPlane) along which the plastic substrate will controllably deform when folded or rolled or scrunched up. For applications such as electronic newspapers (generic technology called e-paper) these flexural planes may also provide a means for the display media to controllably bend and distort in a windy environment without causing temporary or permanent damage to individual devices or circuit elements, and preferably without loss of display information quality.

The FlexCPlane trenches/wells may be filled with a compliant substance (see FIG. 87(2)), such as silicone, that acts as a damping agent to ensure that flexure along any of the FlexCPlanes (laser etched/ablated trenches/wells) cannot be so manipulated as to over stress/strain the micro hinge-/bellow-like structures, thereby leading to fracture and crack formation and subsequent propagation.

A 4-point FlexCPlane structure (see FIG. 87) applied to the corners of a square provides a means of deforming or folding along orthogonal planes. Alternate FlexCPlane structures; dependent upon the nature of the application, (degree of deformation/bending/folding/rolling required) and the device type(s) and circuitry layout/complexity required; may comprise multiple flexural planes (see FIGS. 87B and 87C) with different fold weightings based on the length, width, and depth of the ablated micro hinge-/bellow-like structures produced. Such complex structures may be defined as intrusive (laser ablated on reverse side to the side used for device and circuit manufacture) or non-intrusive (laser ablated on either side of substrate thereby catering for device and circuit manufacture on either or both surfaces) to a specified region, and may be in from the top plane of the substrate, or from the bottom plane of the substrate, or directly through the total thickness of the substrate.

The FlexCPlane concept may be applied to specific locations that are designed to optimise the folding behaviour of a flexible circuit/display using Origami folding techniques, but applied to plastic sheet or plastic coated paper (for example a pocket-sized fold up games monitor or TV display or interactive map (see reference: http://db.uwaterloo.ca/˜eddemain/papers/MapFolding/. for a mathematical explanation of Origami folding of maps). For some applications the flexible substrate media may have an embossed pattern or bi-layer laminate that affords a degree of mechanical stiffness to a very thin section plastic film onto which the required electronic circuitry is manufactured. The laser ablated folding structure (FlexCPlanes) would preferably be located so as to act on the embossed or laminated stiffening structure/film so as to achieve the desired folding behaviour whilst retaining the handling ability being sought for such a very light structure.

Localised Inorganic Barrier and Device Growth Platform

In order to maintain the best mechanical deformability from a flexible plastic display it is believed that replacement of whole area barrier and surface asperity smoothing coatings, with localised equivalent schemes, will provide considerable benefits. The embodiment as described herein is directed to embedded devices and circuits since these are regarded as providing the best overall performance and lifetime. However, the ideas being present apply equally well to surface manufactured devices and circuits. As previously disclosed, a flexible plastic substrate may have laminated on its surface a low-tack pressure-sensitive (peelable) masking film which has been subsequently laser ablated into it a pattern which is also transferred into the substrate to some controlled depth (trench or well). The edges of the masking film and the trench/well feature ablated into the substrate are preferably auto-aligned. The spatial and temporal nature of the laser ablation process may sometimes form a rough surface at the nano/micron scale that might undergo smoothing from the heat transfer of the laser pulse during UV or IR laser ablation. In any event the masking process permits a liquid deposition to be performed that fills a portion of the trench/well so as to provide a highly smooth surface onto which is then deposited a multiple layer stack (or quantum stack) coating structure that provides the following key functions:
Adhesion promotion to smoothing polymer (physical and chemical interaction)
Barrier to oxygen and moisture/water vapour ingress
Oxide-based growth surface for the manufacture of oxide-based devices and circuits

The liquid filling of the laser ablated trench/well may be undertaken using digital ink jet printing (D-IJP)) or precision spraying methods.

Depending upon the application requirement, and the nature of the polymer-oxide thin film interface reaction being sought for the subsequent oxide thin film adhesion promotion film, a range of liquids may be used to provide the smoothing layer that may be applied using D-IJP or spraying as dictated by such liquid/ink properties as viscosity, surface tension, and visco-elastic nature. The oxide film-to-smoothing polymer coating interface adhesion may be enhanced by using ion bombardment techniques—termed ion-assisted deposition—whereby the oxide film is driven into the near surface region of the polymer surface under the action of ion recoil as a result of energetic ion collisions during the early stages of the film growth. The ion bombardment (integral part of the specific magnetron sputter deposition process or secondary ion beam or plasma source) is only used for the first few monolayers of oxide film growth as to not promote surface roughness directly which would be exacerbated as the barrier film stack was deposited on top of the adhesion promoting layer.

A completed laser ablation patterned trench/well (1702) comprising a smoothing layer (1704) and adhesion promotion multiplayer barrier stack (1706) is shown in FIG. 88. It is this structure which provides a high degree of substrate flexibility and environmental protection without making use of whole area barrier films or multiple layer structures as is used in the Vitex Systems, Incorporated Baric multiple layer coating approach (reference: http://wvvw.vitexsys.com/coating.html.).

By way of a summary, the present invention provides a method comprising applying a mask to substrate; forming a pattern in the mask; processing the substrate according to the pattern; and removing the mask from the substrate. Essential and preferred features include:

Features of the mask:
may be in the form of a sheet film such as a polymeric film (masking film) that may be applied by lamination e.g. using roll-to-roll delivery, or
in the form of a coating (e.g. adhesive) (mask coating) that can be in solid, liquid or vapour form and may be applied by a wide range of methods (printing, spray coating, vapour deposition etc.).
is desirably ultra thin (feature resolution and laser ablation efficiency)
needs to adhere or be made to adhere to the substrate, for example electrostatically or by means of adhesive
should be peelable (if mechanical removal is to be used)
may include photoabsorbers (laser ablation efficiency, auto-etch stop at mask/substrate interface)
may be multi-layered (e.g. film+adhesive)
should have sufficient mechanical and/or chemical integrity (to assist peeling and so mask areas remaining after patterning are not affected by patterning method e.g. laser ablation or microstructure material deposition method e.g. magnetron sputtering)
may need to be treated (chemically/physically) to assist with wettability or attachability, and may be delivered from another (non-mask) sheet/film (release liner)

The formation of the pattern in the mask:
preferably by laser ablation
other methods may be used e.g. micro stencilling although
laser ablation preferred because of cost and laser etch control: auto-stop at mask/substrate interface (therefore need for IR photoabsorbers) for on-substrate patterning
may use other lasers including different types in one process sequence
the resulting pattern may be a: contiguous pattern: continuously connected features (areas of disconnected mask) or Non-contiguous pattern: Discrete array of regular or non-regular features
patterning can be: On-substrate: Pattern imaging of a mask coating or sheet film directly on the substrate surface; Off-substrate :Pattern imaging of a mask coating or sheet film off the substrate that is then transferred by some means (e.g. release liner) onto the substrate surface
laser ablation can cause debris, methods such as suction, air flow etc. need to be used for a clean process

Processing the substrate according to the pattern
depositing a thin or thick coating (material) through the patterned mask such that when the mask is removed a patterned coating (feature(s)) remains on the substrate
this “coating” is different to the mask coating even though methods of depositing a thin or thick film coating can produce “the mask” as well as the required “patterned coating”
The resulting microstructures (features) comprise these preferably functionally equivalent (e.g. microelectronic material -semiconductor, conductor, dielectric etc.) coatings/materials.
A build up of these microstructures (patterned coatings/features) using successive masks and different functional materials (layers) results in devices and circuits e.g. thin film transistor (TFT) or integrated circuit.
A stack of different functional materials (layers) can be deposited from whole area coating deposition techniques (e.g. vapour) using one mask because this cannot be done with a subtractive (removing unwanted coating) technique such as photolithography.

Mechanically removing the mask from the substrate
Mask is peelable to allow mechanical removal by peeling
removal may be by de-lamination (used patterned mask peeled off substrate onto e.g. roll-to-roll mechanism for disposal)
may use some peel assist methods (heating etc.)

Seal-n-peel removal system
is a (non-mask) material (e.g. polymeric film) in sheet form with adhesive properties (different to the mask adhesive) that is applied to the used (covered with functional coating) patterned mask (or mask stack). This patterned sandwich can then be mechanically removed (peeled) from the substrate using a de-lamination mechanism

Key features of this process are:
Provides support/strengthening/rigidity for removal of ultra-thin LPM mask materials
Provides support/strengthening/rigidity for removal of wide-area ultra-thin LPM mask materials
Provides method of removing non-contiguous patterned mask
Seals excess materials (including functional coatings on masks and laser ablation debris)
Provides a method for clean disposal of these consumables and allows reclamation of functional materials e.g. metallic coating

Apparatus to be used for the process includes:
1. a mechanism for applying a mask to a substrate
   lamination equipment with:
      i. delivery of the mask in sheet form (possibly with a non-mask liner) possibly from a roll to roll delivery system, and
      ii. Equipment to laminate mask onto substrate e.g. rollers
   coating equipment:
      i. e.g. liquid printing system or vapour deposition
      ii. may need further treatment e.g. curing
2. a mechanism for forming a pattern in the mask
   vacuum chamber
   laser equipment
   computer control
   x-y addressable platen (flat bed, roll to roll) maybe with vacuum
      off-substrate−mask (+release liner)+transfer to substrate and release liner removal
      On-substrate−substrate+mask
   Laser ablation debris removal systems e.g. suction, air-flow
3. a mechanism for processing the substrate according to the pattern
   mechanism to transport patterned mask/substrate into and out of an industry standard deposition system
   preferably low temperature deposition process(e.g. magnetron sputter, IJP)—mask/substrate temperature tolerance
4. a mechanism for mechanically removing the mask from the substrate.
   Lamination equipment to attach seal-n-peel film to processed mask
   De-lamination equipment to remove (peel-off) processed mask or patterned sandwich (e.g. onto roll
   Disposal system

Manufacture of microstructures
LPM process can be used to make a wide range of microstructures
Any substrate can be used but flexible (plastic) substrate (roll-to-roll manufacture) preferred
Preferably these are made from functional (thin or thick film) materials (for use in microelectronic devices and circuits)
The LPM process especially suitable for manufacture of transparent thin film transistor arrays for e.g. active matrix backplane display pixel drivers on flexible substrate and/or large area substrates (no process area limitations)

1. A method of manufacturing microstructures comprising:
applying a mask to a substrate;
forming a pattern in the mask;
processing the substrate according to the pattern;
removing the mask from the substrate;
the processed mask being optionally removed by means of a film coating.

2-127. (canceled)
